(19) United States
(12) Patent Application Publication
(10) Pub. No.: US 2004/0262665 A1
(43) Pub. Date: Dec. 30, 2004

(54) Semiconductor storage device, method for operating thereof, semiconductor device and portable electronic equipment

(76) Inventors: Hiroshi Iwata, Ikoma-gun (JP); Kouichirou Adachi, Tenri-shi (JP); Akihide Shibata, Nara-shi (JP)

Correspondence Address: BIRCH STEWART KOLASCH & BIRCH, PO BOX 747, FALLS CHURCH, VA, 22040-0747, US

(21) Appl. No.: 10/847,628

(22) Filed: May 18, 2004

(30) Foreign Application Priority Data
May 19, 2003 (JP) P2003-141034
May 20, 2003 (JP) P2003-142590
May 20, 2003 (JP) P2003-142600

(51) Int. Cl. G11C 8/00

(52) U.S. Cl. 257/314

(57) ABSTRACT

A semiconductor storage device comprises memory function bodies that are formed on sidewalls of gate electrode located on one side and the other side of source/drain diffusion regions and have a function to retain electric charge or polarization. A quantity of electric charge flowing in a channel region changes depending on an amount of an electric charge or polarization retained in the memory function body specified by selecting a prescribed word line and a first bit line and a second bit line.

This nonprovisional application claims priority under 35 U.S.C. §119(a) on Patent Application No. 2003-141034 filed in Japan on May 19, 2003, Patent Application No. 2003-142590 filed in Japan on May 20, 2003, and Patent Application No. 2003-142600 filed in Japan on May 20, 2003, the entire contents of which are hereby incorporated by reference.

### TECHNICAL FIELD

The present invention relates to a semiconductor storage device, a method for operating the semiconductor storage device, a semiconductor device and portable electronic equipment. More particularly, the present invention relates to a semiconductor storage device in which field-effect transistors having memory function parts are arrayed, each function part having a function of holding electric charges or polarization. The present invention further relates to a method for operating the semiconductor storage device, a semiconductor device that employs such a semiconductor storage device and portable electronic equipment that employs such a semiconductor storage device.

### BACKGROUND ART

The following will describe a flash memory as a representative example of conventional semiconductor storage device. FIG. 57 is a schematic plan view of conventional flash memory cell array. FIG. 58 is a schematic sectional view taken along line 58-58 of FIG. 57. In FIGS. 57 and 58, there are shown a semiconductor substrate 961, a floating gate FG, word lines WL, a source line SL, a bit line BL, element isolation regions 908 and an insulator 931 (refer to Japanese Patent Laid-Open Publication No. HEI 5-304277).

The flash memory cell which constitutes the flash memory cell array comprises a floating gate, and retains storage as the quantity of charge in the floating gate. In the memory cell array as shown in FIG. 57, constructed by arranging the memory cells, the desired memory cell can be subjected to rewrite and read operations by selecting the specified word line and bit line and applying a prescribed voltage to the lines.

FIG. 59 schematically shows a drain current (Id) vs. gate voltage (Vg) characteristic when the quantity of charges in the floating gate of the flash memory cell changes. While Id-Vg characteristic in erase operation is shown by continuous line, Id-Vg characteristic in write operation is shown by broken line. As the quantity of charges in the floating gate increases, the threshold voltage increases, and the Id-Vg curve is displaced roughly parallel in a direction in which the gate voltage Vg increases with respect to same drain current Id, resulting in a curve shown in broken line.

However, in the aforementioned conventional flash memory, the floating gate being located between the word line (gate electrode) and channel region arranged under the word line in the semiconductor substrate, because it is necessary to prevent leakage of electric charges from the floating gate, it has been difficult to reduce the thickness of an insulation film that isolates the floating gate from the word line and an insulation film that isolate the floating gate from the channel region. Therefore, it has been difficult to reduce the thickness of a practically gate insulation film, and this has hindered the miniaturization of the memory cell.

### SUMMARY OF THE INVENTION

Accordingly, an aspect of the present invention is a semiconductor storage device that is easy to miniaturize.

Example embodiments of the present invention preferably include a semiconductor storage device comprising:

element isolation regions formed at a surface of a semiconductor substrate;

active regions other than the element isolation regions formed at the surface of the semiconductor substrate, wherein the active regions are arranged in a matrix form defined by a first direction and a second direction intersecting with the first direction;

two source/drain diffusion regions which operate as a source or a drain and are formed in each of the active regions;

a channel region defined between the two source/drain diffusion regions;

a plurality of word lines extending in the second direction provided on the. semiconductor substrate, each of the word lines being located on the channel regions of the active regions arranged in the second direction, with an insulator disposed between each of the word lines and the semiconductor substrate; and

a plurality of first bit lines extending in the first direction and a plurality of second bit lines extending in the first direction provided on the semiconductor substrate, wherein

each of the first bit lines is connected to one of the source/drain diffusion regions formed in the active regions arranged in the first direction,

each of the second bit lines is connected to the other of the source/drain diffusion regions formed in the active regions arranged in the first direction,

each of the word lines functions as a gate electrode on the channel region,

the insulator functions as a gate insulator on the channel region,

memory function bodies having a function to maintain electric charge or polarization are formed in sidewalls located on one side and the other side of the source/drain diffusion regions with regard to the gate electrode, and

a quantity of electric charge flowing in the channel region specified by selecting the prescribed word line, first bit line and second bit line changes according to an amount of the electric charge or polarization retained in one of the memory function bodies specified by selecting the prescribed word line, first bit line and second bit line.

According to the above-mentioned construction, by selecting a prescribed word line, a first bit line and a second bit line, the storage information of a specified memory function body can be subjected to rewrite or read.

Furthermore, the memory function body, which has a function to retain electric charge or polarization, is formed on the sidewalls of the gate electrode of the word line, and this memory function body is formed separately from the insulator that separates the channel region from the word line. Therefore, it is easy to form the insulator into a thin film and to restrain the short-channel effect. Therefore, the element can be scaled down in size, and the manufacturing cost can be reduced.

Moreover, example embodiments of the present invention preferably include a semiconductor storage device comprising:

element isolation regions formed at a surface of a semiconductor substrate;

active regions other than the element isolation regions formed at the surface of the semiconductor substrate, wherein the active regions extend in a first direction and are arranged in a second direction intersecting with the first direction;

a plurality of source/drain diffusion regions which operate as a source or a drain and are formed in each of the active regions;

channel regions defined between the source/drain diffusion regions that adjoin in an identical active region;

a plurality of word lines extending in the second direction provided on the semiconductor substrate, each of the word lines being located on the channel regions of the active regions, with an insulator disposed between each of the word lines and the semiconductor substrate; and

a plurality of first bit lines extending in the first direction and a plurality of second bit lines extending in the first direction provided on the semiconductor substrate, wherein

each of the first bit lines is connected to one of the source/drain diffusion regions formed on an identical active region,

each of the second bit lines is connected to the other of the source/drain diffusion regions formed on the identical active region,

each of the word lines functions as a gate electrode on the channel region,

the insulator functions as a gate insulator on the channel region,

memory function bodies having a function to maintain electric charge or polarization are formed in sidewalls located on one side and the other side of the source/drain diffusion regions with regard to the gate electrode, and

a quantity of electric charge flowing in one of the channel regions specified by selecting the prescribed word line, first bit line and second bit line changes according to an amount of the electric charge or polarization retained in one of the memory function bodies specified by selecting the prescribed word line, first bit line and second bit line.

According to the above-mentioned construction, by selecting a prescribed word line, a first bit line and a second bit line, the storage information of a specified memory function body can be subjected to rewrite or read.

Furthermore, the memory function body, which has the function to retain electric charge or polarization, is formed on the sidewalls of the gate electrode of the word line, and this memory function body is formed separately from the insulator that separates the channel region from the word line. Therefore, it is easy to form the insulator into a thin film and to restrain the short-channel effect. Therefore, the element can be scaled down in size, and the manufacturing cost can be reduced.

Furthermore, the memory elements adjoining in the first direction (the memory element is defined by the gate electrode, the memory function bodies formed on the sidewalls located on opposite sides of this gate electrode and the source/drain diffusion regions adjoining with respect to this gate electrode) share the diffusion region, and therefore, the area of the memory elements can be largely reduced. Therefore, the integration degree of the semiconductor storage device is further improved, and the manufacturing cost can be reduced.

Moreover, example embodiments of the present invention preferably include a semiconductor storage device comprising:

element isolation regions formed at a surface of a semiconductor substrate;

active regions other than the element isolation regions are formed at the surface of the semiconductor substrate, wherein the active regions extend in a first direction and are arranged in a second direction intersecting with the first direction;

a plurality of source/drain diffusion regions which operate as a source or a drain and are formed in each of the active regions;

channel regions defined between the source/drain diffusion regions that adjoin in an identical active region;

a plurality of word lines extending in the second direction provided on the semiconductor substrate, each of the word lines being located on the channel regions of the active regions, with an insulator disposed between each of the word lines and the semiconductor substrate; and

a plurality of bit lines extending in the first direction provided on the semiconductor substrate, wherein

regarding one of the active regions connected to the adjoining two bit lines, one of the two bit lines is connected to one of the source/drain diffusion regions formed on the active region, and the other of the two bit lines is connected to the other one of the source/drain diffusion regions formed on the active region,

each of the word lines functions as a gate electrode on the channel region,

the insulator functions as a gate insulator on the channel region,

memory function bodies having a function to maintain electric charge or polarization are formed in sidewalls located on one side and the other side of the source/drain diffusion regions with regard to the gate electrode,

a memory element is defined by the gate electrode, the memory function bodies formed in the sidewalls located on opposite sides of this gate electrode and the source/drain diffusion regions adjoining regarding this gate electrode, and

a quantity of electric charge flowing in one of the channel regions specified by selecting the prescribed word line and mutually adjoining two bit lines changes according to an amount of the electric charge or polarization retained in one of the memory function bodies specified by selecting the prescribed word line and the mutually adjoining two bit lines.

According to the above-mentioned construction, by selecting a prescribed word line and mutually adjacent two bit lines, the storage information of a specified memory function body can be subjected to rewrite or read.

Furthermore, the memory function body, which has the function to retain electric charge or polarization, is formed on the sidewalls of the gate electrode of the word line, and this memory function body is formed separately from the insulator that separates the channel region from the word line. Therefore, it is easy to form the insulator into a thin film and to restrain the short-channel effect. Therefore, the element can be scaled down in size, and the manufacturing cost can be reduced.

Furthermore, one bit line extended in the first direction is shared by two active regions extended in this first direction, and therefore, the area of the memory elements can be largely reduced. Therefore, the integration degree of the semiconductor storage device is further improved, and the manufacturing cost can be reduced.

Moreover, example embodiments of the present invention preferably include a semiconductor storage device comprising:

element isolation regions formed at a surface of a semiconductor substrate;

active regions other than the element isolation regions are formed at the surface of the semiconductor substrate, wherein the active regions extend in a first direction and are arranged in a second direction intersecting with the first direction;

a plurality of source/drain diffusion regions which operate as a source or a drain and are formed in each of the active regions;

channel regions defined between the source/drain diffusion regions that adjoin in an identical active region;

a plurality of word lines extending in the second direction provided on the semiconductor substrate, each of the word lines being located on the channel regions of the active regions, with an insulator disposed between each of the word lines and the semiconductor substrate; and

a plurality of bit lines extending in the first direction provided on the semiconductor substrate, wherein

concerning successively adjoining first bit line, second bit line and third bit line, a first active region is connected to the first bit line and the second bit line, and a second active region is connected to the second bit line and the third bit line,

the second bit line is connected to one of the source/drain diffusion regions formed in the first active region and connected to one of the source/drain diffusion regions formed in the second active region,

the first bit line is connected to the other of the source/drain diffusion regions formed in the first active region,

the third bit line is connected to the other of the source/drain diffusion regions formed in the second active region,

each of the word lines functions as a gate electrode on the channel region,

the insulator functions as a gate insulator on the channel region,

a memory function bodies having a function to maintain electric charge or polarization are formed in sidewalls located on one side and the other side of the source/drain diffusion regions with regard to the gate electrode,

a memory element is defined by the gate electrode, the memory function bodies formed in the sidewalls located on opposite sides of this gate electrode and the source/drain diffusion regions adjoining regarding this gate electrode, and

a quantity of electric charge flowing in one of the channel regions specified by selecting the prescribed word line and mutually adjoining two bit lines changes according to an amount of the electric charge or polarization retained in one of the memory function bodies specified by selecting the prescribed word line and the mutually adjoining two bit lines.

According to the above-mentioned construction, by selecting a prescribed word line and mutually adjacent two bit lines, the storage information of a specified memory function body can be subjected to rewrite or read.

Furthermore, the memory function body, which has the function to retain electric charge or polarization, is formed on the sidewalls of the gate electrode of the word line, and this memory function body is formed separately from the insulator that separates the channel region from the word line. Therefore, it is easy to form the insulator into a thin film and to restrain the short-channel effect. Therefore, the element can be scaled down in size, and the manufacturing cost can be reduced.

Further, if the prescribed source/drain diffusion region, which belongs to the first active region, is one of the source/drain diffusion regions, then the source/drain diffusion region, which is the source/drain diffusion region adjacent to this prescribed source/drain diffusion region in the second direction and belongs to the second active region, also serves as one of the source/drain diffusion regions. That is, the source/drain diffusion region that is the source/drain diffusion region placed between adjoining two word lines and belongs to the first active region, and the source/drain diffusion region that belongs to the second active region have same operation as a source or a drain. Therefore, the interconnection, which connects the bit line with the source/drain diffusion region, can be simplified. As a result, the integration degree of the semiconductor storage device is further improved, and the manufacturing cost can be reduced.

Moreover, example embodiments of the present invention preferably include a semiconductor storage device comprising:

a semiconductor substrate having an element isolation region and an active region at its surface;

a plurality of memory elements that are a plurality of field-effect transistors formed in the active region and arranged in a matrix form;

a plurality of word lines each connected to gate electrodes of the memory elements of an identical row; and

a plurality of bit lines each connected in common to source/drain diffusion regions of the memory elements of an identical column via contacts, wherein

concerning adjoining two bit lines, one of the bit lines is electrically connected to one of the source/drain diffusion regions of an identical column, and the other one of the bit lines is electrically connected to the other of the source/drain diffusion regions of the identical column,

the memory element comprises:

the gate electrode formed on the semiconductor substrate, with a gate insulator disposed therebetween;

two memory function bodies that are formed on opposite sides of the gate electrode and have a function to retain electric charge or polarization;

a channel region arranged below the gate insulator; and

the source/drain diffusion regions arranged on opposite sides of the channel region, and wherein

a quantity of a current, which flows from one of the source/drain diffusion regions to the other of the source/drain diffusion regions when a voltage is applied to the gate electrode changes according to an amount of electric charge or polarization retained in the memory function body.

According to the above-mentioned construction, the two formed memory function bodies formed on opposite sides of the gate electrode are independent from the gate insulator, and therefore, the memory function undertaken by the memory function bodies and the transistor operation function undertaken by the gate insulator are separated from each other. With this arrangement, it is easy to form the gate insulator into a thin film with a sufficient memory function possessed and to restrain the short-channel effect. Therefore, the memory element can be scaled down in size, and therefore, it is possible to easily scale down the size of the memory element and to reduce the manufacturing cost.

Moreover, the two memory function bodies formed on opposite sides of the gate electrode are separated by the word line, and therefore, interference during rewrite is effectively restrained. In other words, the two memory function bodies are separated by the gate electrode, and therefore, the distance between the two memory function bodies can be reduced. Therefore, the memory element can be further scaled down in size.

Moreover, the memory function bodies are formed on opposite sides of the gate electrode, and therefore, a memory cell array memory cell that has a structure in which the memory function bodies are physically separated from each other, can be provided.

Moreover, by selecting specified word line and bit line, it becomes possible to rewrite or read the storage information of a specified memory function body.

Moreover, example embodiments of the present invention preferably include a semiconductor storage device comprising:

a semiconductor substrate having an element isolation region and an active region at its surface;

a plurality of memory elements that are a plurality of field-effect transistors formed in the active region and arranged in a matrix form;

a plurality of word lines connected to gate electrodes of the memory elements; and

a plurality of bit lines connected to source/drain diffusion regions of the memory elements, wherein

concerning adjoining two bit lines, one of the bit lines is electrically connected to one of the source/drain diffusion regions of an identical column, and the other one of the bit lines is electrically connected to the other of the source/drain diffusion regions of the identical column,

the memory elements adjoining in an identical row share one of the source/drain diffusion regions,

the memory elements adjoining in an identical column share one of the source/drain diffusion regions, and

the memory element comprises:

the gate electrode formed on the semiconductor substrate, with a gate insulator disposed therebetween;

two memory function bodies that are formed on opposite sides of the gate electrode and have a function to retain electric charge or polarization;

a channel region arranged below the gate insulator; and

the source/drain diffusion regions arranged on opposite sides of the channel region, and wherein

a quantity of a current, which flows from one of the source/drain diffusion regions to the other of the source/drain diffusion regions when a voltage is applied to the gate electrode changes according to an amount of electric charge or polarization retained in the memory function body.

According to the above-mentioned construction, a memory function body, which has a function to retain electric charge or a function to retain polarization, is formed on the sidewalls of the word line. This memory function body is formed separately from the insulator (gate insulator) that separates the channel region from the word electrode. With this arrangement, it is easy to form the insulator into a thin film and to restrain the short-channel effect. Therefore, the memory element can be scaled down in size, and the manufacturing cost can be reduced.

Furthermore, the memory elements adjoining in an identical row share one of the source/drain diffusion regions, while the memory elements adjoining in an identical column share one of the source/drain diffusion regions. That is, one source/drain diffusion region is shared by four field-effect transistors. Therefore, the number of bit lines is reduced, and the number of contact holes, which connect the bit lines to the source/drain diffusion regions, is also reduced. Therefore, the margins of the bit lines and the contact holes are small, and therefore, it becomes possible to further shrink the semiconductor storage device and to reduce the manufacturing cost.

In one embodiment, the contact is connected in common to the source/drain diffusion regions adjoining in an identical row.

That is, in the semiconductor storage device of the above-mentioned embodiment, two source/drain diffusion regions adjoining in the identical row share one bit line. Therefore, the area occupied by the element isolation region can be reduced, and the element isolation configuration can be simplified. This therefore enables the achievement of a high integration degree and further reduction of the manufacturing cost.

Moreover, by sharing the source/drain diffusion region by the memory elements adjoining in an identical column, the memory cell area can be largely reduced.

In one embodiment, the contact has an elliptic cylindrical configuration.

According to the semiconductor storage device of the above-mentioned embodiment, the formation of the contact can be made simple, a semiconductor storage device of a small occupation area is provided by narrowing the bit line interval.

In one embodiment, the contact is electrically connected to the source/drain diffusion regions via a conductor having an elliptical plate configuration.

According to the semiconductor storage device of the above-mentioned embodiment, a high-density memory can be achieved even when the etching apparatus has restrictions.

In one embodiment, the memory function body includes an insulation film and a plurality of dot-shaped metal bodies formed in the insulation film, and

the metal bodies have diameters within a range of 0.1 nm to 20 nm.

According to the semiconductor storage device of the above-mentioned embodiment, it becomes possible to achieve operation with a lower voltage for the achievement of low power consumption. Otherwise, it becomes possible to execute operation at higher speed and to provide a high-speed memory.

In one embodiment, the semiconductor storage device comprises a liquid crystal display driver.

According to the semiconductor storage device of the above-mentioned embodiment, a high-performance LCD driver can be manufactured at low cost by incorporating a memory for storing the initial values and so on of the LCD driver built into the LCD driver.

In one embodiment, the word lines are each extended meandering, and

a distance in a direction parallel to the direction in which the bit lines extend between the adjoining two word lines is shorter on the element isolation region than on the active region.

According to the semiconductor storage device of the above-mentioned embodiment, the word lines extend meandering. Between the adjoining two word lines among the plurality of word lines, the distance in the direction parallel to the direction in which the bit lines are extended is shorter on the element isolation region than on the active region. With this arrangement, the length of the element isolation region can be reduced while maintaining a margin between the connection portion of the bit line and the source/drain diffusion region and the word line. That is, the surface area of the element isolation region can be reduced while securing the margin of the word line with respect to the connection portion. Therefore, when the memory elements are employed as the memory cells of a memory cell array, it becomes possible to further shrink (or densify) the memory cell array and to reduce the manufacturing cost.

In one embodiment, the memory function bodies are handled as independent storage units to be subjected to rewrite operation and read operation.

According to the above-mentioned embodiment, one memory element is easily multivalued. Therefore, it is possible to further increase the capacity of the semiconductor storage device and to reduce the manufacturing cost.

Moreover, one memory element can store data of two bits or more, and therefore, the cost per bit unit is further reduced.

Moreover, when the memory elements are employed as the memory cells of a memory cell array, one memory element is easily multivalued. As a result, it is possible to further increase the capacity of the semiconductor storage device and to reduce the manufacturing cost.

In one embodiment, at least part of the memory function body is formed so as to overlap with part of the source/drain diffusion region.

According to the above-mentioned embodiment, the read speed of the semiconductor storage device can be made sufficiently high.

In one embodiment, the memory function body comprises a charge retention film that has a function to retain electric charge, and

the charge retention film has a portion roughly parallel to a surface of the gate insulator.

According to the above-mentioned embodiment, variations in the memory effect of the memory elements that constitute the semiconductor storage device can be reduced, and therefore, variations in the read current of the semiconductor storage device can be restrained. Furthermore, the characteristic change of the memory element during storage retention can be reduced, and therefore, the storage retention characteristic of the semiconductor storage device is improved.

In one embodiment, the memory function body comprises a charge retention film that has a function to retain electric charge, and

the charge retention film has a portion roughly parallel to the surface of the gate insulator and a portion roughly parallel to a side surface of the gate electrode.

According to the above-mentioned embodiment, the rewrite operation of the semiconductor storage device can be executed at high speed.

In one embodiment, the semiconductor storage device further comprises an insulation film, wherein

the memory function body comprises a charge retention film that has a function to retain electric charge,

the charge retention film has a portion roughly parallel to the surface of the gate insulator,

the insulation film is disposed between the portion of the charge retention film and the semiconductor substrate, and

a thickness of the insulation film is smaller than a thickness of the gate insulator and not smaller than 0.8 nm.

According to the above-mentioned embodiment, it becomes possible to lower the voltage of the write operation and erase operation of the semiconductor storage device and execute the write operation and the erase operation at high speed. Furthermore, the memory effect of the memory elements that constitute the semiconductor storage device is increased, and therefore, the read speed of the semiconductor storage device can be increased.

Moreover, by making the thickness of the insulation film formed between the charge retention film and the active region smaller than the thickness of the gate insulator and not smaller than 0.8 nm, the reliability of the memory element can be improved.

In one embodiment, the semiconductor storage device further comprises an insulation film, wherein

the memory function body comprises a charge retention film that has a function to retain electric charge,

the charge retention film has a portion roughly parallel to the surface of the gate insulator,

the insulation film is disposed between the portion of the charge retention film and the semiconductor substrate, and

a thickness of the insulation film is greater than the thickness of the gate insulator and not greater than 20 nm.

According to the above-mentioned embodiment, the retention characteristic can be improved without degrading the short-channel effect of the memory elements that constitutes the semiconductor storage device. Therefore, a sufficient storage retention performance can be obtained even if the semiconductor storage device is made to have a high integration degree.

In one embodiment, the memory function body comprises:

a silicon nitride film, and

two silicon oxide films, and wherein

the silicon nitride film is disposed between the two silicon oxide films.

According to the above-mentioned embodiment, the efficiency of charge injection into the memory function body is increased during rewrite operation, and the semiconductor storage device can be operated at higher speed.

Moreover, since the structure in which the silicon nitride film is placed between the silicon oxide films can be manufactured through almost the same processes as those of a logic LSI (Large Scale Integrated circuit), there can be provided the processes of an LSI in which a memory and a logic circuit are consolidated.

Moreover, example embodiments of the present invention preferably include a method for operating the semiconductor storage device, wherein,

regarding a selecting memory element that is the memory element to which the memory function body to be operated belongs,

before a potential for executing operation is applied to the word line connected to the selecting memory element,

one of two bit lines connected to the selecting memory element is precharged with a first potential and the other is precharged with a second potential,

a bit line located adjacently on a side opposite from the other bit line concerning the one bit line is precharged with the first potential, and

a bit line located adjacently on a side opposite from the one bit line concerning the other bit line is precharged with the second potential.

According to the operation method of the above-mentioned construction, one of the two bit lines connected to the selected memory element is precharged with the first potential, and the other is precharged with the second potential. Therefore, the information of the desired memory function body can be speedily read after the potential for executing operation is applied to the word line connected to the selected memory element. That is, the semiconductor storage device can be operated with high efficiency at high speed.

Moreover, random access read, write and erase operations can be achieved by a comparatively simple control circuit.

Moreover, the occupation area of the memory can be reduced.

Furthermore, the bit line located adjacently on the side opposite from the other bit line is precharged with the first potential regarding the one bit line, while the bit line located adjacently on the side opposite from the one bit line is precharged with the second potential regarding the other bit line. By this operation, in detecting the current flowing in the selected memory element, a noise current can be reduced. As a result, a semiconductor storage device of reduced malfunction can be obtained.

Moreover, example embodiments of the present invention preferably include a semiconductor device comprising the semiconductor storage device, a column decoder, a sense amplifier and a row decoder, wherein

at least one of the column decoder, the sense amplifier and the row decoder and the semiconductor storage device are formed on an identical semiconductor substrate.

According to the above-mentioned construction, the rewrite and read operations can be executed by selecting a specified memory element. Furthermore, it is possible to easily consolidate normal transistors that constitute logic circuits of a column decoder, a sense amplifier, a row decoder and so on and an analog circuit the semiconductor storage device of the present invention, and therefore, the semiconductor device is provided at low cost through easy manufacturing processes.

Moreover, the semiconductor device may include the column decoder, the sense amplifier and the row decoder so as to be constructed of one chip. In this case, a high-speed nonvolatile high-density memory can be provided.

Moreover, example embodiments of the present invention preferably include a portable electronic equipment comprising the semiconductor storage device.

According to the above-mentioned construction, by employing the semiconductor storage device, the capacity of the nonvolatile memory included in the control circuit can be increased, and the functions of the portable electronic equipment can be improved.

Moreover, the semiconductor storage device has low power consumption, high speed and nonvolatility. Therefore, the functions, which have been produced by using a plurality of components, can be achieved only by the semiconductor storage device. As a result, there can be provided portable electronic equipment that has low power consumption, a small parts count and a small size.

Moreover, by employing the aforementioned semiconductor storage device for the portable electronic equipment, the capacity of the nonvolatile memory included in the control circuit can be increased, and the functions of the portable electronic equipment can be improved.

Moreover, example embodiments of the present invention preferably include a portable electronic equipment comprising a semiconductor device, wherein

the semiconductor device comprises:

the semiconductor storage device,

a column decoder,

a sense amplifier, and

a row decoder, and wherein

at least one of the column decoder, the sense amplifier and the row decoder and the semiconductor storage device are formed on an identical semiconductor substrate.

According to the above-mentioned construction, the manufacturing cost of the control circuit is reduced by employing the semiconductor device, and therefore, the cost of the portable electronic equipment can be reduced.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic sectional view of the memory element of the first embodiment of the present invention;

FIG. 2 is a view showing a modification example of the memory element of the first embodiment;

FIG. 3 is a view for explaining write operation of the memory element of the first embodiment;

FIG. 4 is a view for explaining write operation of the memory element of the first embodiment;

FIG. 5 is a view for explaining erase operation of the memory element of the first embodiment;

FIG. 6 is a view for explaining erase operation of the memory element of the first embodiment;

FIG. 7 is a view for explaining read operation of the memory element of the first embodiment;

FIG. 8 is a schematic sectional view showing the memory element of the second embodiment;

FIG. 9 is a sectional view of a portion of the memory element of FIG. 8;

FIG. 10 is a partial sectional view showing a modification example of the memory element of the second embodiment;

FIG. 11 is a graph showing the electrical characteristic of the memory element of the second embodiment;

FIG. 12 is a partial sectional view showing a modification example of the memory element of the second embodiment;

FIG. 13 is a partial sectional view of the memory element of the third embodiment;

FIG. 14 is a partial sectional view of the memory element of the fourth embodiment;

FIG. 15 is a partial sectional view of the memory element of the fifth embodiment;

FIG. 16 is a partial sectional view of the memory element of the sixth embodiment;

FIG. 17 is a partial sectional view of the memory element of the seventh embodiment;

FIG. 18 is a partial sectional view of the memory element of the eighth embodiment;

FIG. 19 is a graph showing the electrical characteristic of the memory element of the ninth embodiment;

FIG. 20 is a plan view showing the semiconductor storage device of the tenth embodiment;

FIG. 21 is a sectional view taken along the line 21-21 of FIG. 20;

FIG. 22 is a sectional view taken along the line 22-22 of FIG. 20;

FIG. 23 is a circuit diagram of the semiconductor storage device of the tenth embodiment;

FIG. 24 is a plan view showing the semiconductor storage device of the eleventh embodiment;

FIG. 25 is a sectional view taken along the line 25-25 of FIG. 24;

FIG. 26 is a plan view showing the semiconductor storage device of the twelfth embodiment;

FIG. 27 is a sectional view taken along the line 27-27 of FIG. 26;

FIG. 28 is a circuit diagram of the semiconductor storage device of the twelfth embodiment;

FIG. 29 is a view for explaining the arrangement of first layer metal interconnections of the semiconductor storage device of the twelfth embodiment;

FIG. 30 is a plan view showing the semiconductor storage device of the thirteenth embodiment;

FIG. 31 is a sectional view taken along the line 31-31 of FIG. 30;

FIG. 32 is a view for explaining the arrangement of first layer metal interconnections of the semiconductor storage device of the thirteenth embodiment;

FIG. 33 is a view for explaining the semiconductor storage device of the fourteenth embodiment of the present invention, in which the schematic sectional views of a memory element that constitutes a memory cell array and a switching element that constitutes a logic circuit section are compared with each other while being juxtaposed;

FIG. 34 is a block diagram of the semiconductor storage device of the fourteenth embodiment;

FIG. 35 is a block diagram showing the portable electronic equipment of the fifteenth embodiment of the present invention;

FIG. 36 is a schematic plan view of the memory cell array of the sixteenth embodiment of the present invention;

FIG. 37 is a schematic sectional view taken along the line 37-37 of FIG. 36;

FIG. 38 is a schematic sectional view taken along the line 38-38 of FIG. 36;

FIG. 39 is a circuit diagram of the memory cell array of the sixteenth embodiment;

FIG. 40 is a schematic plan view of a modification example of the memory cell array of the sixteenth embodiment;

FIG. 41 is a schematic plan view of the memory cell array of the seventeenth embodiment of the present invention;

FIG. 42 is a schematic sectional view taken along the line 42-42 of FIG. 41;

FIG. 43 is a schematic plan view of the memory cell array of the eighteenth embodiment of the present invention;

FIG. 44 is a view for explaining the arrangement of the first layer metal interconnections of the memory cell array of the eighteenth embodiment;

FIG. 45 is a view for explaining the forming process of the memory cell of the memory cell array of the nineteenth embodiment of the present invention;

FIG. 46 is a schematic sectional view of the memory cell array of the nineteenth embodiment;

FIG. 47 is a schematic sectional view of another memory cell array of the nineteenth embodiment;

FIG. 48 is a view for explaining the arrangement of metal interconnections of the memory cell array of the nineteenth embodiment;

FIG. 49 is a schematic plan view of a modification example of the memory cell array of the nineteenth embodiment;

FIG. 50 is a schematic plan view of the semiconductor storage device of the twenty-first embodiment of the present invention;

FIG. 51 is a schematic sectional view taken along the line 51-51 of FIG. 50;

FIG. 52 is a schematic sectional view taken along the line 52-52 of FIG. 50;

FIG. 53 is a schematic sectional view taken along the line 53-53 of FIG. 50;

FIG. 54 is a circuit diagram of the semiconductor storage device of the twenty-first embodiment;

FIG. 55 is a schematic plan view of the semiconductor storage device of the twenty-second embodiment of the present invention;

FIG. 56 is a block diagram showing the portable electronic equipment of the twenty-third embodiment of the present invention;

FIG. 57 is a schematic plan view of a conventional flash memory cell array;

FIG. 58 is a sectional view taken along the cross-sectional line 58-58 of FIG. 57; and

FIG. 59 is a graph showing the electrical characteristic of a conventional flash memory.

### DETAILED DESCRIPTION

The semiconductor storage device (memory cell array) of the present invention is constituted by arranging memory elements that can store 2-bit information and are able to be easily scaled down in size and easily formed.

An outline of a memory element to be employed in the semiconductor storage device of the present invention will be described first.

The memory element employed in the semiconductor storage device of the present invention is constructed mainly of first conductivity type regions that are diffusion regions, a second conductivity type region, memory function bodies each straddling the border between the first and second conductivity type regions, and a gate electrode on a gate insulation film, or mainly of a gate insulation film, a gate electrode on the gate insulation film, memory function bodies on opposite sides of the gate electrode, source/drain regions (diffusion regions) which are each formed on opposite sides of the gate electrode with regards to the memory function bodies, and a channel region arranged below the gate electrode.

The memory element functions as a memory device storing four-valued or more information by storing binary or more information in one charge retention film. The memory element also functions as a memory device having a selector transistor function and a memory transistor function because of the variable resistance effect of the memory function body. However, the memory element does not necessarily need to store four-valued or more information, but it may also function to store, for example, binary information.

It is preferable that the semiconductor storage device of the present invention is formed on a semiconductor substrate as the semiconductor layer, preferably in a first conductivity type well region formed in the semiconductor substrate.

The semiconductor substrate is not limited to particular ones as far as it is applicable to semiconductor apparatuses, and it is possible to use various substrates such as bulk substrates made from elemental semiconductors such as silicon and germanium, or compound semiconductors such as SiGe, GaAs, InGaAs, ZnSe, and GaN; SOI (Silicon on Insulator) substrates; multilayer SOI substrates, and substrates having a semiconductor layer on a glass or plastic substrate. Among others, a silicon substrate or an SOI substrate having a silicon layer formed as a surface semiconductor layer is preferable. The semiconductor substrate or the semiconductor layer may be monocrystal (e.g., a single crystal obtained by epitaxial growth), polycrystalline, or amorphous, though a current amount flowing inside will be slightly different among them.

On the semiconductor substrate or the semiconductor layer, it is preferable that device isolation regions are formed. Elements such as transistors, capacitors and resistors, circuits composed of such elements, semiconductor devices, and an inter-layer insulation film or films may be formed in combination in a single or a multilayer structure on the semiconductor substrate or the semiconductor layer. It is noted that the device isolation regions may be formed by any of various device isolation films including a LOCOS (local oxidation of silicon) film, a trench oxide film, and an STI (Shallow Trench Isolation) film. The semiconductor substrate or the semiconductor layer may be either of a P type or an N type conductivity type, and it is preferable that at least one first conductivity type (P type or N type) well region is formed in the semiconductor substrate. Acceptable impurity concentrations of the semiconductor layer and the well region are those within the range known in the art. It is noted that in the case of using an SOI substrate as the semiconductor layer, a well region may be formed in the surface semiconductor layer, and also a body region may be provided under the channel region.

Materials of the gate insulation film or the insulation film are not particularly limited as far as they are usable in typical semiconductor apparatuses. For example, insulation films including a silicon oxide film and a silicon nitride film, and high-dielectric films including aluminum oxide films, titanium oxide films, tantalum oxide films, hafnium oxide films are usable in the form of a single-layer film or a multi-layer film. Among others, the silicon oxide film is preferable. An appropriate thickness of the gate insulation film is, for example, approx. 1 to 20 nm, preferably 1 to 6 nm. The gate insulation film may be only formed right under the gate electrode, or may be formed to be larger (in width) than the gate electrode.

The gate electrode or electrode is formed on the gate insulation film normally in a shape for use in a semiconductor device or a shape that has a concave portion in a lower end portion. Herein, the “single gate electrode” is defined as a gate electrode consisting of a monolayer or multilayer conductive film and formed into a single inseparable piece. The gate electrode may have a side wall insulation film on each side surface. The gate electrode is normally not specifically limited so long as it is used for a semiconductor device, and there can be enumerated conductive films of: polysilicon; metals including copper and aluminum; high melting point metals including tungsten, titanium, and tantalum; and silicides of high melting point metals, in the form of a single-layer or a multi-layer. The gate electrode should properly be formed with a film thickness of, for example, about 50 to 400 nm. It is to be noted that a channel region is formed under the gate electrode.

The memory function body includes a film or region that has a function to store and retain charges, trap charges or retain a charge polarized state. Materials implementing these functions include: silicon nitride; silicon; silicate glass including impurities such as phosphorus or boron; silicon carbide; alumina; high-dielectric substances such as hafnium oxide, zirconium oxide, or tantalum oxide; zinc oxide; ferroelectric substance; and metals. The memory function body may be formed into single-layer or multi-layer structure of: for example, an insulation film containing a silicon nitride film; an insulation film incorporating a conductive film or a semiconductor layer inside; an insulation film containing one or more conductor dots or semiconductor dots; and an insulation film incorporating a ferroelectric film whose polarization direction is changed by an electric field and the state of the polarization is retained. Among these, the silicon nitride is preferable because it can achieve a large hysteresis property by the presence of a number of levels for trapping electric charges, and has good holding characteristics in that the electric-charge holding time is long and that there hardly occurs leakage of electric charges caused by generation of leakage paths, and further because it is a material normally used in LSI process.

Use of an insulation film containing inside an insulation film having a charge holding function such as a silicon nitride film enables increase of reliability relating to memory holding. Since the silicon nitride film is an insulator, electric charges of the entire silicon nitride film will not be immediately lost even if part of the electric charges are leaked. Further, in the case of arraying a plurality of memory elements, even if the distance between the memory elements is shortened and adjacent memory function bodies come into contact with each other, information stored in each memory function body is not lost unlike the case where the memory function body is made from a conductor. Also, it becomes possible to dispose a contact plug closer to the memory function body, or in some cases it becomes possible to dispose the contact plug so as to overlap with the memory function body, which facilitates miniaturization of the memory elements.

For further increase of the reliability relating to the memory holding, the insulator having a function of holding electric charges is not necessarily needed to be in the film shape, and insulators having the function of holding an electric charge may preferably be present in an insulation film in a discrete manner. More specifically, such insulators may be dispersed like dots within a material having difficulty in holding electric charges, such as silicon oxide.

Also, use of an insulator film containing inside a conductive film or a semiconductor layer as a charge holding portion enables free control of the quantity of electric charges injected into the conductor or the semiconductor, thereby bringing about an effect of facilitating achieving a multi-valued memory cell.

Further, using an insulator film containing one or more conductor or semiconductor dots as a memory function body facilitates execution of write and erase by direct tunneling of electric charges, thereby bringing about an effect of reduced power consumption.

Moreover, it is acceptable to use, as a memory function body, a ferroelectric film such as PZT (lead zirconate titanate) and PLZT (lead lanthanum zirconate titanate) whose polarization direction is changed by an electric field. In this case, electric charges are substantially generated by polarization on the surface of the ferroelectric film and retained in the state. Therefore, electric charges are supplied from outside the film that has the memory function, and a hysteresis characteristic similar to that of the film that traps electric charges can be obtained. In addition, since there is no need to inject electric charges from outside the film and the hysteresis characteristic can be obtained only by the polarization of the electric charges in the film, high-speed write and erase is achievable.

It is preferable that the memory function body further contains a region that obstructs escape of electric charges or a film having a function of obstructing escape of electric charges. Materials fulfilling the function of obstructing escape of electric charges include a silicon oxide.

Preferably, the charge retention film contained in the memory function body is formed on opposite sides of the gate electrode directly or via an insulation film, and it is disposed on the semiconductor substrate (a well region, a body region, or a source/drain region or a diffusion region) via the gate insulation film or the insulation film. The charge retention films on opposite sides of the gate electrode are preferably formed so as to cover all or part of side surfaces of the gate electrode directly or via the insulation film. In an application where the gate electrode has a recess portion on the lower edge side, the charge retention film may be formed so as to fill the entire recess portion or part of the recess portion directly or via the insulation film.

Preferably, the gate electrode is disposed only on the side of the memory function body, or the upper portion of the memory function body is not covered with the gate electrode. In such arrangement, it becomes possible to dispose a contact plug closer to the gate electrode, which facilitates miniaturization of the memory elements. Also, the memory elements having such simple disposition are easily manufactured, resulting in an increased process yield.

If a conductive film is used as a charge retaining film, it is preferable to place an insulation film such that the charge retaining film does not touch the semiconductor substrate (well region, body region, source/drain region, or diffusion region) or the gate electrode. For example, there may be a stacked structure of a conductive film and an insulation film, a structure in which dots of a conductive film is scattered in an insulation film, a structure in which the conductive or semiconductor charge retention film is included in a side wall insulation film on a side surface of the gate, etc.

The source/drain region is each disposed on the other side of the gate electrode with regard to the charge retaining film. The source/drain region has a conductivity type opposite to that of the semiconductor layer or the well region. A junction of the diffusion region and the semiconductor layer or the well region should preferably have a steep slope of impurity concentration. The reason for the above is that hot electrons and hot holes are efficiently generated at a low voltage, and high-speed operation can be achieved at a lower voltage. The junction depth of the diffusion region is not specifically limited and is allowed to be properly adjusted according to the performance and so on of the semiconductor storage device desired to be obtained. When a SOI substrate is employed as a semiconductor substrate, the diffusion region may have a junction depth smaller than the thickness of the surface semiconductor layer. However, the diffusion region should preferably have a junction depth almost equal to the thickness of the surface semiconductor layer.

The source/drain region may be arranged so as to overlap with the gate electrode end or arranged so as to meet the gate electrode end or arranged so as to be offset with respect to the gate electrode end. In particular, in the case of offset, the easiness of inversion of the offset region under the charge retaining film is largely changed by the quantity of charges accumulated in the memory function body when the voltage is applied to the gate electrode, increasing the memory effect and reducing the short-channel effect. Therefore, this arrangement is preferable. However, since a drive current between the source and drain regions is significantly reduced if the offset is excessive, it is preferred that the amount of offset, i.e., a distance from one gate electrode end to the nearer source/drain region end in the direction of the gate length should preferably be shorter than the thickness of the charge retaining film in the direction parallel to the gate length direction. What is particularly important is that at least part of the film or region having the charge retention function in the memory function body overlaps with part of the source/drain region. The reason for the above is that the essence of the memory elements that constitute the semiconductor storage device of the present invention is to rewrite the storage by the electric field intersecting the memory function body due to a voltage difference between the gate electrode and the source/drain region existing only in the side wall portion of the memory function body.

The source/drain region may be partially extended to a position higher than the surface of the channel region, i.e., the lower surface of the gate insulation film. In this case, it is proper that a conductive film integrated with this source/drain region is constructed while being laminated on the source/drain region formed in the semiconductor substrate. As the conductive film, there can be enumerated, for example, semiconductor of polysilicon, amorphous silicon or the like, silicide, aforementioned metals, high-melting-point metals and so on. Among others, polysilicon is preferable. The reason for the above is that the polysilicon, of which the impurity diffusion speed is significantly greater than that of the semiconductor layer, easily tolerates a shallowed junction depth of the diffusion region in the semiconductor layer and easily suppresses the short-channel effect. In this case, it is preferable to provide an arrangement that part of this source/drain region and the gate electrode hold at least part of the memory function body therebetween.

The memory element of the present invention can be formed by the ordinary semiconductor process according to a method similar to the method of forming a side wall spacer of a single layer or laminate structure on the side wall of the gate electrode or word line. In concrete, there can be enumerated: a method comprising forming a gate electrode or an electrode, thereafter forming a single layer film or multilayer film including a charge retaining film, a charge retaining film/insulation film, an insulation film/charge retaining film, and an insulation film/charge retaining film/insulation film, and leaving the film or films in a side wall spacer shape by etching back under appropriate conditions; a method comprising forming an insulation film or a charge retaining film, leaving the film in a side wall spacer shape by etching back under appropriate conditions, further forming a charge retaining film or insulation film and leaving the film in a side wall spacer shape by etching back under appropriate conditions; a method comprising coating or depositing, on a semiconductor wafer including a gate electrode, an insulation film material in which a particulate charge retaining material is distributed, and leaving the insulation film material in a side wall spacer shape by etching back under appropriate conditions; a method comprising forming a gate electrode, thereafter forming the single layer film or the multilayer film and carrying out patterning by using a mask, and so on. Moreover, there can be enumerated a method comprising forming a charge retaining film, a charge retaining film/insulation film, an insulation film/charge retaining film, or an insulation film/charge retaining film/insulation film before forming a gate electrode or an electrode, forming an opening through the film or films in a region that becomes a channel region, forming a gate electrode material film on the entire upper surface of the wafer and patterning this gate electrode material film in a shape, which is larger than the opening in size and encompasses the opening.

When a memory cell array is constructed by arranging the memory elements of the present invention, the best mode of the memory elements is to satisfy, for example, all the required conditions:

(1) The function of a word line is possessed by the integrated body of the gate electrodes of a plurality of memory elements;

(2) Formed on each of opposite sides of the word line is a memory function body;

(3) A material that retains electric charges in the memory function body is an insulator, and in particular, a silicon nitride film;

(4) The memory function bodies are constructed of an ONO (Oxide Nitride Oxide) film, and the silicon nitride film has a surface roughly parallel to the surface of the gate insulation film;

(5) The silicon nitride film in each memory function body is separated from the word line and the channel region by the silicon oxide film;

(6) The insulation film (the silicon nitride film) in the memory function body overlaps with the diffusion region;

(7) The thickness of the insulation film, which separates the silicon nitride film that has a surface roughly parallel to the surface of the gate insulation film from the channel region or the semiconductor layer differs from the thickness of the gate insulation film;

(8) Write and erase operations of one memory element are executed by a single word line;

(9) There is no electrode (word line), on the upper side of each memory function body, which has a function to assist the write and erase operations; and

(10) A portion put in contact with the diffusion region right under each memory function body has a region where the impurity concentration of the conductivity type opposite to the conductivity type of the diffusion region is high.

The memory elements are not required to satisfy all of these requirements, but may satisfy at least one of these requirements.

When some of the above requirements are satisfied, there are most preferable combinations of requirements. For example, a most preferable combination resides in that (3) a material that retains electric charges in the memory function body is an insulator, and in particular, a silicon nitride film; (9) there is no electrode (word line), on the upper side of each memory function body, which has a function to assist the write and erase operations; and (6) the insulation film (the silicon nitride film) in the memory function body overlaps with the diffusion region. It was discovered that the insulator retained electric charge in the memory function body, and in the case where there was no electrode that had a function to assist write and erase operations on the memory function body, the write operation was executed satisfactorily only when the insulation film (silicon nitride) in the memory function body and the diffusion region overlapped each other. That is, it was discovered that satisfying the requirement (6) is indispensable when the requirements (3) and (9) were satisfied. On the other hand, in the case where the conductor retains electric charge in the memory function body, the write operation was able to be executed even when the conductor in the memory function body and the diffusion region did not overlap each other (because the conductor in the memory function body assisted write by capacitive coupling with the write electrode). Moreover, in the case where there was an electrode that had the function to assist write and erase operations on the memory function body, the write operation was able to be executed even when the insulation film in the memory function body and the diffusion region did not overlap each other.

However, in the case where electric charge is retained not by the conductor but by the insulator in the memory function body and there is no electrode that has the function to assist the write and erase operations on the memory function body, very large effects as described below can be obtained.

First, a bit line contact can be arranged closer to the memory function body located on the word line side wall, or even if the memory elements are put close to each other in distance, the plurality of memory function bodies do not interfere with one another, and the storage information can be retained. Therefore, the miniaturization of the memory elements is facilitated. When the charge retaining region in the memory function body consists of a conductor, interference occurs between the adjacent charge retaining regions by capacitive coupling as the distance between the memory elements is reduced, and the storage information cannot be retained.

Moreover, when the charge retaining region in the memory function body consists of an insulator (e.g., silicon nitride film), there is no need to make the memory function bodies of one memory cell independent of those of another memory cell. For example, the memory function bodies continuously formed on opposite sides of and along one word line shared by a plurality of memory cells are not required to be isolated every memory cell, and it is possible to share the memory function bodies formed on opposite sides of one word line by a plurality of memory cells that share the word line. Therefore, the photolithography and etching process for isolating the memory function bodies become unnecessary, and the manufacturing process is simplified. Furthermore, the alignment margin for the photolithography process and the film etching margin become unnecessary. Therefore, the margin between the memory cells can be reduced. Therefore, in comparison with the case where the charge retaining region in the memory function body consists of a conductor (e.g., polycrystalline silicon film), the memory cell occupation area can be miniaturized even if the same microfabrication level is applied. The case where the charge retaining region in the memory function body consists of a conductor would need the photolithography and etching process for separating the memory function bodies every memory cell, the photolithography alignment margin and the film etching margin.

Furthermore, since the element structure is simple in that no electrode having the function to assist the write (program) and erase operations is located on the upper side of the memory function bodies, the number of fabrication process steps is reduced, and the process yield can be improved. Therefore, combination with the transistors that constitute a logic circuit and an analog circuit can be facilitated.

Furthermore, as a very important design matter, we discovered that the write and erase were made possible with a very low voltage by overlapping the charge retention region in the memory function body with the diffusion region overlap even when the charge retention region in the memory function body was an insulator and there was no electrode that had the function to assist the write and erase operations on the memory function body (by satisfying the above-mentioned two requirements, there could be obtained the very important effects of shrinking the cell occupation area, improving the yield by simplifying the manufacturing method and reducing the cost). In concrete, we have ascertained that the write and erase operations can be executed at a low voltage of not higher than 5 V. This. operation produces a very large effect in terms of circuit design. There is no need to make a high voltage in a chip dissimilarly from the flash memory, and therefore, a charge pump circuit, which requires an enormous occupation area, can be eliminated or reduced in scale. Particularly, when a small-scale capacity memory for adjustment is built in a logic LSI, the occupation area of the memory section is dominated by the occupation area of the peripheral circuit for driving the memory cells than the memory cells. Therefore, it is most effective to eliminate or reduce the scale of the memory cell voltage booster circuit in order to reduce the chip size.

This is why satisfying the requirements (3), (9) and (6) is particularly preferable.

By being combined with a logic element, a logic circuit or the like, the semiconductor storage device of the present invention can be effectively widely applied to data processing systems of personal computers, notebook type computers, laptop type computers, personal assistant/transmitters, mini computers, workstations, mainframes, multi-processor computers or any other types of computers; electronic components that constitute a data processing system, such as CPU's, memories and data storage devices; communication equipment such as telephones, PHS's (Personal Handy phone Systems), modems and routers; image display equipment such as display panels and projectors; business machines such as printers, scanners and copiers; imaging equipment such as video cameras and digital cameras; amusement equipment such as game machines and music players; information equipment of portable information terminals, watches and electronic dictionaries; car equipment such as car navigation systems and car audio devices; AV (Audio Visual) equipment for recording and reproducing information of animations, still pictures and music; electrical appliances such as washing machines, microwave ovens, refrigerators, rice cookers, dish washers, vacuum cleaners and air conditioners; healthcare equipment such as massage machines, scales and sphygmomanometers; and electronic equipment such as portable storage devices of IC cards, memory cards and so on. In particular, the applications to the portable electronic equipment of portable telephones, portable information terminals, IC cards, memory cards, portable computers, portable game machines, digital cameras, portable animation players, portable music players, electronic dictionaries and watches are effective. It is to be noted that the semiconductor storage device of the present invention may be built in electronic equipment as at least part of a control circuit or a data storage circuit, or detachably mounted thereto at need.

Embodiments of the semiconductor storage device, the method for operating the semiconductor storage device, semiconductor device and portable electronic equipment of the present invention will be described in detail below with reference to the drawings.

In the embodiments described below, memory elements which are formed as N-channel type elements may be formed as P-channel type elements.

Moreover, in the drawings, the same reference numerals are given to the portions where the same material and substances are used and do not necessarily indicate the same shapes.

Moreover, it is to be noted that the drawings are schematic, and the dimensional relations between thickness. and plane, ratios of thickness and size between layers and portions and so on are different from those of the actual ones. Therefore, the concrete dimensions of thickness and size should be determined in consideration of the following description. Moreover, there are, of course, included the portions whose mutual dimensional relations and ratios are different between the figures.

(The First Embodiment)

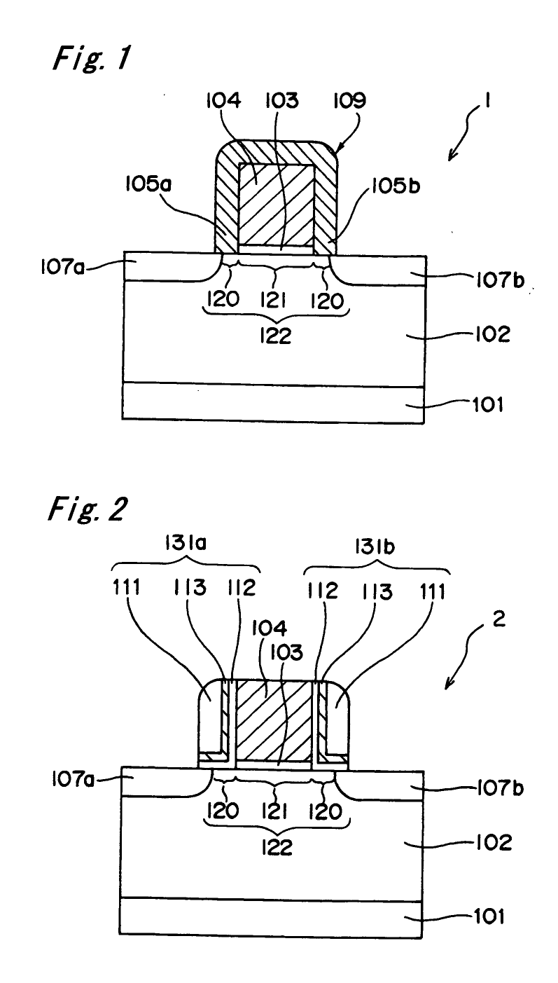

FIG. 1 is a sectional view showing one example of the memory element that constitutes the semiconductor storage device of the present invention. This memory element 1 is formed on a p-type well region 102 formed on the surface of a semiconductor substrate 101. A gate electrode 104 is formed on the p-type well region 102 via a gate insulator 103. Memory function bodies 105a and 105b are formed on opposite sides of the gate electrode 104. In this case, the memory function bodies indicate the portions in which electric charge is actually accumulated by rewrite operation.

In the example shown in FIG. 1, a silicon nitride 109 that has a trap level at which electric charge is retained and becomes a charge retention film covers the upper surface and side surfaces of the gate electrode 104, and the portions of the silicon nitride 109 located on opposite sidewall portions of the gate electrode 104 serve as the memory function bodies 105a and 105b that actually retain electric charge. Each of diffusion regions 107a and 107b functions as a source region or a drain region. A channel region 122 is defined between the diffusion regions 107a and 107b that function as the source region or the drain region.

The diffusion region of this memory element 1 has an offset structure. That is, the diffusion regions 107a and 107b do not reach a region 121 located below the gate electrode, and offset regions 120 and 120 that separate this gate electrode 104 from the diffusion regions 107a and 107b are located below the memory function bodies 105a and 105b. The region 121 located below the gate electrode and the offset regions 120 and 120 constitute the channel region 122.

FIG. 2 shows another example of the memory element. The memory element 2 of FIG. 2 differs from the memory element 1 of FIG. 1 in that each of the memory function bodies 131a and 131b has a trap level at which electric charge is retained and the silicon nitride 113, which becomes a charge retention film, is structurally placed between the silicon oxides 111 and 112. With the structure in which the silicon nitride is placed between the silicon oxides as shown in FIG. 2, charge injection efficiency during rewrite operation is increased, allowing the operation to be executed at higher speed.

In FIG. 2, the silicon nitride 113 may be replaced by a ferroelectric. Furthermore, in FIG. 1, the memory function bodies 105a and 105b may have a structure in which particles constructed of a conductor or a semiconductor of a nanometer size are distributed in scattered dots in an insulation film. In this case, it becomes difficult for electric charge to tunnel the dots when the particle diameter is smaller than 1 nm since the quantum effect is excessively large, and no remarkable quantum effect appears at room temperature when the particle diameter exceeds 10 nm. Therefore, the diameter of the particles should preferably fall within a range of 1 nm to 10 nm. Moreover, the memory function bodies 131a and 131b are not always required to have a sidewall spacer configuration dissimilarly to the memory element 2 (FIG. 2). For example, the silicon nitride 109 that has the trap level at which electric charge is retained covers the side surfaces and the upper surface of the gate electrode 104 in the memory element 1 (FIG. 1). However, the opposite sidewall portions (105a and 105b) of the gate electrode operate as memory function bodies that substantially retain electric charge. That is, it is only required that a function to retain electric charge or a substance to retain polarization is arranged in these regions.

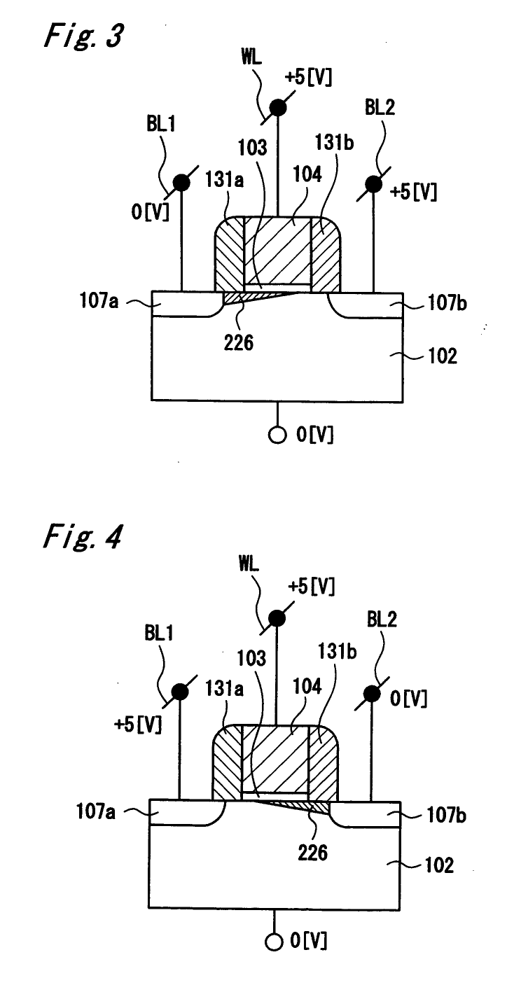

The principle of write operation of the memory elements 1 and 2 will be described with reference to FIG. 3 and FIG. 4. In this case, the description is based on the case where the entire bodies of the memory function bodies 131a and 131b have a function to retain electric charges.

Moreover, the term of “write” means the injection of electrons into the memory function bodies 131a and 131b when the memory elements 1 and 2 are the N-channel type. Hereinafter, the description is provided on the assumption that the memory elements 1 and 2 are the N-channel type.

In order to inject an electron (execute write) into the second memory function body 131b, as shown in FIG. 3, an N-type first diffusion region 107a and an N-type second diffusion region 107b are made to serve as a source electrode and a drain electrode, respectively. For example, a voltage of 0 V is applied to the first diffusion region 107a and the P-type well region 102, a voltage of +5 V is applied to the second diffusion region 107b, and a voltage of +5 V is applied to the gate electrode 104. According to the above-mentioned voltage conditions, an inversion layer 226 extends from the first diffusion region 107a (source electrode), but it does not reach the second diffusion region 107b (drain electrode), generating a pinch-off point. An electron is accelerated from the pinch-off point to the second diffusion region 107b (drain electrode) by a high electrical field and becomes a so-called hot electron (high energy conduction electron). Write is executed by the injection of this hot electron into the second memory function body 131b. Since no hot electron is generated in the vicinity of the first memory function body 131a, write is not executed.

Write can be executed by thus injecting electrons into the second memory function body 131b.

On the other hand, in order to inject an electron (execute write) into the first memory function body 131a, as shown in FIG. 4, the second diffusion region 107b and the first diffusion region 107a are made to serve as the source electrode and the drain electrode, respectively. For example, a voltage of 0 V is applied to the second diffusion region 107b and the P-type well region 102, a voltage of +5 V is applied to the first diffusion region 107a, and a voltage of +5 V is applied to the gate electrode 104. As described above, by exchanging the source and drain regions reversely to the case where an electron is injected into the second memory function body 131b, write can be executed by injecting an electron into the first memory function body 131a.

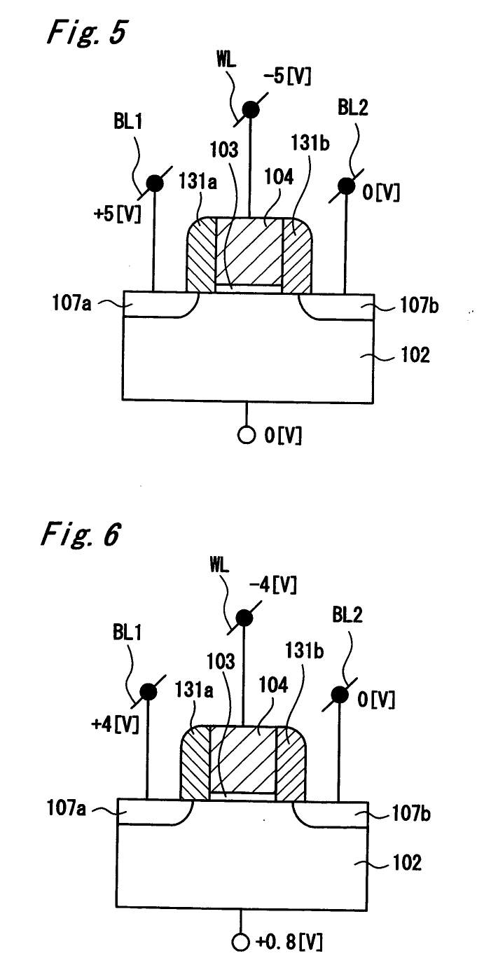

Next, the principle of erase operation of the memory element will be described with reference to FIG. 5 and FIG. 6.

According to a first method for erasing the information stored in the first memory function body 131a, as shown in FIG. 5, a positive voltage (e.g., +5 V) is applied to the first diffusion region 107a, a voltage of 0 V is applied to the P-type well region 102, a reverse bias is applied to a PN junction of the first diffusion region 107a and the P-type well region 102, and a negative voltage (e.g., −5 V) is further applied to the gate electrode 104. At this time, the potential slope becomes steep, in particular, in the vicinity of the gate electrode 104 at the PN junction due to the influence of the gate electrode to which the negative voltage is applied. Accordingly, a hot hole (high energy hole) is generated on the P-type well region 102 side of the PN junction due to band-to-band tunneling. This hot hole is drawn toward the gate electrode 104 that has a negative potential, and consequently, the hole is injected into the first memory function body 131a. As described above, the erase of the first memory function body 131a is executed. In this case, it is proper to apply a voltage of 0 V to the second diffusion region 107b.

When erasing the information stored in the second memory function body 131b, it is proper to exchange the potential of the first diffusion region with the potential of the second diffusion region in the aforementioned case.

According to a second method for erasing the information stored in the first memory function body 131a, as shown in FIG. 6, a positive voltage (e.g., +4 V) is applied to the first diffusion region 107a, a voltage of 0 V is applied to the second diffusion region 107b, a negative voltage (e.g., −4 V) is applied to the gate electrode 104, and a positive voltage (e.g., +0.8 V) is applied to the P-type well region 102. In this case, a forward voltage is applied across the P-type well region 102 and the second diffusion region 107b, injecting an electron into the P-type well region 102. The injected electron diffuses to a PN junction of the P-type well region 102 and the first diffusion region 107a and become hot electrons by being accelerated there by an intense electric field. This hot electron generates an electron-hole pair at the PN junction. That is, by applying the forward voltage across the P-type well region 102 and the second diffusion region 107b, the electron injected into the P-type well region 102 becomes a trigger to generate a hot hole at the PN junction located on the opposite side. The hot hole generated at the PN junction is drawn toward the gate electrode 104 that has a negative potential, and consequently, the hole is injected into the first memory function body 131a.

According to the second method, even when only a voltage insufficient for the generation of a hot hole by band-to-band tunneling is applied to the PN junction of the P-type well region and the first diffusion region 107a, the electron injected from the second diffusion region 107b becomes a trigger to generate an electron-hole pair at the PN junction, allowing a hot hole to be generated. Therefore, the voltage during the erase operation can be lowered. Particularly, when an offset region 120 (see FIG. 1 and 2) exists, the effect that the PN junction becomes steep due to the gate electrode to which the negative potential is applied is a little, and therefore, it is difficult to generate a hot hole by band-to-band tunneling. The second method makes up for the defect, and the erase operation can be achieved at a low voltage.

In erasing the information stored in the first memory function body 131a, a voltage of +5 V must to be applied to the first diffusion region 107a according to the first erase method, whereas a voltage of +4 V is sufficient according to the second erase method. As described above, according to the second method, the voltage during erase can be reduced. Therefore, power consumption is reduced, and the deterioration of the memory element due to the hot carrier can be restrained.

Moreover, by either one of the erase methods, overerase does not easily occur in the memory element. The term of “overerase” here is a phenomenon that the threshold value is lowered without saturation as the amount of holes accumulated in the memory function body increases. This is a serious problem in EEPROM (Electrically Erasable Programmable Read-Only Memory) represented by a flash memory, and there occurs a fatal malfunction that memory cell selection becomes impossible particularly when the threshold value becomes negative. On the other hand, in the memory element of the semiconductor storage device of the present invention, only electrons are induced under the memory function bodies even when a large amount of holes are accumulated in the memory function body, and almost no influence is exerted on the potential of the channel region under the gate insulation film. The threshold value during erase is determined by the potential under the gate insulation film, and therefore, overerase does not easily occur.

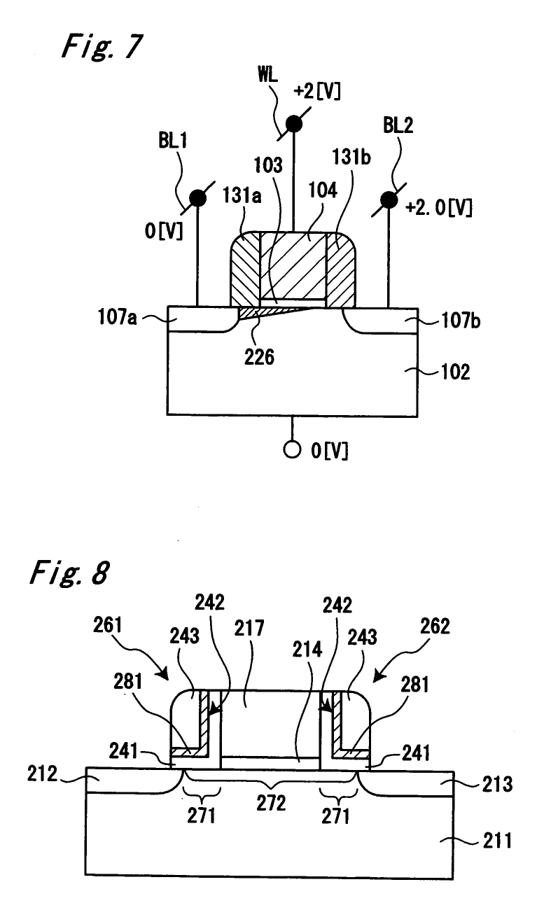

The principle of read operation of the memory element will be further described with reference to FIG. 7.

In reading the information stored in the first memory function body 131a, as described in FIG. 7, the transistor is operated by making the first diffusion region 107a and the second diffusion region 107b serve as a source electrode and a drain electrode, respectively. For example, a voltage of 0 V is applied to the first diffusion region 107a and the P-type well region 102, a voltage of +2 V is applied to the second diffusion region 107b, and a voltage of +2 V is applied to the gate electrode 104. In this case, when no electron is accumulated in the first memory function body 131a, a drain current easily flows. When electrons are accumulated in the first memory function body 131a, the inversion layer is not easily formed in the vicinity of the first memory function body 131a, and therefore, a drain current hardly flows. Therefore, by detecting the drain current, the storage information of the first memory function body 131a can be read. In particular, when read is executed by giving a voltage that causes the pinch-off operation, the state of charges accumulated in the first memory function body 131a can be more accurately determined without being influenced by the presence or absence of charges in the second memory function body 131b.

In reading the information stored in the second memory function body 131b, the transistor is operated by making the second diffusion region 107b and the first diffusion region 107a serve as the source electrode and the drain electrode, respectively. For example, it is proper to apply a voltage of 0 V to the second diffusion region 107b and the P-type well region 102, apply a voltage of +1.8 V to the first diffusion region 107a and apply a voltage of +2 V to the gate electrode 104. As described above, by exchanging the source and drain regions reversely to the case where the information stored in the first memory function body 131a is read, the information stored in the second memory function body 131b can be read.

If the channel region (offset regions 120) that is not covered with the gate electrode 104 is left, then the inversion layer is lost or formed depending on the presence or absence of surplus electric charges of the memory function bodies 131a and 131b in the channel region that is not covered with the gate electrode 104, and consequently, a great hysteresis (a change in the threshold value) is obtained. It is to be noted that the drain current is largely reduced when the width of the offset region 120 is excessively large, and the read speed is significantly slowed. Therefore, it is preferable to determine the width of the offset region 120 so that sufficient hysteresis and read speed can be obtained.

Even when the diffusion regions 107a and 107b reached the ends of the gate electrode 104, i.e., even when the diffusion regions 107a and 107b and the gate electrode 104 overlapped with each other, the threshold. value of the transistor was scarcely changed by the write operation. However, a parasitic resistance at the ends of the source and drain is largely changed, and the drain current is largely reduced (by an order of magnitude or more). Therefore, read can be executed by detecting the drain current, and a function as a memory can be obtained. However, when a larger memory hysteresis effect is needed, it is preferred that the diffusion regions 107a and 107b do not overlap with the gate electrode 104 (the offset region 120 exists).

By the aforementioned operation method, 2-bit write and erase per transistor can be selectively achieved. Moreover, by arranging memory elements with a word line WL connected to the gate electrodes 104 of the memory elements and with a first bit line BL1 and a second bit line BL2 connected to the first diffusion regions 107a and the second diffusion regions 107b, respectively, a memory cell array can be constructed.

Moreover, according to the aforementioned operation method, the 2-bit write and erase per transistor are executed by exchanging the source electrode with the drain electrode. However, the device may be operated as a 1-bit memory by fixing the source electrode and the drain electrode. In this case, it is possible to make one of the source and drain regions have a common fixed voltage, and the number of bit lines connected to the source and drain regions can be reduced by half.

As is apparent from the above description, in the memory element of the semiconductor storage device of the present invention, the memory function bodies are formed independently of the gate insulation film and formed on opposite sides of the gate electrode, and therefore, the 2-bit operation can be achieved. Moreover, the memory function bodies are separated by the gate electrode, and therefore, interference during rewrite is effectively restrained. Furthermore, the gate insulation film, which is separated from the memory function body, can therefore restrain the short-channel effect by being reduced in film thickness. Therefore, the miniaturization of the memory element and also the semiconductor storage device is facilitated.

(The Second Embodiment)

FIG. 8 is a schematic sectional view showing one example of the memory element in the second embodiment.

The memory element in the semiconductor storage device of the present embodiment has a construction that the memory function bodies 261 and 262 include a region for retaining electric charges (this may be a region for storing electric charges, or a film having the function to retain electric charges) and a region for restraining the escape of electric charges (this may be a film that has a function to restrain the escape of electric charges). As shown in FIG. 8, one example of the construction is formed by ONO (Oxide Nitride Oxide) construction. That is, the silicon nitride film 242 is placed between the silicon oxide film 241 and the silicon oxide film 243, constituting the memory function bodies 261 and 262. In this case, the silicon nitride film 242 produces a function to retain electric charge. Moreover, the silicon oxide films 241 and 243 play the role of films that have a function to make the electric charge accumulated in the silicon nitride hard to escape.

Also, the region (silicon nitride film 242) for holding or retaining electric charges in the memory function bodies 261 and 262 are overlapped with the diffusion regions 212 and 213. Herein, the term “overlap” is used to refer to the state that at least part of the region (silicon nitride film 242) for retaining electric charges is present on at least part of the diffusion regions 212 and 213. In the present embodiment, the end portion of the horizontal portion 281 of the silicon nitride film 242 exists above each the end portions located on the confronting sides of the diffusion regions 212 and 213. It is noted that there are shown a semiconductor substrate 211, a gate insulation film 214, and an offset region 271 between the gate electrode 217 and the diffusion regions 212 and 213. The uppermost surface of the semiconductor substrate 211 under the gate insulation film 214 is a channel region 272.

An effect produced by the arrangement that the silicon nitride film 242 serving as the region for retaining electric charges in the memory function bodies 261 and 262 overlap with the diffusion regions 212 and 213 will be described.

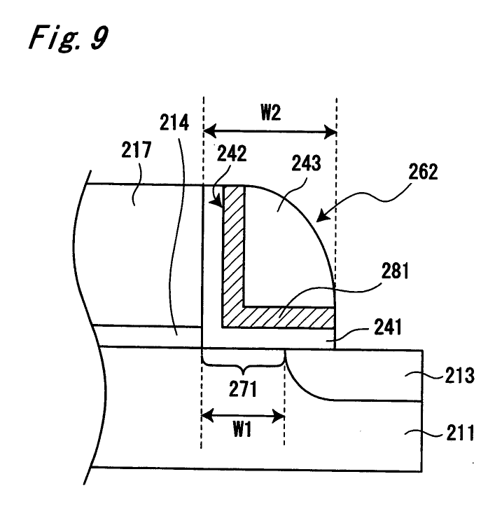

FIG. 9 is an enlarged sectional view of the peripheral portions of the memory function body 262 in FIG. 8. In FIG. 9, W1 depicts the amount of offset of a gate electrode 217 with respect to a diffusion region 213, and W2 depicts the width of a memory function body 262 in a cross-sectional plane in the channel-length direction of the gate electrode. In FIG. 9, the end of the silicon nitride film 242 remote from the gate electrode 217 (the end portion of the horizontal part 281 of the silicon nitride film 242) coincided with the end of the memory function body 262 remote from the gate electrode 217 at the memory function body 262. Therefore, the width of the memory function body 262 was defined as W2. The amount of overlap of the memory function body 262 with the diffusion region 213 is expressed by W2-W1. What is important here is that the memory function body 262 constructed of the silicon nitride film 242 of the memory function body 262 overlaps with the diffusion region 213, i.e., the arrangement that the relation: W2>W1 is satisfied.

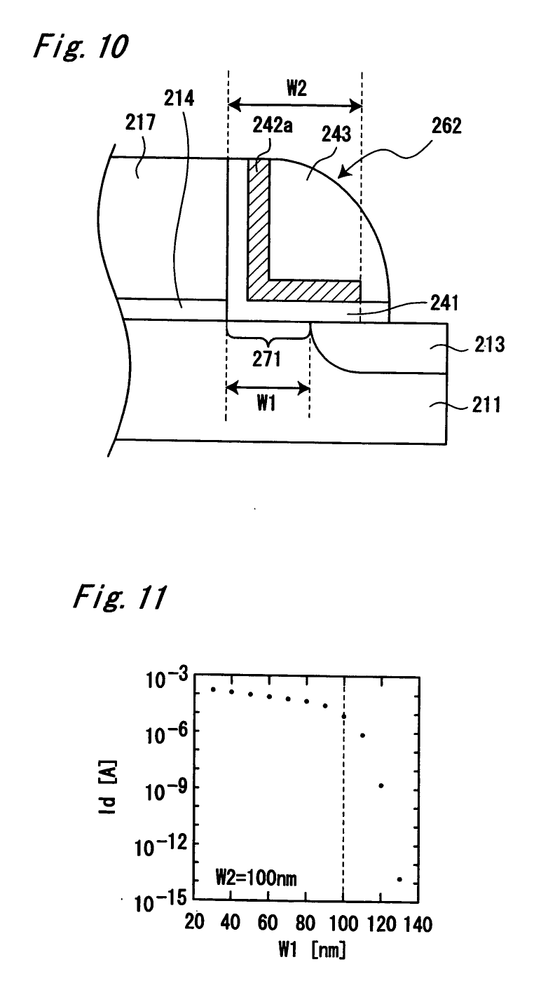

In the case where an edge of a silicon nitride film 242a on the side away from the gate electrode 217 in a memory function body 262 is not aligned with an edge of the memory function body 262 on the side away from the gate electrode as shown in FIG. 10, W2 may be defined as the width from the edge of the gate electrode 217 to the edge of the silicon nitride film 242a on the side away from the gate electrode 217.

FIG. 11 shows a drain current Id in the structure of FIG. 9 with the width W2 of the memory function body 262 being fixed to 100 nm and the offset amount W1 being varied. Herein, the drain current is obtained by device simulation performed under the conditions that the memory function body 262 is in erase state (positive holes are stored), and the diffusion regions 212 and 213 are set to be a source electrode and a drain electrode, respectively.

As shown in FIG. 11, with W1 being 100 nm or more (i.e., when the silicon nitride film 242 and the diffusion region 213 are not overlapped), the drain current shows rapid reduction. Since a drain current value is almost in proportion to a read operation speed, memory performance is rapidly deteriorated when W1 is 100 nm or more. In the range where the silicon nitride film 242 and the diffusion region 213 are overlapped, the drain current shows mild reduction. Therefore, taking a manufacturing dispersion into consideration, it is difficult to obtain a memory function unless at least part of the silicon nitride film 242 that is a film having a function of holing electric charges is overlapped with the source/drain region.

Based on the above-described result of the device simulation, a memory cell array is manufactured with W2 being fixed to 100 nm, and W1 being set to 60 nm and 100 nm as design values. When W1 is 60 nm, the silicon nitride film is overlapped with the diffusion regions by 40 nm as a design value, and when W1 is 100 nm, there is no overlap as a design value. As a result of measuring read time of these memory cell arrays in comparison with the worst cases in consideration to dispersion, it was found out that the case where W1 was 60 nm as a design value was 100 times faster in readout access time. From a practical standpoint, it is preferable that the read access time is 100 nanoseconds or less per bit. It was found out, however, that this condition was never satisfied in the case of W1=W2. It was also found out that W2−W1>10 nm was more preferable in consideration to manufacturing dispersion.

It is preferable for reading information stored in the memory function body 261 to set the diffusion region 212 as a source electrode and the diffusion region 213 as a drain region similar to the embodiment 1 and to form a pinch-off point on the side closer to the drain region in the channel region. More specifically, in reading information stored in either one of two memory function bodies, the pinch-off point is preferably formed in a region closer to the other memory function body in the channel region. This makes it possible to detect memory information in the memory function body 261 with good sensitivity regardless of the storage condition of the memory function body 262, resulting in large contribution to implementation of two-bit operation.

In the case of storing information only in one side out of the two memory function bodies, or in the case of using these two memory function bodies in the same storing condition, a pinch-off point is not necessarily formed in read operation.

Although not shown in FIG. 8, a well region (P type well in the case of N-channel element) is preferably formed on the surface of the semiconductor substrate 211. Forming the well region facilitates control of electric characteristics (withstand voltage, junction capacitance, and short channel effect) while maintaining impurity concentration of the channel region optimum for memory operation (rewrite operation and read operation).

The memory function bodies should preferably include a charge retention film that has the function to retain electric charge and an insulation film from the viewpoint of improving the retention characteristic of the memory. In this embodiment, there are employed the silicon nitride film 242 that has a level at which electric charge is trapped as a charge retention film and the silicon oxide films 241 and 243 that have operation to prevent the dispersion of the electric charge accumulated in the charge retention film as the insulation films. The inclusion of the charge retention film and the insulation films in the memory function body can prevent the dispersion of electric charge and improve the retention characteristic. Furthermore, the volume of the charge retention film can be appropriately reduced in comparison with the case where the memory function body is constructed only of the charge retention film. By appropriately reducing the volume of the charge retention film, it becomes possible to limit the movement of electric charge in the charge retention film and restrain the occurrence of a characteristic change due to the movement of electric charge during storage retention.

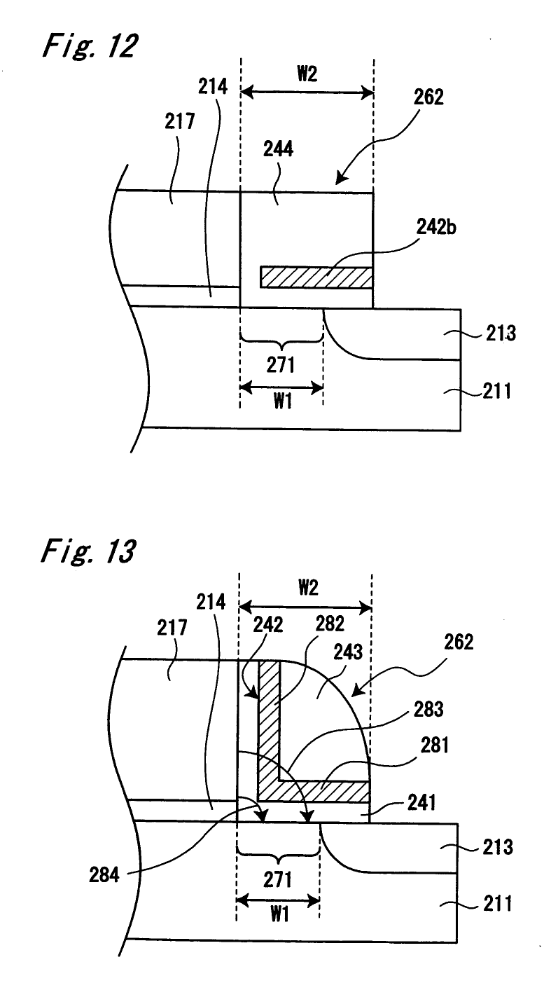

Also, it is preferable that the memory function body contains a charge retaining film disposed approximately parallel to the surface of the gate insulation film. In other words, it is preferable that the surface of the charge retaining film in the memory function body is disposed so as to have a constant distance from the surface of the gate insulation film. More particularly, as shown in FIG. 12, a silicon nitride film 242b as an electric charge retention film in the memory function body 262 has a face approximately parallel to the surface of the gate insulation film 214. In other words, the silicon nitride film 242b is preferably formed to have a uniform height from the height corresponding to the surface of the gate insulation film 214. The presence of the silicon nitride film 242b approximately parallel to the surface of the gate insulation film 214 in the memory function body 262 makes it possible to effectively control easiness of formation of an inversion layer in the offset region 271 with use of an amount of electric charges stored in the charge retention film 242b, thereby enabling increase of memory effect. Also, by placing the silicon nitride film 242b approximately parallel to the surface of the gate insulation film 214, change of memory effect may be kept relatively small even with a dispersed offset amount (W1), enabling restraint of memory effect dispersion. In addition, movement of electric charges toward upper side of the silicon nitride film 242b may be suppressed, and therefore characteristic change due to the movement of electric charges during memory holding may be restrained.

Furthermore, the memory function body 262 preferably contains an insulation film (e.g., a portion of the silicon oxide film 244 on the offset region 271) that separates the silicon nitride film 242b approximately parallel to the surface of the gate insulation film 214 from the channel region (or the well region). This insulation film may restrain dissipation of the electric charges stored in the charge retention film, thereby contributing to obtaining a memory element with better holding characteristics.

It is noted that controlling the thickness of the silicon nitride film 242b as well as controlling the thickness of the insulation film under the silicon nitride film 242b (a portion of the silicon oxide film 244 on the offset region 271) to be constant make it possible to keep the distance from the surface of the semiconductor substrate to the electric charges stored in the charge retention film approximately constant. More particularly, the distance from the surface of the semiconductor substrate to the electric charges stored in the charge retention film may be controlled to be within the range from a minimum thickness value of the insulation film under the silicon nitride 242b to the sum of a maximum thickness of the insulation film under the silicon nitride film 242b and a maximum thickness of the silicon nitride film 242b. Consequently, the concentration of electric line of force generated by the electric charges stored in the silicon nitride film 242b may be roughly controlled, and therefore dispersion of the degree of memory effect of the memory device may be minimized.

(The Third Embodiment)

In this embodiment, a charge retention film 242 of the memory function body 262 has an approximately uniform thickness as shown in FIG. 13. Further, the charge retention film 242 is configured to have a region 281 extending in direction approximately parallel to the surface of the gate insulation film 214 and a region 282 extending in direction approximately parallel to the side face of the gate electrode 217.

When a positive voltage is applied to the gate electrode 217, electric line of force in the memory function body 262 passes the silicon nitride film 242 total two times through the first portion 281 and the second portion 282 as shown with an arrow 283. It is noted that when a negative voltage is applied to the gate electrode 217, the direction of electric line of force is reversed. Herein, a dielectric constant of the silicon nitride film 242 is approx. 6, while a dielectric constant of silicon oxide films 241 and 243 is approx. 4. Eventually, an effective dielectric constant of the memory function body 262 in the direction of electric line of force 283 becomes larger than that in the case where the charge retention film includes only the first portion 281, which makes it possible to decrease potential difference between the both ends of the electric line of force. More specifically, much part of the voltage applied to the gate electrode 217 is used to reinforce electric fields in the offset region 271.

Electric charges are injected into the silicon nitride film 242 in rewrite operation because generated electric charges are pulled by electric fields in the offset region 271. As a consequence, the charge retention film 242 including the horizontal part 282 increases the electric charges injected into the memory function body 262 in rewrite operation, thereby increasing a rewrite speed.

In the case where a portion of the silicon oxide film 243 is a silicon nitride film, more specifically, in the case where the charge retention film is not flat against the height corresponding to the surface of the gate insulation film 214, movement of electric charges toward upper side of the silicon nitride film becomes outstanding, and holding characteristics are deteriorated.

Instead of silicon nitride film, the charge retention film is more preferably formed from high-dielectric substances such as hafnium oxide having extremely large dielectric constant.

Further, the memory function body more preferably includes an insulation film (a portion of the silicon oxide film 241 on the offset region 271) that separates the charge retention film approximately parallel to the surface of the gate insulation film from the channel region (or the well region). This insulation film may restrain dissipation of the electric charges stored in the charge retention film, thereby enabling further improvement of holding characteristics.

Also, the memory function body more preferably includes an insulation film (a portion of the silicon oxide film 241 in contact with the gate electrode 217) that separates the gate electrode from the charge retention film extending in the direction approximately parallel to the side face of the gate electrode. This insulation film may prevent injection of electric charges from the gate electrode into the charge retention film and prevent change of electric characteristics, which may increase reliability of the memory element.

Further, similar to the second embodiment, it is preferable that the thickness of the insulation film under the charge retention film 242 (a portion of the silicon oxide film 241 on the offset region 271) is controlled to be constant, and further the thickness of the insulation film disposed on the side face of the gate electrode (a portion of the silicon oxide film 241 in contact with the gate electrode 217) is controlled to be constant. Consequently, the concentration of electric line of force generated by the electric charges stored in the charge retention film 242 may be roughly controlled, and leakage of electric charges may be prevented.

(The Fourth Embodiment)

In this embodiment, optimization of the distance between a gate electrode, a memory function body, and a source/drain region is explained.

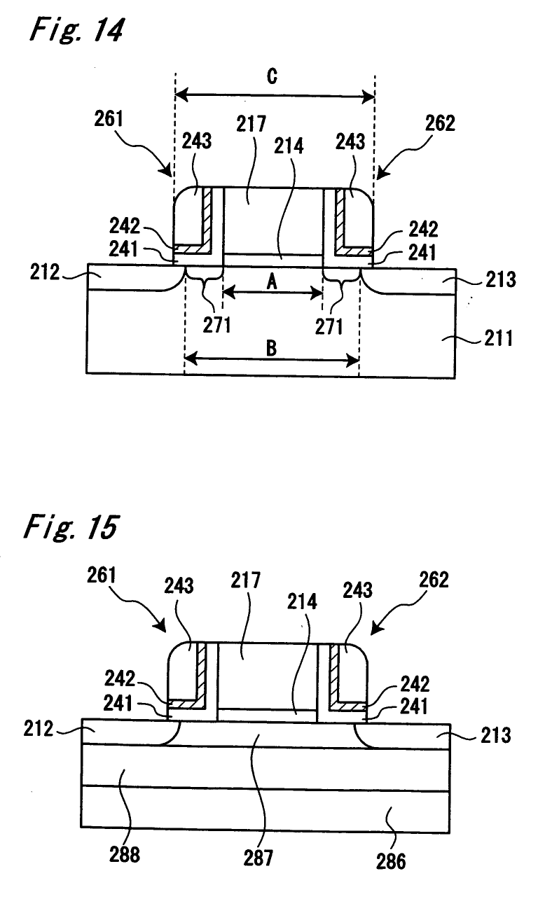

As shown in FIG. 14, reference symbol A denotes a gate electrode length in the cross section in channel length direction, reference symbol B denotes a distance (channel length) between source and drain regions, and reference symbol C denotes a distance from the edge of one memory function body to the edge of the other memory function body, more specifically a distance from the edge of a film (the edge. away from the gate electrode) having a function of holding the electric charges in one charge holding portion in the cross section in channel length direction to the edge of a film 242 (the edge away from the gate electrode 217) having a function of holding the electric charges in the other memory function body 262.

A relationship of B<C is preferable. There is present an offset region 271 between a portion under the gate electrode 217 and the source/drain regions 212 and 213 in the channel region. Setting as B<C, the electric charges stored in the memory function bodies 261 and 262 (silicon nitride film 242) effectively change easiness of inversion in the entire part of the offset region 271. As a result, memory effect is increased, and high-speed read operation is particularly enabled.

Also, when the gate electrode 217 and the source/drain regions 212 and 213 are offset, that is, when the relationship of A<B is satisfied, easiness of inversion of the offset region when a voltage is applied to the gate electrode 217 is largely changed by an electric charge amount stored in the memory function bodies. Consequently, memory effect increases and short channel effect can be reduced. However, as long as the memory effect is effective, the offset region is not necessarily required. Even when the offset region 271 is not present, if the impurity concentration in the source/drain regions 212 and 213 is sufficiently small, the memory effect can still be effective in the memory function bodies 261 and 262 (silicon nitride film 242).

Therefore, the state of A<B<C is most preferable.

(The Fifth Embodiment)

A memory element of semiconductor storage device according to this embodiment has essentially the same structure as that in the second embodiment except that the semiconductor substrate is SOI substrate as shown in FIG. 15.

The memory element is structured such that an embedded oxide film 288 is formed on a semiconductor substrate 286, and on top of the embedded oxide film 288, SOI layer is further formed. In the SOI layer, there are formed diffusion regions 212 and 213, and other areas constitute a body region 287.

This memory device also brings about the functions and effects similar to those of the memory device in the second embodiment. Further, since the junction capacitance between the diffusion regions 212 and 213 and the body region 287 may be considerably reduced, it becomes possible to increase a device speed and to decrease power consumption.

(The Sixth Embodiment)

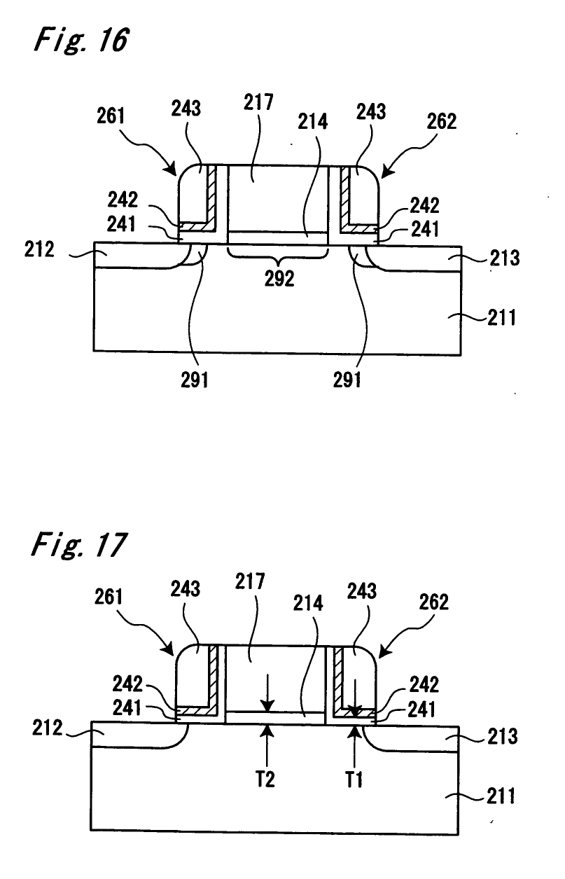

A memory element in this embodiment has essentially the same structure as that in the second embodiment except that in the vicinity of the channel side of N type diffusion regions 212 and 213, a P type highly-concentrated region 291 is added as shown in FIG. 16.

More specifically, the concentration of P type impurity (e.g., boron) in the P type highly-concentrated region 291 is higher than the concentration of P type impurity in the region 292. An appropriate value of the P type impurity concentration in the P type highly-concentrated region 291 is, for example, around 5×10¹⁷ to 1×10¹⁹ cm⁻³. Also, a value of the P type impurity concentration in the region 292 may be set to, for example, 5×10¹⁶ to 1×10¹⁸ cm⁻³.

Thus, providing the P type highly-concentrated region 291 makes the gradient of impurity concentration at junction between the diffusion regions 212 and 213 and the semiconductor substrate 211 steep right under the memory function bodies 261 and 262. This facilitates generation of hot carriers in write and erase operation, thereby enabling reduction of voltage in write operation and erase operation or implementing high-speed write operation and erase operation. Further, since the impurity concentration in the region 292 is relatively small, a threshold value when the memory is in erased state is small and so the drain current becomes large. Consequently, a read speed is increased. This makes it possible to provide a memory device having low rewrite voltage or a high rewrite speed, and having a high read speed.

Also in FIG. 16, by providing the P type highly-concentrated regions 291 in a position adjacent to the source/drain regions and on the lower side of the memory function bodies 261 and 262 (that is a position not right under the gate electrode), a threshold value of the entire transistor shows considerable increase. The volume of this increase is extremely larger than that in the case where the P type highly-concentrated region 291 is right under the gate electrode. When write electric charges (electrons in the case where the transistor is N channel type) are stored in the memory function bodies 261 and 262, the difference becomes larger. When enough erase electric charges (positive holes in the case where the transistor is N channel type) are stored in the memory function body, a threshold value of the entire transistor is decreased down to a value determined by the impurity concentration in the channel region (region 292) under the gate electrode 217. More specifically, the threshold value in the erased state is not dependent on the impurity concentration in the P type highly-concentrated region 291, whereas the threshold value in the written state is extremely influenced. Therefore, disposing the P type highly-concentrated region 291 under the memory function bodies and adjacent to the source/drain regions imparts extremely large fluctuation only to the threshold value in the written state, thereby enabling remarkable increase of memory effect (difference of threshold values in the erased state and the written state).

(The Seventh Embodiment)

A memory element of a semiconductor storage device in this embodiment has essentially the same structure as that in the second embodiment except that the thickness T1 of the insulation film 241 that separates the charge retention film (silicon nitride film 242) from the channel region or the well region is smaller than the thickness T2 of the gate insulation film 214 as shown in FIG. 17.

The gate insulation film 214 has a lower limit of the thickness T2 because of the request for withstand voltage in memory rewrite operation. However, the thickness T1 of the insulation film 241 can be smaller than T2 regardless of the request for withstand voltage.

In the memory device of the present embodiment, the thickness T1 of the insulation film has high design freedom as stated above because of the following reason. In the memory device, the insulation film 241 that separates the charge retention film (silicon nitride 242) from the channel region or the well region is not interposed in between the gate electrode 217 and the channel region or the well region. Consequently, the insulation film 241 that separates the charge retention film (silicon nitride 242) from the channel region or the well region does not receive direct influence from the high-electric fields that affect in between the gate electrode 217 and the channel region or the well region, but receives influence from relatively weak electric fields expanding from the gate electrode 217 in lateral direction. As a result, despite the request for withstand voltage to the gate insulation film 214, it becomes possible to make T1 smaller than T2. Contrary to this, for example in EEPROM as typified by flash memory, an insulation film that separates a floating gate from the channel region or the well region is interposed in between a gate electrode (control gate) and the channel region or the well region, so that the insulation film receives direct influence from high electric fields of the gate electrode. In EEPROM, therefore, the thickness of the insulation film that separates the floating gate from the channel region or the well region is limited, which hinders optimization of the functions of a memory device. As is apparent from the above, it is an essential reason for increasing the degree of freedom of T1 that the insulation film 241 that separates the charge retention film 242 from the channel region or the well region in the memory element of the present embodiment is not placed between the gate electrode 217 and the channel region or the well region.

Decreasing the thickness T1 of the insulation film 241 facilitates injection of electric charges into the memory function bodies 261 and 262, decreases voltage for write operation and erase operation, or enables high-speed write operation and erase operation. In addition, since an electric charge amount induced in the channel region or the well region increases when electric charges are stored in the silicon nitride film 242, increased memory effect may be implemented.

Some electric lines of force having short length in the memory function body do not pass the silicon nitride film 242 as shown with an arrow 284 in FIG. 13. Since electric field strength is relatively large on such a short electric line of force, the electric fields along the electric line of force plays an important role in rewrite operation. By decreasing the thickness T1 of the insulation film 241, the silicon nitride film 242 moves to the lower side of the FIG. 13, so that the electric line of force shown with the arrow 284 passes the silicon nitride film 242. As a consequence, an effective dielectric constant in the memory function body along the electric line of force in the direction of arrow 284 becomes large, which makes it possible to make potential difference between the both ends of the electric line of force 284 smaller. Therefore, most part of voltage applied to the gate electrode 217 is used to strengthen the electric fields in the offset region, thereby implementing high-speed write operation and erase operation.

As is clear from the above, by setting as T1<T2, it becomes possible to decrease voltage in write operation and erase operation or implement high-speed write operation and erase operation, and to enable further increase of memory effect without degrading withstand voltage capability of the memory.

It is noted that the thickness T1 of the insulation film 241 is preferably 0.8 nm or more, that is the limit range in which uniformity in manufacturing process or certain level of film quality may be maintained and holding characteristics do not suffer extreme deterioration.

More specifically, in the case of liquid crystal driver LSI which has a severe design rule and requires high withstand voltage, maximum 15 to 18V voltage is necessary for driving liquid crystal panel TFT (Thin Film Transistor). Eventually, it is not possible to make the gate oxide film thinner. In the case of mounting a nonvolatile memory of the present invention as an image adjuster together with other devices on the liquid crystal driver LSI, the memory element of the present invention enables optimum design of the thickness of the insulation film that separates the charge retention film (silicon nitride film 242) from the channel region or the well region independently of the thickness of the gate insulation film. For example, in a memory element with a gate electrode length (word line width) of 250 nm, there may be separately set like T1=20 nm and T2=10 nm, fulfilling a memory element with good write efficiency. (Short channel effect is not generated even though T1 is larger than that of normal logic transistors, because the source/drain regions are offset from the gate electrode.)

(The Eighth Embodiment)

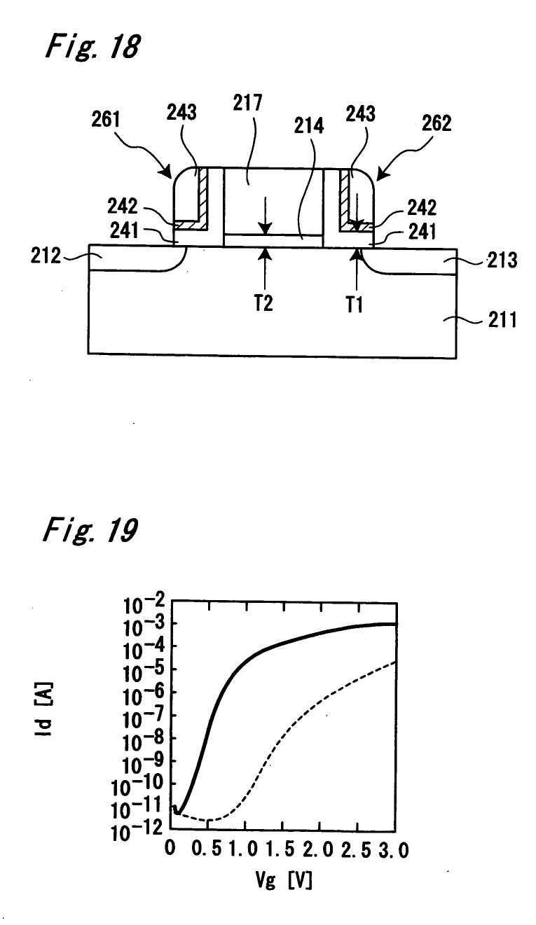

A memory element of a semiconductor storage device according to this embodiment has essentially the same structure as that in the second embodiment except that the thickness (T1) of the insulation film 241 that separates the charge retention film (silicon nitride film 242) from the channel region or the well region is larger than the thickness (T2) of the gate insulation film 214 as shown in FIG. 18.

The gate insulation film 214 has an upper limit of the thickness T2 because of the request for prevention of short channel effect of the device. However, the thickness T1 of the insulation film 241 can be larger than T2 regardless of the request for prevention of short channel effect. More specifically, as miniaturization scaling proceeds (thinning of the gate insulation film proceeds), the thickness of the insulation film 241 that separates the charge retention film (silicon nitride film 242) from the channel region or the well region may be optimally designed independently of the thickness T2 of the gate insulation film 214, which implements the effect that the memory function bodies 261 and 262 will not disturb scaling.

In the memory device of the present embodiment, the thickness T1 of the insulation film 241 has high design freedom as stated above because, as is already described, the insulation film 241 that separates the charge retention film 242 from the channel region or the well region is not interposed in between the gate electrode 217 and the channel region or the well region. As a result, despite the request for prevention of short channel effect to the gate insulation film 214, it becomes possible to make T1 larger than T2.

Increasing the thickness T1 of the insulation film 241 makes it possible to prevent dissipation of the electric charges stored in the memory function body and to improve holing characteristics of the memory.

Therefore, setting as T1>T2 enables improvement of holding characteristics without deteriorating short channel effect of the memory.

It is noted that the thickness T1 of the insulation film 241 is preferably 20 nm or less in consideration of reduction of a rewrite speed.

More specifically, a conventional nonvolatile memory as typified by flash memory is structured such that a selection gate electrode constitutes a write/erase gate electrode, and a gate insulation film (including a floating gate) corresponding to the write/erase gate electrode serves also as an electric charge storage film. Consequently, since the request for miniaturization (creation of thinner devices is essential for restraining short channel effect) conflicts the request for securing reliability (in order to control leakage of stored electric charges, the thickness of an insulation film that separates a floating gate from the channel region or the well region cannot be decreased to smaller than approx. 7 nm), miniaturization of the device is difficult. In fact, according to ITRS (International Technology Roadmap for Semiconductors), miniaturization of a physical gate length down to approx. 0.2 micron or lower is not yet in sight. In the memory device of the present invention, independent designing of T1 and T2 is available as described above, and therefore miniaturization becomes possible. In the present invention, for example, in a memory element with a gate electrode length (word line width) of 450 nm, there is separately set like T2=4 nm and T1=7 nm, fulfilling a semiconductor storage device free from generation of short channel effect. Short channel effect is not generated even though T2 is set larger than that of normal logic transistors, because the source/drain regions are offset from the gate electrode. Also, since the source/drain regions are offset from the gate electrode in the memory device of the present invention, miniaturization is further facilitated compared to normal logic transistors.

As described above, since an electrode for supporting write and erase operation is not present above the memory function body, the insulation film that separates the charge retention film from the channel region or the well region does not directly receive the influence of high electric fields which is produced between the electrode that supports write and erase operation and the channel region or the well region, but receives influence only from relatively weak electric fields expanding from the gate electrode in lateral direction. This makes it possible to fulfill a memory element having the gate length miniaturized more than the gate length of the logic transistors in comparison with the same processing accuracy.

(The Ninth Embodiment)

This embodiment relates to changes of electric characteristics when rewrite operation is performed in the memory element of the semiconductor storage device according to the present invention.

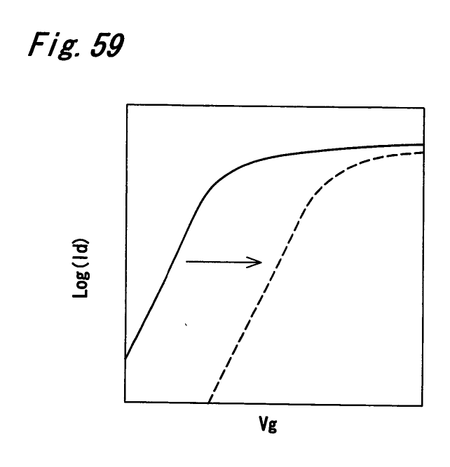

FIG. 19 is a view showing characteristic curves of a drain current (Id) versus a gate voltage (Vg) (measured values) where an electric charge amount in the memory function body of an N-channel type memory element varies between erase state and written state. As clearly shown in FIG. 19, when write operation is performed in the erased state, not only the threshold value simply rises, but inclination of the graph dramatically falls especially in sub-threshold region. Therefore, even in the region with relatively high gate voltage (Vg), a drain current ratio of the erased state to the written state is large. For example in the point of Vg=2.5V, the current ratio is still two digits or more. This characteristic is largely different from that in the case of a flash memory shown in FIG. 59.

The appearance of the above characteristic in the memory device is a phenomenon peculiar to the case where the gate electrode and the diffusion region are offset and therefore the gate electric fields are difficult to reach the offset region. When the memory device is in the written state, an inversion layer is extremely difficult to be generated in the offset region below the memory function body even if a positive voltage is applied to the gate electrode. This causes smaller inclination of the Id-Vg curve line in the sub-threshold region in the written state. When the memory device is in the erased state, high-density electrons are induced in the offset region. Further, when 0V is applied to the gate electrode (i.e., in OFF state), electrons are not induced in the channel below the gate electrode (and therefore an off current is small). This causes large gradient of the Id-Vg curve line in the sub-threshold region in the erased state and a large increase rate of current (conductance) even in the voltage region over the threshold.

As is clear from the above description, the memory element of the semiconductor storage device according to the present invention makes it possible to make the drain current ratio of the erased state to the written state particularly large.

(The Tenth Embodiment)

This embodiment is a semiconductor storage device (memory cell array) constituted by arranging the aforementioned memory elements.

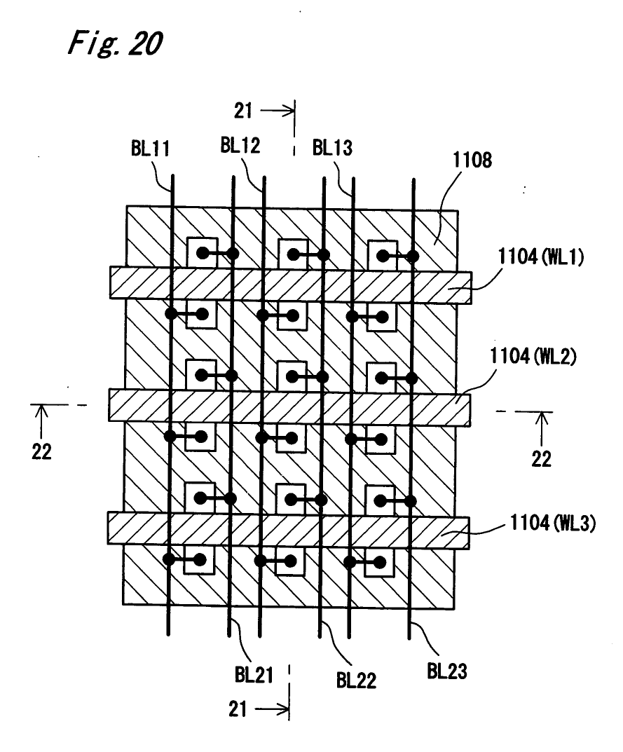

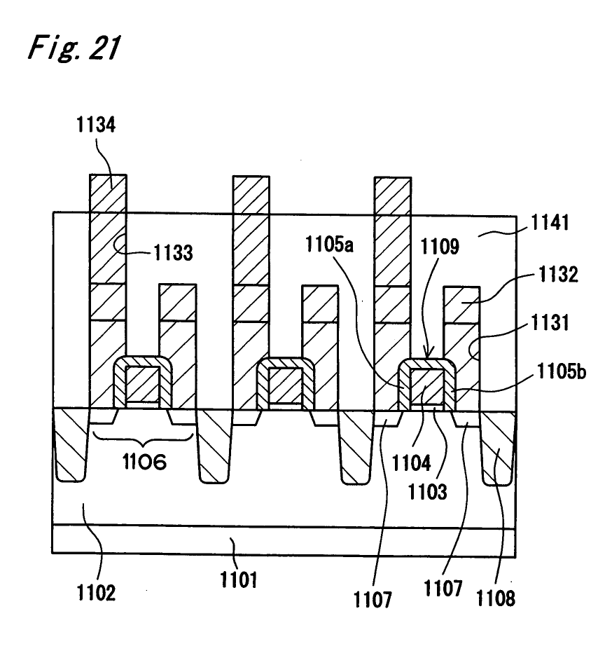

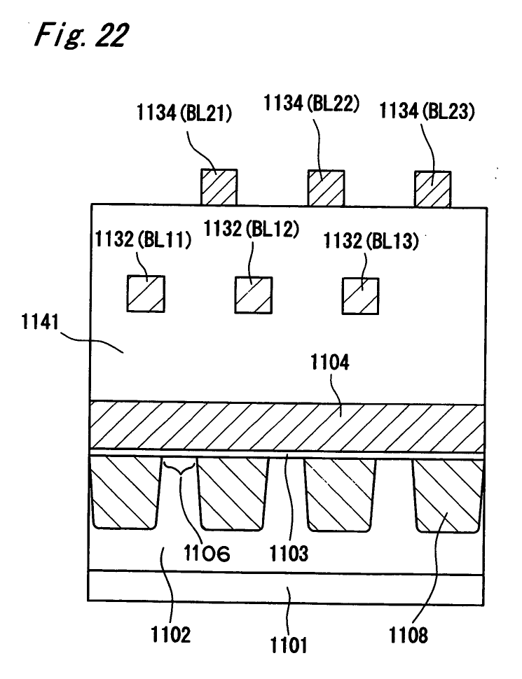

FIG. 20 is a plan view showing the semiconductor storage device of the tenth embodiment, FIG. 21 is a sectional view taken along the line 21-21 of FIG. 20, FIG. 22 is a sectional view taken along the line 22-22 of FIG. 20. It is to be noted that an upper portion interconnection structure (bit line and contact) is expressed as connection for the sake of simplicity in FIG. 20. Although a memory cell array of three rows by three columns are shown in FIGS. 20 through 22, the number of rows and the number of columns are arbitrary. It is to be noted that the first direction of the present invention corresponds to the direction of row, and the second direction corresponds to the direction of column. Hereinafter, the same thing can be said for the first and second directions.

A p-type well region 1102 is formed on a semiconductor substrate 1101. An element isolation region 1108 is formed in the surface portion of the p-type well region 1102. A region where the element isolation region 1108 is not formed on the surface of the semiconductor substrate becomes an active region 1106. Active regions 1106 are arranged on the semiconductor substrate. Word lines WL1, WL2 and WL3 (1104) are formed extended sidewise in the sheet plane and arranged side by side longitudinally in the sheet plane. The word lines WL1, WL2 and WL3 extend over the active regions via gate insulators 1103, and diffusion regions 1107 are formed on opposite sides of each word line (in the regions that are the active regions 1106 and are not covered with the word lines). A word line (gate electrode) and two diffusion regions (source region or drain region) formed on opposite sides of the word line constitute one field-effect transistor. A silicon nitride 1109 is formed on the sidewalls and the upper surfaces of the word lines WL1, WL2 and WL3 (1104). The portions of the silicon nitrides 1109 located on the sidewalls on opposite sides of the word lines serve as memory function bodies 1105a and 1105b. One of the two diffusion regions formed on opposite sides of the word line is connected to any one of first bit lines BL11, BL12 and BL13, while the other is connected to any one of second bit lines BL21, BL22 and BL23. In the present embodiment, the first bit line is constructed of a first layer metal interconnection 1132, and the second bit line is constructed of a second layer metal interconnection 1134. However, the interconnection method is not limited to this.

In FIGS. 21 and 22, there are shown a contact hole 1131 (hole for connecting the active layer or the word line to the first layer metal interconnection) and a viahole 1133 (hole for connecting the first layer metal interconnection to the second layer metal interconnection).

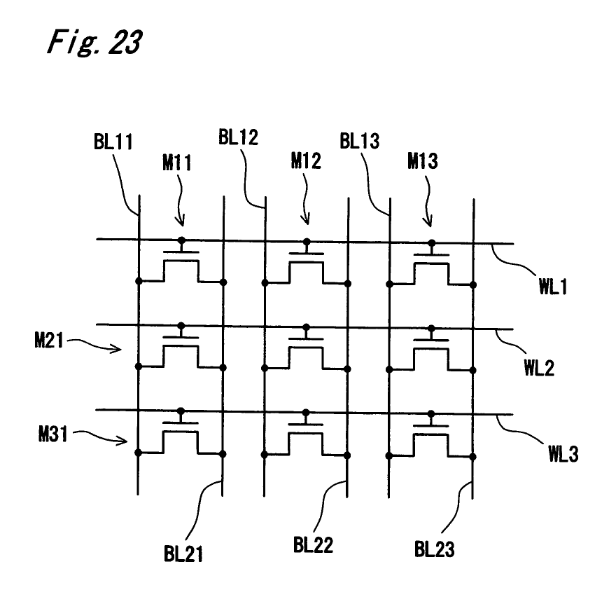

FIG. 23 shows a circuit diagram of the above-mentioned memory cell array. For the sake of simplicity, the memory elements are each expressed by the symbol that represents an ordinary field-effect transistor. With regard to a memory element Mij (i=1, 2, 3, j=1, 2, 3), the gate electrode is connected to the word line WLi (i=1, 2, 3), one of the diffusion regions is connected to the first bit line BL1j (j=1, 2, 3), and the other of the diffusion regions is connected to the second bit line BL2j (j=1, 2, 3).

The memory cell array is operated by applying voltages required for the method of operating the memory element to the desired memory element via specified word line, first specified bit line and second bit line. For example, when one of the memory function bodies of the memory element M11 is subjected to write, it is proper to apply, for example, +5 V to the word line WL1, +5 V to the first bit line BL11 and 0 V to the second bit line BL21. When the other of the memory function bodies of the memory element M11 is subjected to write, it is proper to apply +5 V to the word line WL1, 0 V to the first bit line BL11 and +5 V to the second bit line BL21. At this time, it is proper to apply, for example, 0 V to the other nonselected word lines and nonselected bit lines.

As is apparent from the above description, the memory cell array of the present embodiment is constituted by arranging the aforementioned memory elements. As described above, with regard to the memory elements, one element can store two bits, and the gate insulator can be formed into a thin film, allowing scaling down to be facilitated. Therefore, it also becomes easy to scale down the size of the memory cell array of the present embodiment constituted by arranging the aforementioned memory elements, and the manufacturing cost is reduced.

Moreover, as described above, the process for forming the memory elements has a great resemblance to the ordinary CMOS process and is able to be manufactured much easier than the nonvolatile memory such as a conventional EEPROM that has a floating gate. Therefore, the memory cell array of the present invention can easily be manufactured and easily consolidated with a logic circuit.

As described in connection with the second embodiment, in the memory element employed in the present embodiment, the regions (silicon nitrides 242) that retain electric charge in the memory function bodies 261 and 262 should preferably overlap with the diffusion regions 212 and 213, respectively. If such the memory element is employed in the semiconductor storage device of the present embodiment, the read speed of the semiconductor storage device can be made sufficiently high.

Moreover, as described in connection with the second embodiment, in the memory element employed in the present embodiment, the memory function bodies should preferably include a charge retention film arranged roughly parallel to the surface of the gate insulator. If such the memory element is employed in the semiconductor storage device of the present embodiment, variations in the memory effect of the memory elements can be reduced, and therefore, variations in the read current of the semiconductor storage device can be restrained. Furthermore, the characteristic change of the memory element during storage retention can be reduced, and therefore, the storage retention characteristic of the semiconductor storage device is improved.

Moreover, as described in connection with the third embodiment, in the memory element employed in the present embodiment, it is preferable that the memory function bodies include a charge retention film and this charge retention film has a portion extended roughly parallel to the surface of the gate insulator and a portion extended roughly parallel to the side surfaces of the gate electrode. If such the memory element is employed in the semiconductor storage device of the present embodiment, the rewrite speed of the memory element is increased, and therefore, the rewrite operation of the semiconductor storage device can be executed at high speed.

Moreover, it is preferable to employ the memory element of the seventh embodiment for the memory element employed in the present embodiment. That is, the thickness (T1) of the insulation film that separates the charge retention film (silicon nitride 242) from the channel region or the well region should preferably be smaller than the thickness (T2) of the gate insulator and not smaller than 0.8 nm. If such the memory element is employed in the semiconductor storage device of the present embodiment, it becomes possible to lower the voltage of the write operation and the erase operation or to increase the speed of the write operation and the erase operation. Furthermore, the memory effect of the memory element is increased, and therefore, the read speed of the semiconductor storage device can be increased.

Moreover, it is preferable to employ the memory element of the eighth embodiment for the memory element employed in the present embodiment. That is, the thickness (T1) of the insulation film that separates the charge retention film (silicon nitride 242) from the channel region or the well region should preferably be greater than the thickness (T2) of the gate insulator and not greater than 20 nm. If such the memory element is employed in the semiconductor storage device of the present embodiment, the retention characteristic can be improved without degrading the short-channel effect of the memory element, and therefore, a sufficient storage retention performance can be obtained even if the semiconductor storage device is densely integrated.

Moreover, the memory element employed in the present embodiment should preferably be provided with the memory function bodies that have the structure in which the silicon nitride is placed between the silicon oxides as in, for example, the second embodiment (FIG. 8). If such the memory element is employed in the semiconductor storage device of the present embodiment, it becomes possible to improve the operating speed of the semiconductor storage device and improve reliability.

Moreover, it is preferable to employ the memory element of the best mode that has already been described for the memory element employed in the present embodiment. With the arrangement, the performance of the semiconductor storage device can be optimized.

(The Eleventh Embodiment)

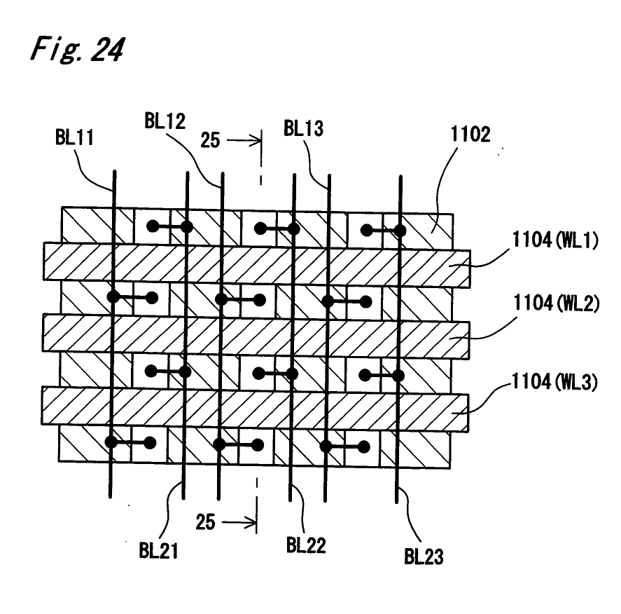

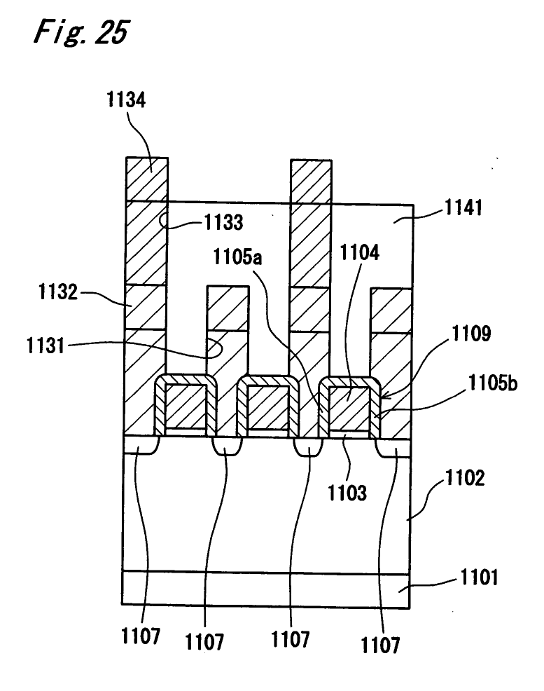

The eleventh embodiment of the present invention will be described with reference to FIGS. 24 and 25. FIG. 24 is a plan view showing the semiconductor storage device of the eleventh embodiment, FIG. 25 is a sectional view taken along the line 25-25 of FIG. 24. It is to be noted that an upper portion interconnection structure (bit lines and contacts) is expressed by wires and dots for the sake of simplicity in FIG. 24. Although a memory cell array of three rows by three columns are shown in FIGS. 24 and 25, the number of rows and the number of columns are arbitrary. In FIGS. 24 and 25, the portions that have the same functions as those of the portions shown in FIGS. 20 and 21 are denoted by the same reference numerals.

The memory cell array of the present embodiment differs from the memory cell array of the tenth embodiment in that adjoining memory elements (memory elements arranged longitudinally in the sheet plane) share a diffusion region. By thus sharing the diffusion region, the area of the diffusion region is reduced. Furthermore, the margin of the element isolation region for separating the diffusion region itself becomes unnecessary, and therefore, the area of the memory element can be largely reduced.

Even if the diffusion region is shared by the adjoining memory elements, a voltage for the desired operation can be applied to the desired memory element by a method similar to the operation method described in connection with the first embodiment. The circuit diagram of the memory cell array of the present embodiment is the same as that of FIG. 23.

According to the memory cell array of the present embodiment, the pitch between the word lines is further reduced than in the memory cell array of the tenth embodiment. Therefore, the cell area can be largely reduced, and the manufacturing cost can be further reduced.

(The Twelfth Embodiment)

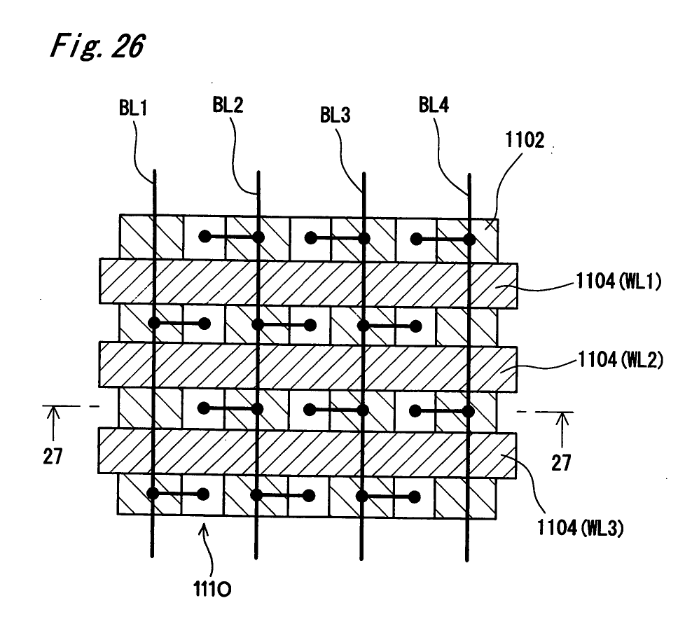

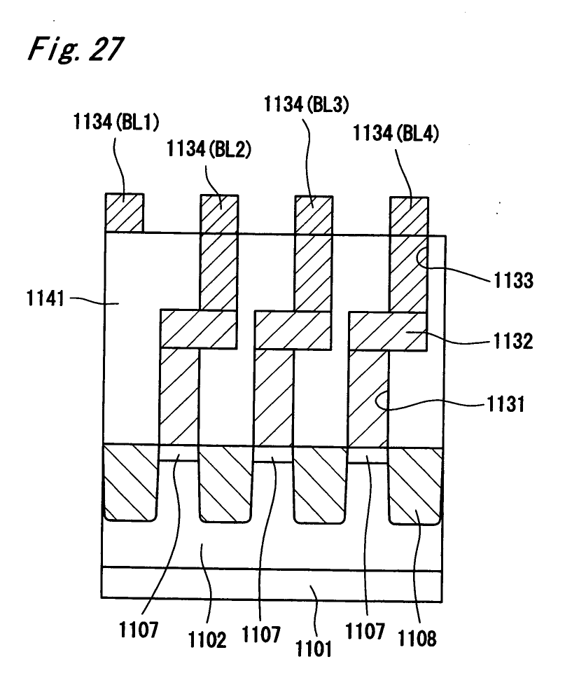

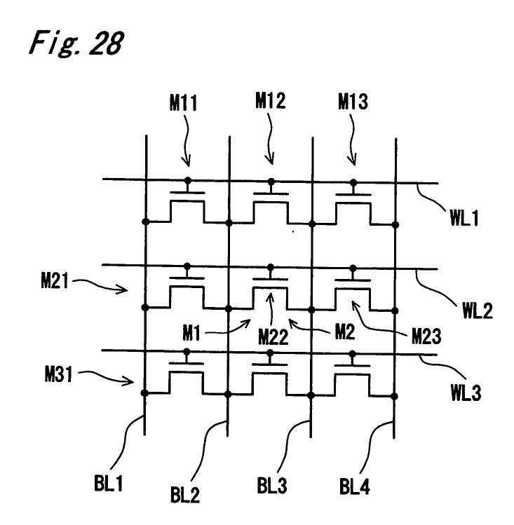

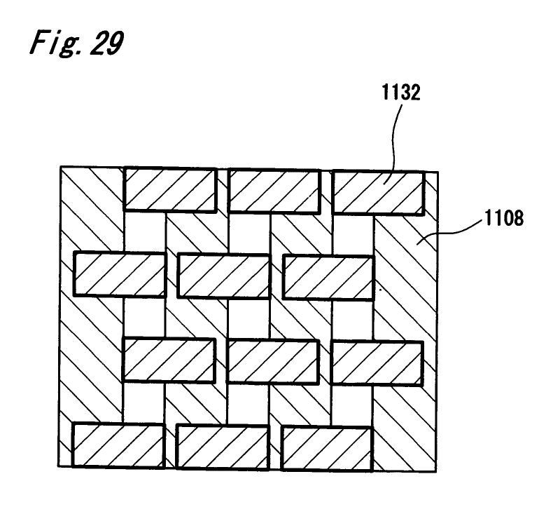

The twelfth embodiment of the present invention will be described with reference to FIGS. 26 through 29. FIG. 26 is a plan view showing the semiconductor storage device of the twelfth embodiment, FIG. 27 is a sectional view taken along the line 27-27 of FIG. 26. FIG. 28 is a circuit diagram of the semiconductor storage device of the twelfth embodiment. FIG. 29 is a view for explaining the arrangement of first layer metal interconnections of the semiconductor storage device of the twelfth embodiment. It is to be noted that an upper portion interconnection structure (bit lines and contacts) is expressed by wires and dots for the sake of simplicity in FIG. 26. Although a memory cell array of three rows by three columns are shown in FIGS. 26 through 29, the number of rows and the number of columns are arbitrary. Moreover, in FIG. 29, an element isolation region 1108 is also illustrated in order to clarify the positional relation of the first layer metal interconnections with respect to the lower layer portions. In FIGS. 26 through 29, the portions that have the same functions as those of the portions shown in FIGS. 20 through 25 are denoted by the same reference numerals.

The memory cell array of the present embodiment differs from the memory cell array of the eleventh embodiment in that the pair of the first bit line and the second bit line is made common as one bit line. That is, in FIG. 24, if the second bit line BL21 and the first bit line BL12 are made common and the second bit line BL22 and the first bit line BL13 are made common to provide individual bit lines BL2 and BL3, respectively, there is provided the memory cell array of FIG. 26.

That is, when adjoining two bit lines 1134 and 1134 are selected, one active region 1110 is specified between these two bit lines 1134 and 1134. The diffusion regions 1107 that belong to the specified active region 1110 are alternately connected to one 1134 and the other 1134 of the bit lines. Since the diffusion regions 1107 that belong to the specified active region 1110 become alternately a source region or a drain region. Therefore, it can also be expressed that the one 1134 of the selected two bit lines is connected to one of the source/drain regions that belong to the specified active region 1110, while the other 1134 of the selected two bit lines is connected to the other of the source/drain regions that belong to the specified active region 1110.

As described above, by making the first bit line and the second bit line common, the number of interconnections (bit lines) can be reduced. Therefore, the area of the memory elements can be more largely reduced, and the manufacturing cost can be reduced.

The operation of this cell array will be described next.

First of all, a read method will be described with reference to FIG. 28. In FIG. 28, the memory elements included in the memory array are each indicated by the symbol that represents an ordinary field-effect transistor for the sake of simplicity. Then, in a memory cell Mij (i=1, 2, 3, j=1, 2, 3) constructed of the aforementioned memory cells, the gate electrode is connected to the word line WLi (i=1, 2, 3), one of two source/drain diffusion regions is connected to the bit line BLj (j=1, 2, 3), and the other of the source/drain diffusion regions is connected to the bit line BLj+1 (j=1, 2, 3). Moreover, the memory cell Mij includes two memory function bodies M1 and M2 (1105a, 1105b).

In this case, it is assumed that the storage information of the memory function body (M1) located on the bit line BL2 side of the memory element M22 is subjected to read. First of all, the bit lines BL1 and BL2 are precharged with logic level L, and the bit lines BL3 and BL4 are precharged with logic level H. After the precharge is completed, the word line WL2 is made to have logic level H. At the moment when the word line WL2 comes to have logic level H, the memory elements M22 and M23 are turned on. At this time, a high voltage (logic level H-logic level L) is applied across the source and the drain of the memory element M22 to flow a current, when the amount of the current changes depending on the state of the memory function body M1. Therefore, by detecting the amount of the current flowing in the bit line BL2 or BL3 or monitoring the voltage change of the bit line BL2 or BL3, the state of the memory function body M1 can be known.

If the bit line BL1 is not precharged with logic level L during the aforementioned operation, then the memory element M21 is disadvantageously turned on to flow a current from the bit line BL1 to the bit line BL2 at the moment when the word line WL2 comes to have logic level H. Such a current obstructs the detection of the current that flows in the selected memory element M22. Therefore, the bit line BL1 should preferably be precharged with the same logic level L as that of the bit line BL2. Likewise, the bit line BL4 should preferably be precharged with the same logic level H as that of the bit line BL3.

When the storage information in the memory function body (M2) located on the bit line BL3 side of the memory element M22 is retrieved, the bit lines BL1 and BL2 are precharged with logic level H, and the bit lines BL3 and BL4 are precharged with logic level L. It is proper to make the word line WL2 have logic level H after the precharge is completed.

Table 1 shows a concrete example of voltages during the operations of write, read and erase in the memory cell array of the present embodiment. There are Lbw, Hbw, Lww and Hww, which represent the low-level potential of the bit lines, the high-level potential of the bit lines, the low-level potential of the word lines and the high-level potential of the word lines, respectively, during write. There are Lbr, Hbr, Lwr and Hwr, which represent the low-level potential of the bit lines, the high-level potential of the bit lines, the low-level potential of the word lines and the high-level potential of the word lines, respectively, during read. There are Lbe1, Lbe2, Hbe, Lwe and Hwe, which represent the low-level potential 1 of the bit lines, the low-level potential 2 of the bit lines, the high-level potential of the bit lines, the low-level potential of the word lines and the high-level potential of the word lines, respectively, during erase. Concrete voltages are exemplified in the parentheses.

The erase method shown in Table 1 is provided by the aforementioned second erase method. Therefore, a voltage Lbe2 (+0.8 V in Table 1) is applied to the p-type well region during erase. When the memory function body M1 of the memory element M22 is subjected to erase, electrons injected by the forward voltage applied across the p-type well region and the bit line BL3 become a trigger to execute the erase. Moreover, the voltage Lbe2 is applied to the bit line BL1, and this is to prevent the memory element M21 from being erroneously erased.

TABLE 1

| Operation | BL1 | BL2 | BL3 | BL4 | WL1 | WL2 | WL3 |
|---|---|---|---|---|---|---|---|
| Write (M1) | Hbw | Hbw | Lbw | Lbw | Lww | Hww | Lww |
| | (+5 V) or Open | (+5 V) | (0 V) | (0 V) or Open | (0 V) | (+5 V) | (0 V) |
| Write (M2) | Lbw | Lbw | Hbw | Hbw | Lww | Hww | Lww |
| | (0 V) or Open | (0 V) | (+5 V) | (+5 V) | (0 V) | (+5 V) | (0 V) |
| | | | | or Open | | | |
| Read (M1) | Lbr | Lbr | Hbr | Hbr | Lwr | Hwr | Lwr |
| | (0 V) | (0 V) | (+2 V) | (+2 V) | (0 V) | (+2 V) | (0 V) |
| Read (M2) | Hbr | Hbr | Lbr | Lbr | Lwr | Hwr | Lwr |
| | (+2 V) | (+2 V) | (0 V) | (0 V) | (0 V) | (+2 V) | (0 V) |
| Erase (M1) | Lbe2 | Hbe | Lbe1 | Lbe1 | Lwe | LWe | Hwe |
| | (+0.8 V) | (+5 V) | (0 V) | (0 V) | (0 V) | (−4 V) | (0 V) |
| | | | | or Open | | | |
| Erase (M2) | Lbe1 | Lbe1 | Hbe | Lbe2 | Lwe | LWe | Hwe |
| | (0 V) | (0 V) | (+5 V) | (+0.8 V) | (0 V) | (−4 V) | (0 V) |
| | or Open | | | | | | |

As is apparent from Table 1, the memory cell array of the present embodiment permits random access (read and rewrite operations every one bit). Therefore, the access efficiency can be increased in comparison with the device that must be subjected to batch erase. Moreover, there is an effect that the control circuit becomes simple since the sequence of temporary storage of the memory state, batch erase and write is also unnecessary.

According to the aforementioned read operation, when it is tried to continuously read 2-bit storage of a certain memory element (e.g., when the memory function bodies M1 and M2 of the memory element M22 are continuously read), it is required to invert all the voltages of the neighborhood bit lines (all the voltages of the bit lines BL1 through BL4 are inverted in the above example), and this therefore leads to low efficiency. Therefore, it is preferable to avoid the state of continuous alternate read by devising the address decoder circuit or the like and taking the measures of separating the addresses for the access of the right and left memory function bodies or similar measures as described later.

(The Thirteenth Embodiment)

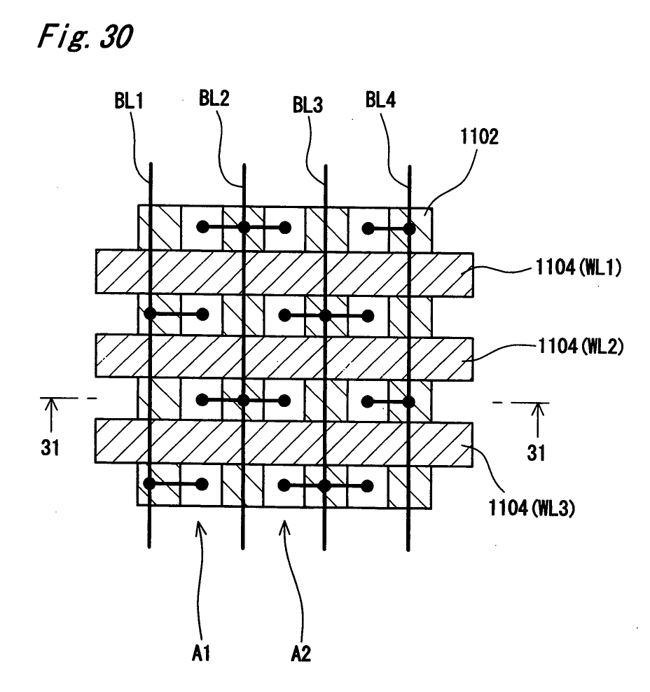

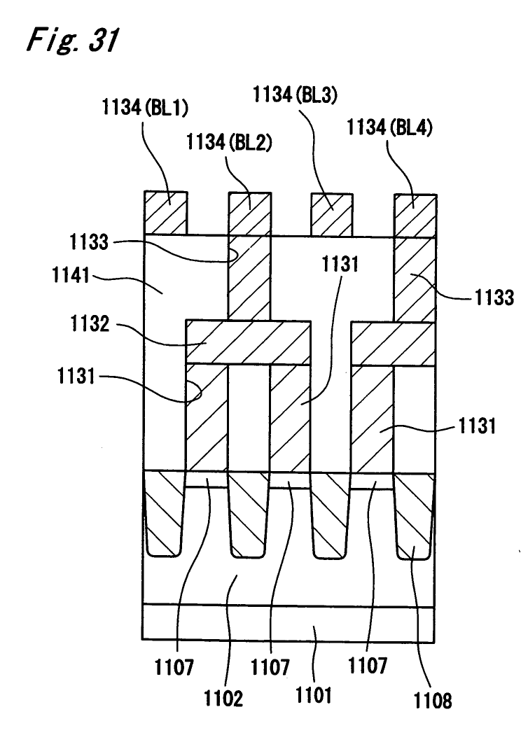

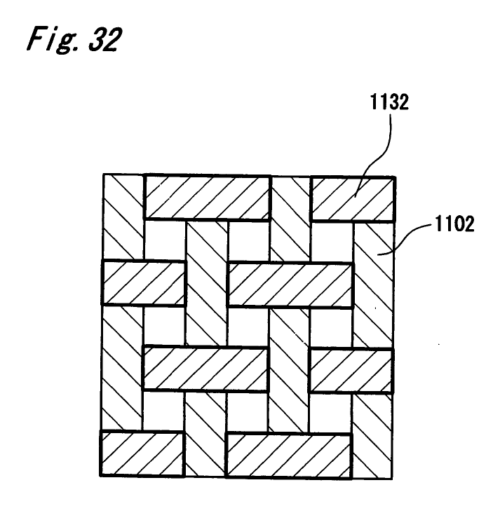

The thirteenth embodiment of the present invention will be described with reference to FIGS. 30 through 32. FIG. 30 is a plan view showing the semiconductor storage device of the thirteenth embodiment, FIG. 31 is a sectional view taken along the line 31-31 of FIG. 30. FIG. 32 is a view for explaining the arrangement of first layer metal interconnections of the semiconductor storage device of the thirteenth embodiment. It is to be noted that an upper portion interconnection structure (bit lines and contacts) is expressed by wires and dots for the sake of simplicity in FIG. 30. Although a memory cell array of three rows by three columns are shown in FIGS. 30 through 32, the number of rows and the number of columns are arbitrary. Moreover, in FIG. 32, an element isolation region 1108 is also illustrated in order to clarify the positional relation of the first layer metal interconnections with respect to the lower layer portions. In FIGS. 30 through 32, the portions that have the same functions as those of the portions shown in FIGS. 20 through 29 are denoted by the same reference numerals.

The memory cell array of the present embodiment differs from the memory cell array of the twelfth embodiment in the connection pattern of the diffusion regions to the bit lines, and this will be described below.

In this case, adjoining three bit lines (e.g., BL1, BL2 and BL3) are selected, and it is assumed that the lines are arranged in the order of the bit line 1 (BL1), the bit line 2 (BL2) and the bit line 3 (BL3). The bit line 1 corresponds to the first bit line of the present invention, the bit line 2 corresponds to the second bit line of the present invention, and the bit line 3 corresponds to the third bit line of the present invention.

In this case, the active region existing between the bit line 1 (BL1) and the bit line 2 (BL2) is assumed to be an active region 1 (A1). Likewise, the active region existing between the bit line 2 (BL2) and the bit line 3 (BL3) is assumed to be an active region 2 (A2). In this case, the bit line 2 (BL2) is connected to one of the source/drain regions that belong to the active region 1 (A1) and the active region 2 (A2). Moreover, the bit line 1 (BL1) is connected to the other of the source/drain regions that belong to the active region 1 (A1). Moreover, the bit line 3 (BL3) is connected to the other. of the source/drain regions that belong to the active region 2 (A2) That is, the active region 1 corresponds to the first active region of the present invention, and the active region 2 corresponds to the second active region of the present invention.

Furthermore, when adjoining two word lines (e.g., WL1 and WL2) are selected, the diffusion region that belongs to the active region 1 (A1) and is placed between the aforementioned two word lines and the diffusion region that belongs to the active region 2 (A2) and is placed between the aforementioned two word lines are both connected to the bit line 2 (BL2) or connected to the bit line 1 (BL1) and the bit line 3 (BL3), respectively. In other words, if the diffusion region that belongs to the active region 1 (A1) and is placed between the selected two word lines (WL1 and WL2) is one of the source/drain regions, then the diffusion region that belongs to the active region 2 (A2) and is placed between the selected two word lines is also one of the source/drain regions.

According to the memory cell array of the present embodiment, as is clarified by comparing FIG. 32 with FIG. 29, a margin between the first layer metal interconnections 1132 can be set large even if the pitch in the sidewise direction in the sheet plane is reduced. This is because the first layer metal interconnections 1132 is partially integrated since the connection pattern of the diffusion regions and the bit lines is arranged as described above, and the number of interconnections is reduced. With regard to the examples of FIGS. 29 and 32, twelve first layer metal interconnections 1132 exist in FIG. 29, whereas the number is reduced to eight in FIG. 32. Therefore, the area of the memory elements can be largely reduced, and the manufacturing cost can be reduced.

The circuit diagram of the memory cell array of the present embodiment is the same as that of FIG. 28. Therefore, the operation method is also allowed to be the same as that of the memory cell array of the twelfth embodiment.

(The Fourteenth Embodiment)

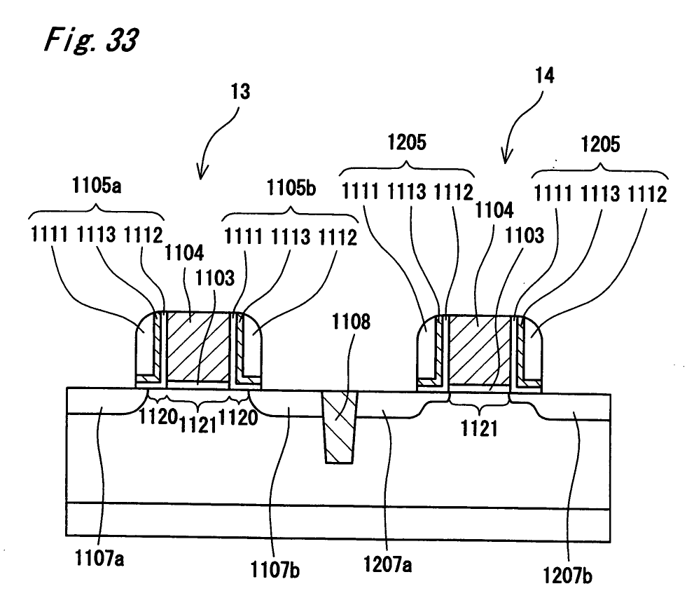

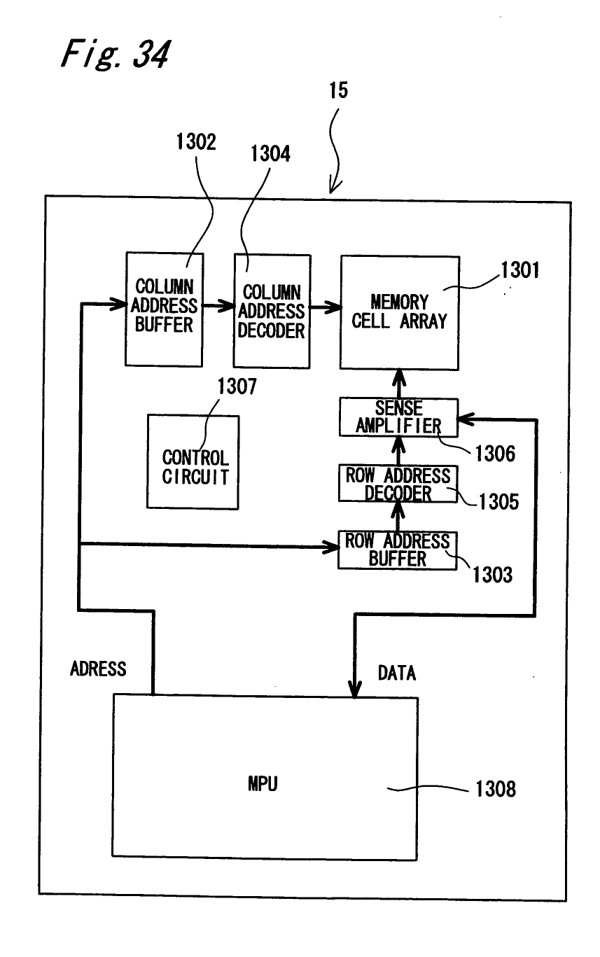

The fourteenth embodiment of the present invention will be described with reference to FIGS. 33 and 34. The semiconductor storage device of the present embodiment includes the memory cell array of the first embodiment or the second embodiment and a logic circuit section and is constructed of one chip.

FIG. 33 is a view that compares the sectional views of a memory element 13 that constitutes a memory cell array with a switching element 14 that constitutes a logic circuit section, which are juxtaposed. In this case, no description is provided for the portions denoted by the same reference numerals as those of the portions that have already been referred and described. A structural difference between the memory element 13 and the switching element 14 resides only in that diffusion regions 1207a and 1207b reach the gate ends in the switching element 14. That is, the switching element 14 has no offset region 1120. The diffusion regions 1207a and 1207b have, for example, an LDD (Lightly Doped Drain) structure. It is to be noted that a sidewall spacer 1205 of the switching element 14 has quite the same structure as that of the memory function bodies 1105a and 1105b of the memory element 13.

A procedure for forming the memory element 13 has high compatibility with an ordinary standard logic transistor formation process. As described above, the switching element 14, which constitutes the logic circuit section, has a construction similar to the construction of the memory element 13. Points of difference between the switching element 14 and the memory element 13 reside in that the sidewall spacer 1205 is not used as a memory function body in the switching element 14 and the switching element 14 has an LDD region. It is proper to select a film thickness composition ratio of silicon oxides 1111 and 1112 with respect to a silicon nitride 1113 so that the memory element 13 appropriately operates. Even if the film construction of the sidewall spacer of the switching element 14 has a structure similar to that of the memory element 13, the transistor performance is not impaired so long as the sidewall spacer width (i.e., a total film thickness of the silicon oxides 1111 and 1112 and the silicon nitride 1113) is appropriate and the element is operated within a voltage range in which no rewrite operation occurs.

With regard to the reference numerals of FIG. 33, there are 1107a and 1107b that represent diffusion regions as one example of the source/drain diffusion regions, and 1121 that represents a region below the gate electrode.

As is apparent from the description provided hereinabove, it is required to form the LDD structure only in the switching element 14 in order to consolidate the switching element 14 that constitutes the logic circuit section with the memory element 13 that constitutes the memory cell array. In order to form the LDD structure, it is proper to carry out impurity implantation for the LDD formation after the formation of the gate electrode and before the formation of the memory function bodies (sidewall spacers). Therefore, merely by masking only the memory element 13 with a photoresist when the impurity implantation for the LDD formation is carried out, it becomes possible to easily consolidate the memory element 13 with the switching element 14 that constitutes the logic circuit section. Further, if an SRAM (Static Random Access Memory) is constructed of the switching element 14, it is easy to consolidate the nonvolatile memory, the logic circuit and the SRAM.

It is to be noted that the switching element 14 is not necessarily required to have the LDD structure, and the memory element 13 is not necessarily inhibited from having an LDD structure. However, it is preferable that the switching element 14 has the LDD structure and the memory element 13 has no LDD structure. With this arrangement, the memory effect of the memory element 13 can be increased with the drive current of the switching element 14 increased. Therefore, the logic circuit section constructed of the switching element 14 operates at high speed, and satisfactory memory characteristics can be obtained from the memory cell array constructed of the memory elements 13.

FIG. 34 is a schematic view of the semiconductor storage device of the present embodiment. The semiconductor storage device 15 includes a memory cell array 1301 constructed of the memory elements 13. The semiconductor storage device 15 further includes a column address buffer 1302, a row address buffer 1303, a column address decoder 1304, a row address decoder 1305 and a sense amplifier 1306, which are to specify the memory cell that is the object to be accessed and is constructed of the switching element 14 as well as a control circuit 1307 and an MPU (Micro Processing Unit) 1308 for controlling these sections.

By consolidating the memory cell array of the twenty-first embodiment or the twenty-second embodiment described later with a logic circuit section on one chip, there is provided a low-cost LSI chip that has a large-capacity nonvolatile memory and is easy to manufacture.

If the efficiency of the read operation is considered in designing the semiconductor storage device as described above, it is inefficient to try to continuously read the 2-bit storage of a certain memory cell as described hereinbefore. This is because, if it is tried to continuously read the 2-bit information of the memory cell as described hereinabove, it is required to invert the direction of the read current (interchange the source with the drain) and invert all the voltages of the neighborhood bit lines. Therefore, it is preferable to separate the addresses of the two bits stored in a certain memory cell. For example, it is proper to give consecutive addresses to one of the stored bits of the memory cells that belong to an. identical word line and are mutually adjacent and separate the addresses of one and the other of the stored bits in an identical memory cell.

(The Fifteenth Embodiment)

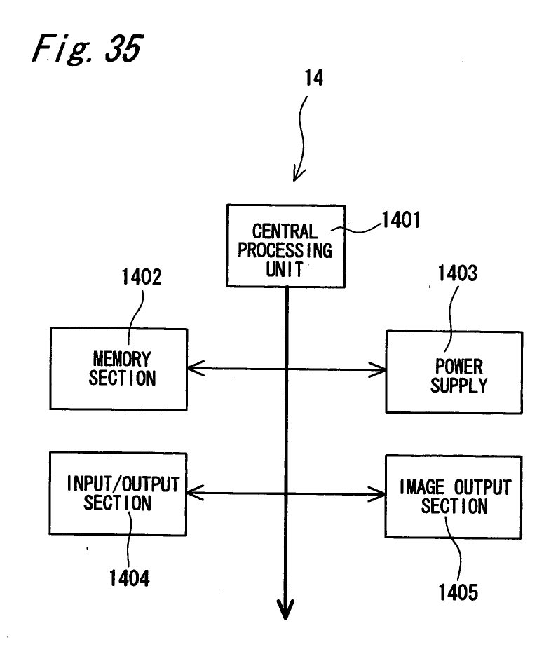

In the present embodiment, one example of the portable electronic equipment that employs the memory cell array of the tenth to thirteenth embodiment is shown. FIG. 35 is a block diagram showing the portable electronic equipment of the fifteenth embodiment of the present invention. The portable electronic equipment 14 is constructed of a central processing unit 1401, a memory section 1402, a power supply 1403, an input/output section 1404 and an image output section 1405. The memory section 1402 includes the cell array of the tenth to thirteenth embodiment.

With regard to the functions of the memory section 1402, there can be provided the function of a rewritable firmware storage device (storing a fundamental sequence and so on of hardware) and the function of a storage device for storing system setting besides the function of the main memory. It is preferable to use this memory section 1402 particularly as a storage device of a portable telephone, portable equipment of an electronic notepad or the like or a storage device of a game machine.

Since the memory section 1402 is constructed of the memory cell array of the tenth to thirteenth embodiment, it is easy to achieve high-density integration, and the manufacturing cost of the portable electronic equipment can be reduced. Moreover, it is easy to consolidate the central processing unit 1401 and so on with the memory section 1402 on one chip, and therefore, the manufacturing cost can also be further reduced. The memory section 1402 may be constructed of the memory cell array of the semiconductor device of the fourteenth embodiment. According to the portable electronic equipment of the present invention, it is possible to further reduce the parts count and further reduce the manufacturing cost by mounting the semiconductor device of the present invention.

(The Sixteenth Embodiment)

In the present embodiment, a semiconductor storage device (memory cell array) constituted by arranging memory elements will be described.

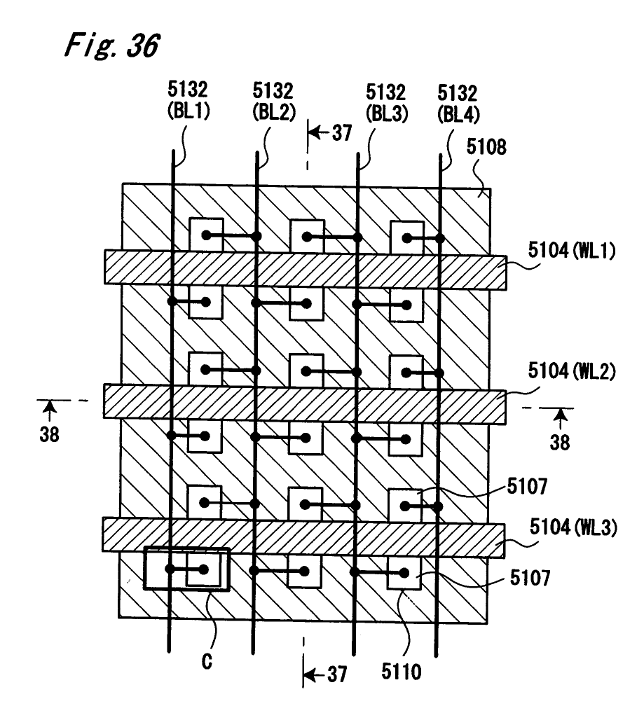

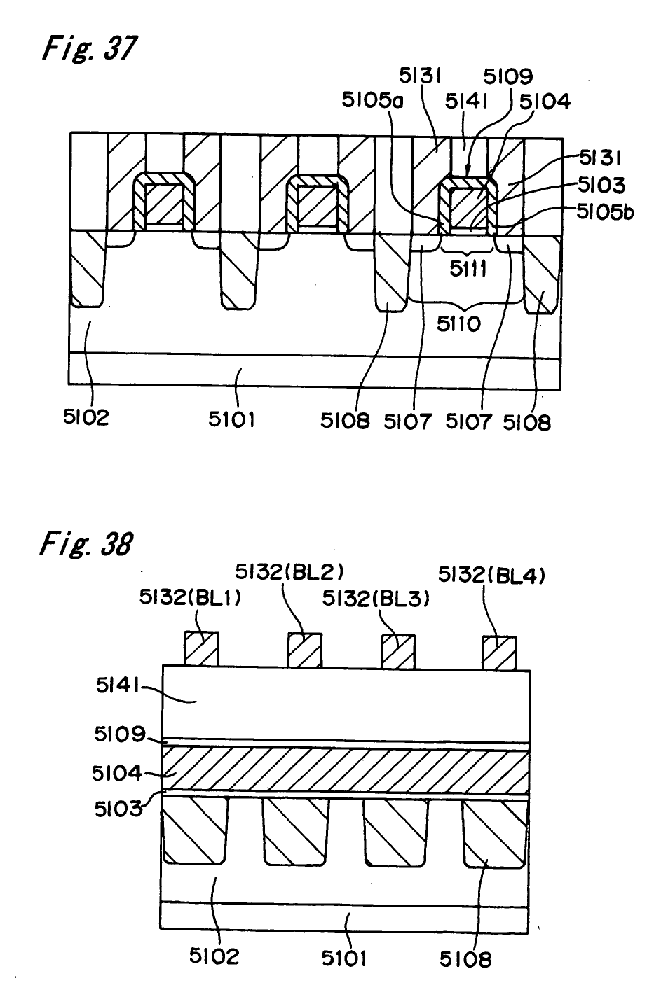

FIG. 36 is a schematic plan view of the memory cell array of the sixteenth embodiment of the present invention. FIG. 37 is a schematic sectional view taken along the line 37-37 of FIG. 36. FIG. 38 is a schematic sectional view taken along the line 38-38 of FIG. 36. It is to be noted that an upper portion interconnection structure (bit lines and contacts) is expressed by wires and dots for the sake of simplicity in FIG. 36. Although a memory cell array of three rows by three columns are shown in FIGS. 36 through 38, the number of rows and the number of columns are arbitrary.

In the aforementioned memory cell array, as shown in FIG. 37, a semiconductor substrate 5101 has a p-type well region 5102. As shown in FIG. 36, the surface of this p-type well region 5102 is divided into an element isolation region 5108 and a plurality of active regions 5110 arranged in a matrix form. A memory element is formed as one example of the memory element in each active region 5110. Moreover, word lines 5104 (WL1, WL2, WL3), which function as gate electrodes of the memory elements, are formed on the semiconductor substrate 5101 while being extended sidewise in the sheet plane in FIG. 36 and arranged side by side longitudinally in the sheet plane of FIG. 36.

As shown in FIG. 37, a silicon nitride 5109 is formed on the side surfaces and the upper surfaces of the word lines 5104 (WL1, WL2, WL3). That is, the side surfaces and the upper surfaces of the word lines 5104 are covered with the silicon nitride 5109. In the silicon nitride 5109, the portions existing on opposite sidewalls of the word line 5104 serve as memory function bodies 5105a and 5105b. Moreover, a gate insulator 5103 is formed between the word line 5104 and each active region 5110. The region located below this gate insulator 5103 serves as a channel region 5111 of the memory element, and source/drain diffusion regions 5107 are formed on opposite sides of the channel region 5111. Then, as shown in FIG. 36, the source/drain diffusion regions 5107 of an identical column are electrically connected in common to bit lines 5132 (BL1, BL2, BL3, BL4). With regard to adjoining two bit lines 5132 (e.g., BL1, BL2) among these bit lines 5132, one bit line 5132 (BL1) is electrically connected to one of the source/drain diffusion regions 5107 of an identical column, and the other bit line 5132 (BL2) is electrically connected to the other of the source/drain diffusion regions 5107 of the identical column. Moreover, the bit lines 5132 (BL1, BL2, BL3, BL4) and the source/drain diffusion regions 5107 are electrically connected together via each contact 5131 (see FIG. 37).

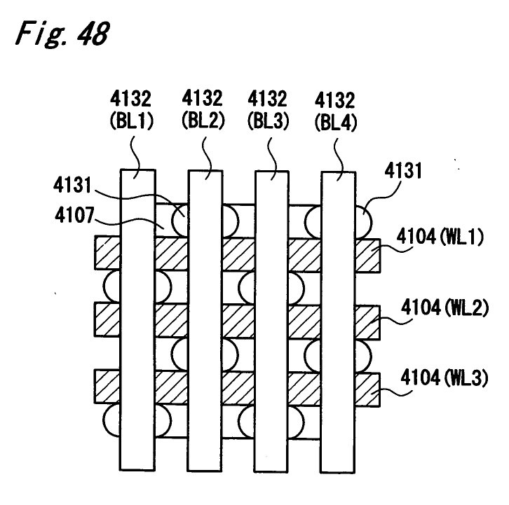

The contact 5131 is formed by internally filling a contact hole (hole for connecting the source/drain diffusion region 5107 to the first layer metal interconnection) with a conductive material. The contact hole is required to be sufficiently large for the connection of the source/drain diffusion region 5107 to the first layer metal interconnection and required to have an increased length in a direction in which the source/drain diffusion region 5107 and the first layer metal interconnection are connected together. Therefore, the contact hole has an elliptic cylinder configuration. That is, the contact 5131 of the elliptic cylinder configuration is formed inside, for example, the portion C enclosed by a solid line square in FIG. 36. Although not shown in FIG. 36, the contact 5131 of the elliptic cylinder configuration is formed into roughly the same configuration as that of a contact 4131 shown in FIG. 48 described later in connection with the nineteenth embodiment in a plane. Moreover, the contact 5131 of an elliptic cylinder configuration is formed also in the portions other than the portion C.

As described above, by employing the contact 5131 of the elliptic cylinder configuration, the diffusion region and the metal interconnection (bit line) can be arranged while being displaced largely in the horizontal direction in the figure as in, for example, the memory cell array shown in FIG. 36 (in the memory cell array shown in FIG. 36, a metal interconnection is arranged on the element isolation region 5108). Therefore, metal interconnections can be arranged at appropriate intervals without being overlapped.

Moreover, a distance between the metal interconnections can be maintained large without using the contact of the elliptic cylinder configuration in comparison with the case where the metal interconnections are routed just over the diffusion region. Therefore, it becomes possible to reduce the distance between the metal interconnections in the permitted range and to reduce the area of the memory cell array.

Moreover, as shown in FIG. 38, the bit lines 5132 are formed above the element isolation regions 5108. Then, an interlayer insulator 5141 exists between the bit lines 5132 and the silicon nitride 5109.

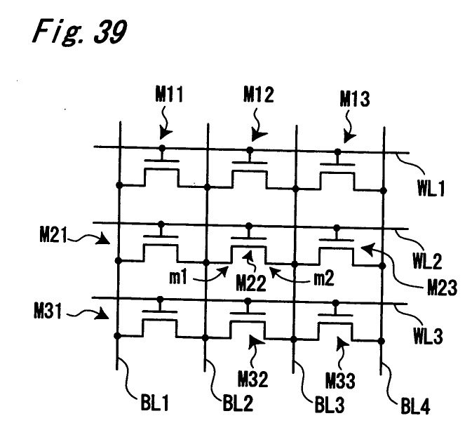

FIG. 39 is a circuit diagram of the memory cell array. In FIG. 39, the memory elements included in the memory array are each indicated by the symbol that represents an ordinary field-effect transistor for the sake of simplicity. Then, in a memory cell Mij (i=1, 2, 3, j=1, 2, 3) constructed of the aforementioned memory cells, the gate electrode is connected to the word line WLi (i=1, 2, 3), one of two source/drain diffusion regions is connected to the bit line BLj (j=1, 2, 3), and the other of the source/drain diffusion regions is connected to the bit line BLj+1 (j=1, 2, 3). Moreover, the memory cell Mij includes two memory function bodies m1 and m2 (5105a, 5105b).

In order to operate the aforementioned memory cell array, it is proper to apply voltages required for the operation method of the memory cell Mij to the desired memory cell via specified word line WLi, bit line BLj and bit line BLj+1. For example, when one of the memory function bodies m1 and m2 of the memory cell M11 is subjected to write, it is proper to apply +5 V to the word line WL1, +5 V to the bit line BL1 and 0 V to the bit line BL2. When the other of the memory function bodies m1 and m2 of the memory cell M11 is subjected to write, it is proper to apply +5 V to the word line WL1, 0 V to the bit line BL1 and +5 V to the bit line BL2. At this time, it is proper to apply, for example, 0 V to the other nonselected word lines and nonselected bit lines.

The operation method of the memory elements that constitutes the memory cells Mij will be described in detail in connection with another embodiment.

As is apparent from the above description, the memory cell array of the present embodiment has the memory cells Mij arranged in a matrix form. This memory cell Mij can singly store two bits, and the gate insulator 5103 can be formed into a thin film Therefore, the memory cell Mij can easily be scaled down in size. Therefore, the memory cell array can easily be scaled down in size, and the manufacturing cost can also be reduced.

Moreover, as described above, the process for forming the aforementioned memory elements has a great resemblance to the ordinary CMOS (Complementary Metal-Oxide Semiconductor) process and is able to be manufactured much easier than the nonvolatile memory such as conventional EEPROM (Electrically Erasable Programmable ROM) that has a floating gate. Therefore, the memory cell array of the present invention can easily be manufactured, and it becomes easy to consolidate the main control section with a logic circuit.

Although the side surfaces and the upper surfaces of the gate electrodes (word lines 5104) are covered with the silicon nitride 5109 in the memory element employed in the aforementioned embodiment, it is acceptable to cover only the side surfaces of the gate electrodes (word lines 5104) with the silicon nitride.

Moreover, it is acceptable to form memory function bodies that have the function to retain electric charge or polarization in place of the silicon nitride 5109. The memory function bodies are formed on the active region on opposite sides of the word line. Such the memory function body has been described in connection with the second embodiment.

It is acceptable to construct the memory function bodies of, for example, silicon nitride that retains electric charge and silicon oxides that place the silicon nitride between the silicon oxides. In this case, it is preferable that the silicon nitride overlaps each of the source/drain diffusion regions. If the memory element including such the memory function bodies is employed in the semiconductor storage device of the present embodiment, the read speed of the semiconductor storage device can be made sufficiently high.

Moreover, the memory function bodies should preferably include a charge retention film arranged roughly parallel to the surface of the gate insulator. If the memory element including such the memory function bodies is employed in the semiconductor storage device of the present embodiment, variations in the memory effect of the memory elements can be reduced. Therefore, variations in the read current of the semiconductor storage device can be restrained. Furthermore, the characteristic change of the memory elements during storage retention can be reduced, and therefore, the storage retention characteristic of the semiconductor storage device is improved.

Moreover, it is preferable that the charge retention film included in the memory function bodies has a portion that is roughly parallel to the surface of the gate insulator and has a portion that is extended roughly parallel to the side surfaces of the gate electrode. If such the memory function bodies are employed in the semiconductor storage device of the present embodiment, the rewrite speed of the memory element is increased, and therefore, the rewrite operation of the semiconductor storage device can be executed at high speed.

Moreover, when an insulation film is formed between the charge retention film and the channel region or the well region, the thickness of this insulation film should preferably be smaller than the thickness of the gate insulator and not smaller than 0.8 nm. If the memory element including such the insulation film is employed in the semiconductor storage device of the present embodiment, it becomes possible to lower the voltage of the write operation and the erase operation or increase the speed of the write operation and the erase operation. Furthermore, the memory effect of the memory element is increased, and therefore, it becomes possible to increase the read speed of the semiconductor storage device.

Moreover, when an insulation film is formed between the charge retention film and the channel region or the well region, the thickness of this insulation film should preferably be greater than the thickness of the gate insulator and not greater than 20 nm. If the memory element including such the insulation film is employed in the semiconductor storage device of the present embodiment, the retention characteristic can be improved without degrading the short-channel effect of the memory element, and therefore, a sufficient storage retention performance can be obtained even if the semiconductor storage device is densely integrated.

Moreover, the memory element of the present embodiment should preferably have two memory function bodies constructed of the silicon nitride and the silicon oxides that place the silicon nitride between the silicon oxides. If such the memory element is employed in the semiconductor storage device of the present embodiment, it becomes possible to improve the operating speed of the semiconductor storage device and improve the reliability.

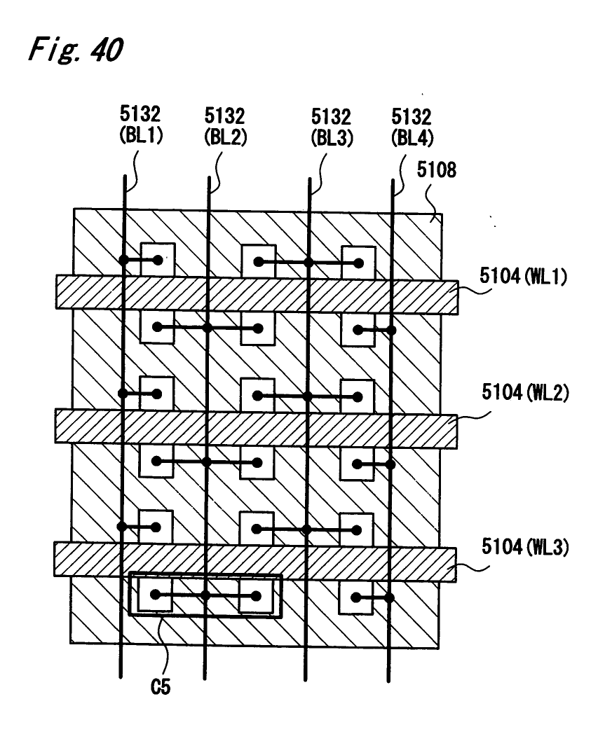

FIG. 40 shows a modification example of the aforementioned memory cell array.

In the above-mentioned modification example, a contact-to-contact distance is increased in the direction in which the word lines 5104 are extended in comparison with the memory cell array shown in FIG. 36. Therefore, it becomes possible to reduce the contact-to-contact distance in the permitted range and shorten the distance between the bit lines. In this case, a contact of an elliptic cylinder configuration is formed inside, for example, the portion C5 enclosed by a solid line square in FIG. 40. Moreover, a contact of an elliptic cylinder configuration is formed also in the portions other than the inside of the portion C5. The contact of the elliptic cylinder configuration is formed into roughly the same configuration as that of the contact 4131 of FIG. 48 described later in a plane. Each of the contacts is electrically connected to two source/drain diffusion regions adjoining in an identical row.

Also, in the aforementioned modification example, the margin between the metal interconnections becomes unnecessary by employing the contact of the elliptic cylinder configuration in comparison with the case of the connection provided by the metal interconnections in the upper portions, so that the occupation area can be reduced and the manufacturing processes are also simplified. That is, the interval between the bit lines 5132 can be narrowed, and the manufacturing processes can be simplified.

Although the gate electrode of the memory element is part of the word line 5104 in the aforementioned embodiment, the gate electrode is not necessarily required to be part of the word line. That is, the gate electrode of the memory element may be provided separately from the word line. In this case, the word line connects the gate electrodes of the memory elements of an identical row.

(The Seventeenth Embodiment)

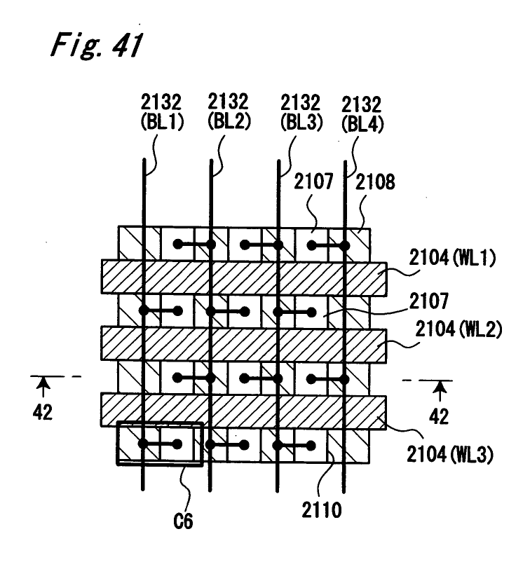

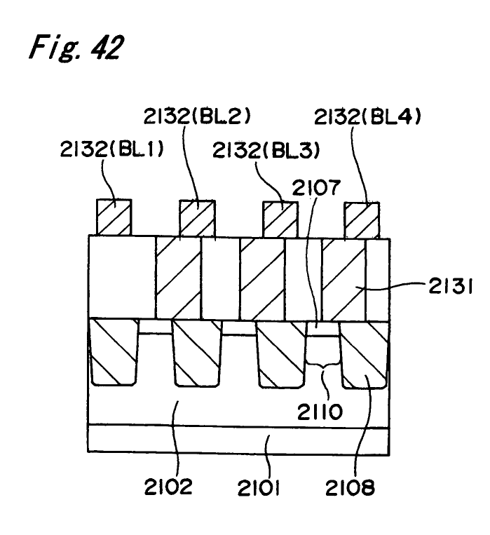

The memory cell array of the present embodiment will be described with reference to FIGS. 41 and 42.

FIG. 41 is a schematic plan view of the memory cell array of the seventeenth embodiment of the present invention, FIG. 42 is a schematic sectional view taken along the line 42-42 of FIG. 41. It is to be noted that the circuit diagram of the memory cell array is the same as that of FIG. 39. Moreover, it is to be noted that an upper portion interconnection structure (bit lines and contacts) is expressed by wires and dots for the sake of simplicity in FIG. 41. Although a memory cell array of three rows by three columns are shown in FIGS. 41 and 42, the number of rows and the number of columns are arbitrary.

As is apparent from FIG. 41, the memory cell array of the present embodiment differs from the memory cell array of the sixteenth embodiment in that two memory elements adjoining in an identical column (the memory elements arranged longitudinally in the sheet plane of FIG. 41) share one source/drain diffusion region 2107. By thus sharing one source/drain diffusion region 2107 by the memory elements adjoining in the identical column, the area of the source/drain diffusion region 2107 itself is reduced. That is, the number of the source/drain diffusion regions 2107 necessary for the memory cell array is reduced. Moreover, the margin of the element isolation region 2108 for separating the source/drain diffusion regions 2107 themselves becomes unnecessary. That is, the element isolation region 2108 is not required to be formed between the memory elements adjoining in the identical column. Therefore, the area of the memory cells can be largely shrunk.

Moreover, the configuration of the element isolation region 2108 is simplified and therefore becomes easy to manufacture, so that the yield is improved.

Also, in the memory cell array of the present embodiment, a voltage for the desired operation can be applied to the desired memory cell by a method similar to that of the sixteenth embodiment.

Moreover, also in the memory cell array of the present embodiment, a contact 2131 of an elliptic cylinder configuration as shown in FIG. 42 is formed inside, for example, the portion C6 enclosed by a solid line square in FIG. 41. Moreover, a contact 2131 of an elliptic cylinder configuration is formed also in the portions other than the portion C6. This contact 2131 of the elliptic cylinder configuration is formed roughly into the same configuration as that of the contact 4131 of FIG. 48 described later in a plane. This contact 2131 is constructed of a conductive material and designed so as to electrically connect bit lines 2132 (BL1, BL2, BL3, BL4) to the source/drain diffusion regions 2107 of the active region 2110.

As described above, the contact 2131 of the elliptic cylinder configuration is employed, and therefore, the distance between the metal interconnections can be maintained large without using a contact of an elliptic cylinder configuration in comparison with the case where the metal interconnections are routed just over the diffusion region. Therefore, it becomes possible to reduce the distance between the metal interconnections in the permitted range and shrink the area of the memory cell array.

Moreover, according to the memory cell array of the present embodiment, the pitch between the word lines 2104 (WL1, WL2, WL3) can be narrowed in comparison with the memory cell array of the sixteenth embodiment. Therefore, the memory cell array of the present embodiment can be reduced in size further than the memory cell array of the sixteenth embodiment, and the manufacturing cost can be further reduced.

When adjoining two bit lines 2104 are selected among the bit lines 2132, one active region 2110 is defined between these two bit lines 2132. A plurality of source/drain diffusion regions 2107, which belong to the defined active region 2110, are alternately connected to one of the two bit lines 2132 and to the other of the two bit lines 2132. That is, one of the adjoining two source/drain diffusion regions among the plurality of source/drain diffusion regions 2107 is connected to one of the two bit lines 2132, and the other of the two source/drain diffusion regions is connected to the other of the two bit lines 2132. Otherwise, the source/drain diffusion regions 2107, which belong to the defined active region 2110, serve alternately as a source region or a drain region. Therefore, it can also be expressed that one of the two bit lines 2104 is connected to one of the source/drain diffusion regions 2107 that belong to the defined active region 2110, and the other of the selected two bit lines 2104 is connected to the other of the source/drain diffusion regions 2107 that belong to the defined active region 2110.

The operation of the aforementioned memory cell array will be described below with reference to FIG. 39.

Reference is first made to the read method of the memory cell array. In this case, for example, the storage information of the memory function body m1 located on, for example, the bit line BL2 side of the memory cell M22 is subjected to read.

First of all, the bit lines BL1 and BL2 are precharged with logic level L, and the bit lines BL3 and BL4 are precharged with logic level H. After the precharge of the bit lines BL1, BL2, BL3 and BL4 is completed, the word line WL2 is made to have logic level H. At the moment when the word line WL2 comes to have logic level H, the memory cell M22 is turned on. At this time, a high voltage (logic level H−logic level L) is applied across the source and the drain of the memory cell M22 and a current flows. The amount of the current changes depending on the state of the memory function body m1. Therefore, by detecting the amount of the current flowing through the bit line BL2 or the bit line BL3 or monitoring the voltage change of the bit line BL2 or the bit line BL3, the state of the memory function body m1 can be known.

If the bit line BL1 is not precharged with logic level L during the aforementioned operation, then the memory element M21 is disadvantageously turned on to flow a current from the bit line BL1 to the bit line BL2 at the moment when the word line WL2 comes to have logic level H. Such a current obstructs the detection of the current that flows in the selected memory element M22. Therefore, the bit line BL1 should preferably be precharged with the same logic level L as that of the bit line BL2. Likewise, the bit line BL4 should preferably be precharged with the same logic level H as that of the bit line BL3.

When the storage information of the memory function body m2 located on the bit line BL3 side of the memory cell M22 is retrieved, it is proper to precharge the bit line BL1 and the bit line BL2 with logic level H, precharge the bit lines BL3 and BL4 with logic level L and thereafter make the word line WL2 have logic level H.

The following Table 2 shows a concrete example of voltages during the operations of write, read and erase in the memory cell array of the present embodiment. In Table 2, there are Lbw, Hbw, Lww and Hww, which represent the low-level potential of the bit lines, the high-level potential of the bit lines, the low-level potential of the word lines and the high-level potential of the word lines, respectively, during write. There are Lbr, Hbr, Lwr and Hwr, which represent the low-level potential of the bit lines, the high-level potential of the bit lines, the low-level potential of the word lines and the high-level potential of the word lines, respectively, during read. There are Lbe1, Lbe2, Hbe, Lwe and Hwe, which represent the low-level potential 1 of the bit lines, the low-level potential 2 of the bit lines, the high-level potential of the bit lines, the low-level potential of the word lines and the high-level potential of the word lines, respectively, during erase. Concrete voltages are exemplified in the parentheses in Table 2 with regard to Lbw, Hbw, . . . , Lwe and Hwe.

The erase method shown in Table 2 is provided by the second erase method described later. Therefore, during erase, a voltage Lbe2 (+0.8 V in Table 2) is applied to the p-type well region 2102 on the semiconductor substrate 2101. When the information of, for example, the memory function body m1 of the memory cell M22 is subjected to erase, electrons injected by the forward voltage applied across the p-type well region 2102 and the bit line BL3 become a trigger to erase the information of the memory function body m1. Moreover, the voltage Lbe2 is applied to the bit line BL1, and this is to prevent the memory element M21 from being erroneously erased.

TABLE 2

| Operation | BL1 | BL2 | BL3 | BL4 | WL1 | WL2 | WL3 |
|---|---|---|---|---|---|---|---|
| Write (M1) | Hbw | Hbw | Lbw | Lbw | Lww | Hww | Lww |
| | (+5 V) or Open | (+5 V) | (0 V) | (0 V) | (0 V) | (+5 V) | (0 V) |
| | | | | or Open | | | |
| Write (M2) | Lbw | Lbw | Hbw | Hbw | Lww | Hww | Lww |
| | (0 V) or Open | (0 V) | (+5 V) | (+5 V) | (0 V) | (+5 V) | (0 V) |
| | | | | or Open | | | |
| Read (M1) | Lbr | Lbr | Hbr | Hbr | Lwr | Hwr | Lwr |
| | (0 V) | (0 V) | (+2 V) | (+2 V) | (0 V) | (+2 V) | (0 V) |
| Read (M2) | Hbr | Hbr | Lbr | Lbr | Lwr | Hwr | Lwr |
| | (+2 V) | (+2 V) | (0 V) | (0 V) | (0 V) | (+2 V) | (0 V) |
| Erase (M1) | Lbe2 | Hbe | Lbe1 | Lbe1 | Lwe | LWe | Hwe |
| | (+0.8 V) | (+5 V) | (0 V) | (0 V) | (0 V) | (−4 V) | (0 V) |
| | | | | or Open | | | |
| Erase (M2) | Lbe1 | Lbe1 | Hbe | Lbe2 | Lwe | LWe | Hwe |
| | (0 V) or Open | (0 V) | (+5 V) | (+0.8 V) | (0 V) | (−4 V) | (0 V) |
| Write (M1) | Hbw | Hbw | Lbw | Lbw | Lww | Hww | Lww |
| | (+5 V) | (+5 V) | (0 V) | (0 V) or Open | (0 V) | (+5 V) | (0 V) |
| | or Open | | | | | | |
| Write (M2) | Lbw | Lbw | Hbw | Hbw | Lww | Hww | Lww |
| | (0 V) | (0 V) | (+5 V) | (+5 V) | (0 V) | (+5 V) | (0 V) |
| | or Open | | | or Open | | | |
| Read (M1) | Lbr | Lbr | Hbr | Hbr | Lwr | Hwr | Lwr |
| | (0 V) | (0 V) | (+2 V) | (+2 V) | (0 V) | (+2 V) | (0 V) |
| Read (M2) | Hbr | Hbr | Lbr | Lbr | Lwr | Hwr | Lwr |
| | (+2 V) | (+2 V) | (0 V) | (0 V) | (0 V) | (+2 V) | (0 V) |
| Erase (M1) | Lbe2 | Hbe | Lbe1 | Lbe1 | Lwe | LWe | Hwe |
| | (+0.8 V) | (+5 V) | (0 V) | (0 V) | (0 V) | (−4 V) | (0 V) |
| | | | | or Open | | | |
| Erase (M2) | Lbe1 | Lbe1 | Hbe | Lbe2 | Lwe | LWe | Hwe |
| | (0 V) | (0 V) | (+5 V) | (+0.8 V) | (0 V) | (−4 V) | (0 V) |
| | or Open | | | | | | |

As is apparent from Table 1, the memory cell array of the present embodiment permits random access (read and rewrite operations every one bit). Therefore, the access efficiency can be increased in comparison with the device that must be subjected to batch erase. Moreover, there is an effect that the control circuit becomes simple since the sequence of temporary storage of the memory state, batch erase and write is also unnecessary.

According to the aforementioned read operation, when it is tried to continuously read 2-bit storage of a certain memory cell (e.g., when the memory function bodies m1 and m2 of the memory element M22 are continuously read), it is required to invert all the voltages of the neighborhood bit lines BL1 through BL4, and this therefore leads to low efficiency. Therefore, it is preferable to avoid the state of continuous alternate read by devising the address decoder circuit or the like and taking the measures of separating the addresses for the access of the right and left memory function bodies m1 and m2 or similar measures as described later.

Although the gate electrode of the memory element is part of the word line 2104 in the aforementioned embodiment, the gate electrode is not necessarily required to be part of the word line. That is, the gate electrode of the memory element may be provided separately from the word line. In this case, the word line connects the gate electrodes of the memory elements of an identical row.

(The Eighteenth Embodiment)

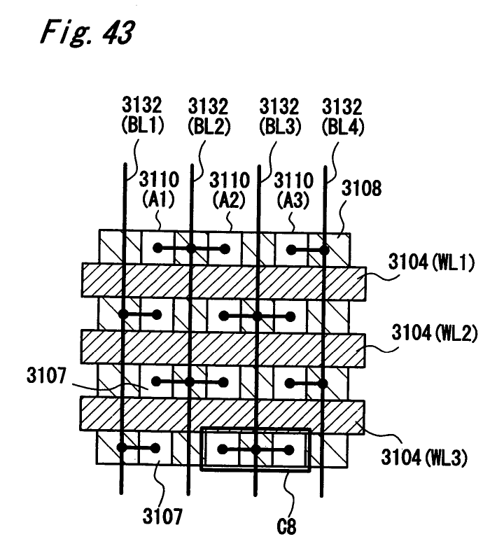

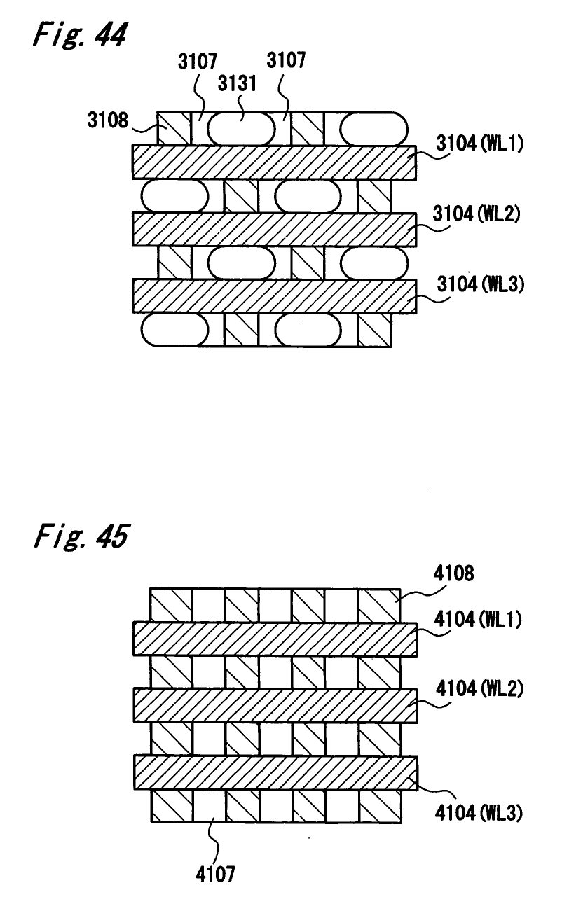

The eighteenth embodiment of the present invention will be described with reference to FIGS. 43 and 44.

FIG. 43 is a schematic plan view of the memory cell array of the eighteenth embodiment of the present invention, FIG. 44 is a view for explaining the arrangement of the first layer metal interconnections of the memory cell array of the eighteenth embodiment. It is to be noted that an upper portion interconnection structure (bit lines and contacts) is expressed by wires and dots for the sake of simplicity in FIG. 43. Although a memory cell array of three rows by three columns are shown in FIGS. 43 and 44, the number of rows and the number of columns are arbitrary.

The memory cell array of the present embodiment differs from the memory cell array of the seventeenth embodiment in the connection pattern of the source/drain diffusion regions 3107 to the bit lines 3132 (BL1, BL2, BL3, BL4).

In the memory cell array of the present embodiment, the surface of the well region is divided into an element isolation region 3108 and a plurality of belt-shaped active regions 3110 (A1, A2, A3). In an active region A1 located between the bit line BL1 and the bit line BL2, one of adjoining two source/drain diffusion regions 3107 is connected to the bit line BL1, and the other of the two source/drain diffusion regions 3107 is connected to the bit line BL2. Moreover, in an active region A2 located between the bit line BL2 and the bit line BL3, one of adjoining two source/drain diffusion regions 3107 is connected to the bit line BL2, and the other of the two source/drain diffusion regions 3107 is connected to the bit line BL3. In an active region A3 located between the bit line BL3 and the bit line BL4, one of adjoining two source/drain diffusion regions 3107 is connected to the bit line BL3, and the other of the two source/drain diffusion regions 3107 is connected to the bit line BL4.

Moreover, two source/drain diffusion regions 3107 adjoining in an identical row are electrically connected to one bit line 3132 (BL1, BL2, BL3, BL4) via a contact of an elliptic cylinder configuration. In concrete, in a region on the upper side of the word line WL1 in the figure, a source/drain diffusion region 3107 that belongs to the active region A1 and a source/drain diffusion region 3107 that belongs to the active region A2 are electrically connected in common to the bit line BL2 via a contact 3131 of an elliptic cylinder configuration (see FIG. 44). In a region located between the word line WL1 and word line WL2, the source/drain diffusion region 3107 that belongs to the active region A2 and a source/drain diffusion region 3107 that belongs to the active region A3 are electrically connected in common to the bit line BL3 via a contact 3131 of an elliptic cylinder configuration. In a region located between the word line WL2 and word line WL3, the source/drain diffusion region 3107 that belongs to the active region A1 and the source/drain diffusion region 3107 that belongs to the active region A2 are electrically connected in common to the bit line BL2 via a contact 3131 of an elliptic cylinder configuration. In a region on the lower side of the word line WL3 in the figure, the source/drain diffusion region 3107 that belongs to the active region A2 and the source/drain diffusion region 3107 that belongs to the active region A3 are electrically connected in common to the bit line BL3 via a contact 3131 of an elliptic cylinder configuration in the portion C8 indicated by a solid line square.

In other words, for example, if the source/drain diffusion region 3107, which belongs to the active region A1 located between the word line WL1 and the word line WL2, is a source region, then the source/drain diffusion region 3107, which belongs to the active region A2 located between the word line WL1 and word line WL2, also serves as a source region.

According to the memory cell array of the present embodiment, the margin between the first layer metal interconnections can be set large even if the pitch in the sidewise direction (direction of row) in FIG. 43 is reduced. Therefore, the memory cell area can be more largely shrunk, and the manufacturing cost can be reduced.

The circuit diagram of the memory cell array of the present embodiment is the same as that of FIG. 39. Therefore, the operation method is also allowed to be the same as that of the memory cell array of the seventeenth embodiment.

If the structure of this device is described in other words, the element isolation region and the active region are alternately formed in a line on the semiconductor substrate, and the word line is formed so as to intersect the element isolation region and the active region. Then, a region that intersects the word line serves as a channel region in the active region, and the region that does not intersect the word line serves as the source/drain diffusion region. Then, two source/drain regions adjoining in an identical row with interposition of the element isolation region are electrically connected to one bit line via one contact. Moreover, paying attention to three channel regions of an identical column, two source/drain diffusion regions located on opposite sides of one element isolation region between channel regions are electrically connected together by one contact, and the two source/drain diffusion regions located on opposite sides of the other terminal element isolation region between channel regions are not electrically connected together in terms of structure.

Although the gate electrode of the memory element is part of the word line 3104 in the aforementioned embodiment, the gate electrode is not necessarily required to be part of the word line. That is, the gate electrode of the memory element may be provided separately from the word line. In this case, the word line connects the gate electrodes of the memory elements of an identical row.

(The Nineteenth Embodiment)

The manufacturing method of the memory cell array of the present embodiment will be described with reference to FIGS. 45 through 48.

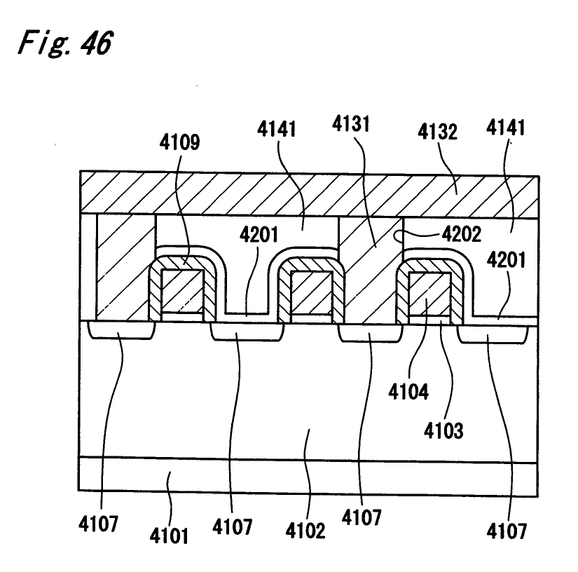

FIG. 45 shows a schematic top view of a semiconductor substrate during the forming processes of the memory cells of the memory cell array of the nineteenth embodiment, and FIG. 46 shows a schematic sectional view of the memory cell array.

The forming processes of the memory cells of the memory cell array will be described with reference to FIGS. 45 and 46.

First of all, as shown in FIG. 45, a trench element isolator (trench-type element isolator) 4108 is formed as one example of the element isolation region on a semiconductor substrate 4101 (see FIG. 46) constructed of, for example, a p-type single-crystal silicon that has a specific resistance of about several ohms per centimeter, and thereafter, a p-type well 4102 (see FIG. 46) is formed. The p-type well 4102 is isolated by the trench element isolator (trench-type element isolator) 4108.

The trench element isolator 4108 is formed by forming a trench by dry etching the semiconductor substrate, thereafter depositing a silicon oxide on the semiconductor substrate including the inside of this groove by the CVD (Chemical Vapor Deposition) method and subsequently leaving the silicon oxide only inside the trench by polishing the silicon oxide by the chemical mechanical polishing (CMP) method.

The p-type well 101 is formed by carrying out ion implantation of a p-type impurity of, for example, B (boron) into the semiconductor substrate and thereafter thermally diffusing the impurity by carrying out annealing.

Next, the surface of the semiconductor substrate is cleaned, and thereafter, a gate oxide (not shown) of a film thickness of 1 to 20 nm is formed on the semiconductor substrate by carrying out an oxidation process, forming a polysilicon film of a thickness of 50 to 400 nm on the gate oxide by the CVD method.

Next, the polysilicon film and the gate oxide are subjected to patterning to form word lines 4104 (WL1, WL2, WL3) that function as gate electrodes as well as gate insulators 4103 (see FIG. 46). The patterning is carried out by using a photoresist film formed on the polysilicon film as a mask.

Next, a silicon nitride 4109 (see FIG. 46) of a film thickness of 0.8 to 200 nm, which covers the upper surface and the side surfaces of the portion that functions as a gate electrode in the word line 4104, is formed. In this silicon nitride 4109, the portions located on opposite sides of the word lines 4104 become memory function bodies.

Next, by forming diffusion regions 4107 (see FIG. 46) as one example of the source/drain diffusion regions in the p-type well 4102 on opposite sides of the word line 4104, a memory cell is formed.

The diffusion regions 4107 are n-type semiconductor regions and are formed by implanting ions of an n-type impurity of, for example, P (phosphorus) into the p-type well 4102.

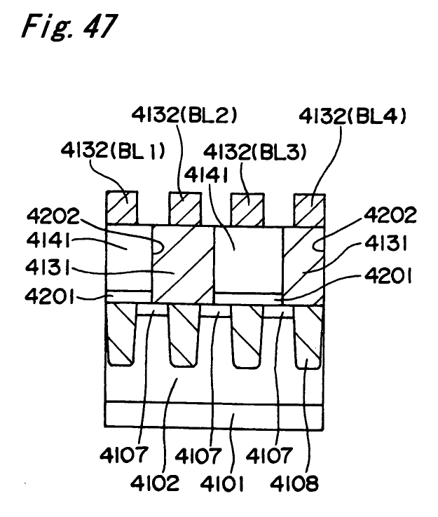

FIG. 47 is a schematic sectional view of another memory cell array of the present embodiment, FIG. 48 is a view for explaining the arrangement of metal interconnections of the memory cell array.

Reference is then made below to an interlayer insulator process that is the process after the formation of the memory cells, a contact process and the remaining processes with reference to FIGS. 46 through 48.

First of all, as shown in FIG. 46, a silicon oxide (not shown) of a film thickness of 20 to 100 nm and a silicon nitride 4201 of a film thickness of 70 to 200 nm are deposited overall by the CVD method, and a silicon oxide of a film thickness of 200 to 700 nm for the formation of an interlayer insulator 4141 is further deposited overall. The silicon nitride is used as an etching stopper during subsequent contact etching.

Next, the silicon oxide is polished by the CMP method to flatten the surface thereof.

Next, a photoresist film is formed on the silicon oxide whose surface has been flattened, and thereafter, contact holes 4202 are formed in the silicon oxide by anisotropic etching using this photoresist film as a mask. At this time, the anisotropic etching is effected on condition that the etching rate of the silicon oxide is faster than the etching rate of the silicon nitride. Moreover, the interlayer insulator 4141, which is constructed of the silicon oxide, is left between the contact holes 4202. Subsequent to the anisotropic etching of the silicon oxide, the silicon nitride is selectively etched with respect to the silicon oxide. Through this process, the contact holes 4202 can be opened to the diffusion region 4107 without etching the element isolation region 4108. Etching the diffusion region 4107 causes junction leakage. However, by opening the contact holes by the aforementioned method (the method of selectively etching the silicon nitride with respect to the silicon oxide subsequently to the anisotropic etching of the silicon oxide), the occurrence of junction leakage can be prevented.

Next, by filling the inside of the contact holes 4202 with tungsten, contacts 4131 of an elliptic cylinder configuration constructed of tungsten are formed.

The contacts 4131 are formed by, for example, depositing tungsten on the silicon oxide inside the contact holes 4202 by the CVD method and thereafter leaving tungsten inside the contact holes 4202 through the removal of the upper portion of tungsten by the CMP method (or the etchback method).

Next, a metal film is formed on the contact 4131 and the interlayer insulator 4141.

The metal interconnections are formed by successively forming films of titanium nitride/aluminum-copper alloy/titanium nitride to a total film thickness of about 600 nm by, for example, the sputtering method.

Finally, by subjecting the metal film to photolithography and metal etching, bit lines 4132 (BL1, BL2, BL3, BL4) as shown in FIGS. 47 and 48 are formed.

In electrically connecting each diffusion region 4107 (n-type semiconductor region) to each bit line 4132, interconnections are provided according to the following rule. In the following case, the direction parallel to the direction in which the word line 4104 is extended (sidewise direction in the figures) is referred to as a row, and the direction parallel to the direction in which the bit line 4132 is extended (longitudinal direction in the figures) is referred to as a column.

If attention paid to a plurality of diffusion regions 4107 of certain one column, a plurality of diffusion regions 4107 are connected to one neighborhood bit line 4132 at intervals of two. In this case, the one bit line 4132 is connected to the diffusion regions 4107 every other row. The other bit lines 4132, which adjoin the one bit line 4132, are connected to diffusion regions 4107 in the rows where the one bit line 4132 is not connected to diffusion regions 4107. That is, the rows where the one bit line 4132 is connected to diffusion regions 4107 and the row where the other bit lines 4132 are connected to diffusion regions 4107 are shifted by one row. In other words, the one bit line 4132 and the other bit lines 4132 are not connected to the diffusion regions 4107 of an identical row.

Moreover, when attention is paid to a plurality of adjoining diffusion regions 4107 of certain two columns, two diffusion regions 4107 adjoining in an identical row are electrically connected to one bit line 4132 located between the two columns via one contact 4131 every other row.

With the aforementioned connection, the memory cells can be individually selected without erroneously selecting two or more memory cells when two adjoining bit lines 4134 and one word line 4104 are selected, making random access possible.

Moreover, since the gate and the element isolation are almost linear in the structure that has interconnections according to the rule as described above, the structure can easily be manufactured, leading to a good yield.

Although the memory function bodies are formed of part of the silicon nitride 4109 in the aforementioned embodiment, the memory function bodies are not limited to this. For example, it is acceptable to oxidize the sidewalls of the word line 4104, form a silicon oxide that covers the sidewalls, thereafter successively deposit a silicon nitride of a film thickness of about 5 to 200 nm and a silicon oxide of a film thickness of 5 to 200 nm overall by the CVD method and form memory function bodies of a sidewall spacer configuration on the sidewalls of the word line 4104 by the etchback method. As one example of this memory function bodies, there is one as shown in FIG. 1.

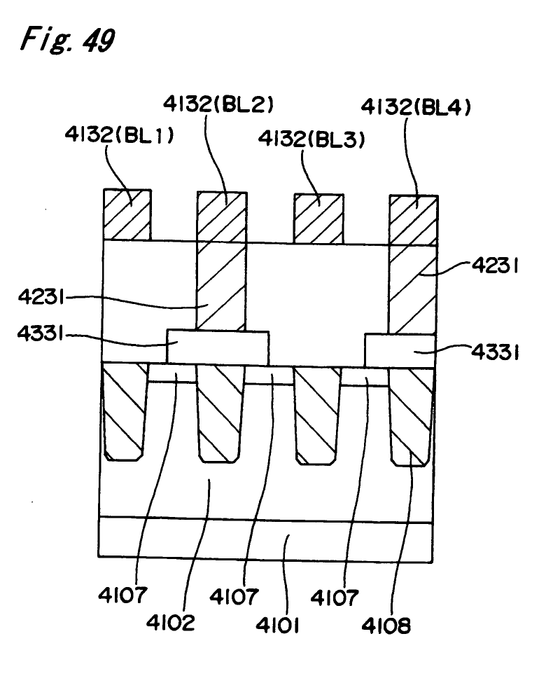

Moreover, the electrical connection of one bit line 4132 to two diffusion regions 4107 may be the one as shown in FIG. 49. That is, it is acceptable to electrically connect one bit line 4132 to two diffusion regions 4107 via a contact 4231 and a conductor 4331 of an elliptic plate configuration.

Although the gate electrode of the memory element is part of the word line 4104 in the aforementioned embodiment, the gate electrode is not necessarily required to be part of the word line. That is, the gate electrode of the memory element may be provided separately from the word line. In this case, the word line connects the gate electrodes of the memory elements of an identical row.

(The Twentieth Embodiment)

In the present embodiment, a concrete manufacturing method of the memory cell array of FIG. 49 will be described. The memory cell array of the present embodiment is manufactured when an etching apparatus that has a condition of high selection ratio (condition that the etching rate of silicon oxide is faster than the etching rate of silicon nitride) cannot be used.

According to the aforementioned memory cell array manufacturing method, a high-density cell of a small occupation area is manufactured similarly to the nineteenth embodiment by adding one mask as follows.

That is, processes up to the memory cell formation process are carried out similarly to the manufacturing method of the nineteenth embodiment. Subsequently, film formation of a silicon nitride is carried out by using CVD. After the silicon nitride formed as a film is subjected to patterning to open a window, tungsten silicide is deposited and subjected to patterning, and local interconnections of the tungsten silicide are provided. Subsequently, bit lines are formed by a metal process.

According to the manufacturing method of the present embodiment, the number of masks increases in comparison with the nineteenth embodiment. However, even when an etching apparatus having a condition of high selection ratio (condition that the etching rate of silicon oxide is faster than the etching rate of silicon nitride) cannot be used, a high-density memory cell on the same level can be formed.

Polysilicon interconnections can be used besides the local interconnections of tungsten silicide. Moreover, the present embodiment can carry out a method for providing polysilicon interconnections and thereafter providing local interconnections during a silicide process. Particularly during the silicide process, which is a self-alignment process, has an advantage that dry etching of a high melting point metal becomes unnecessary and the process can be simplified. Moreover, it is acceptable to employ silicide interconnections of polysilicon, titanium, titanium silicide, cobalt silicide or the like.

Also, even the manufacturing method of the present embodiment is able to achieve the manufacturing up to the production of the gate electrode through processes similar to those of an ordinary logic transistor. Since the manufacturing can be achieved by the reliable manufacturing method, the yield is improved. Moreover, the process for consolidating a memory with a logic circuit can easily be achieved. Moreover, the present embodiment is able to produce a memory of substantially one metal interconnection layer, and therefore, the yield is improved.

Furthermore, although different protection films are used in forming the silicon nitride and the local interconnections of the memory function bodies according to the description of the present embodiment, it is acceptable to concurrently use one protection film for the formation of the silicon nitride and the local interconnections if there is consistency in the film thickness in terms of process. In this case, if patterning is carried out with a resist mask during the etchback after the formation of the gate electrode, sidewalls and a protection pattern can be formed at the same time. By so doing, the processes can be further simplified.

Also, in the present embodiment and the nineteenth embodiment, with regard to the interconnection materials for electrically connecting the diffusion regions to the bit lines, the interconnection materials have close resemblance in terms of structure. Therefore, the materials have almost equal interconnection resistances and have little variations. As a result, there is an advantage that the sense amplifier can be designed comparatively simply.

In the present embodiment, there has been described the case where the memory function body is formed of the so-called ONO (Oxide Nitride Oxide) film made of silicon nitride and insulation films. However, the memory function body may be made of any film so long as the film can change its resistance by, for example, accumulating electric charge or in a similar manner like a variable resistor. For example, it is needless to say that the memory function body can be formed of a film that can accumulate electric charge like, for example, a floating gate and a silicon dot film.

(The Twenty-First Embodiment)

In this embodiment, a memory cell array that has the memory element of the first to eighth embodiment as a memory cell.

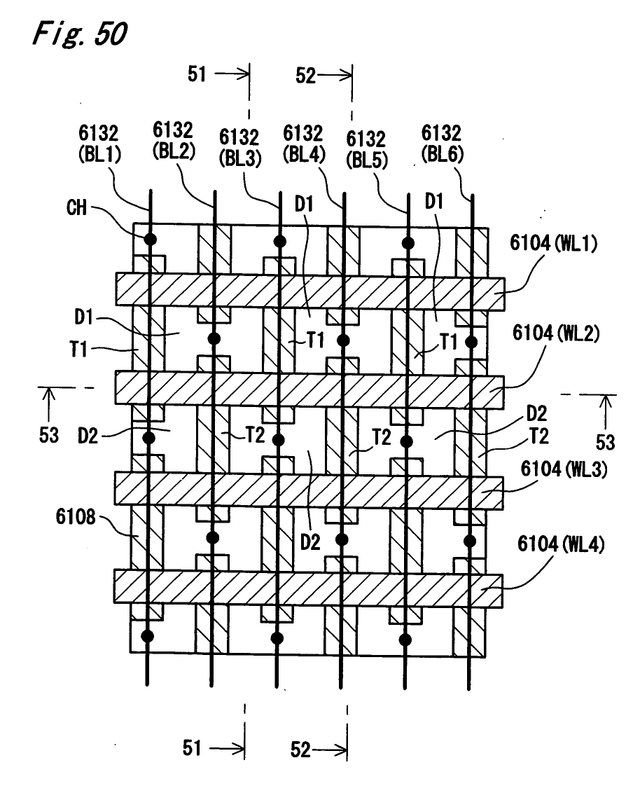

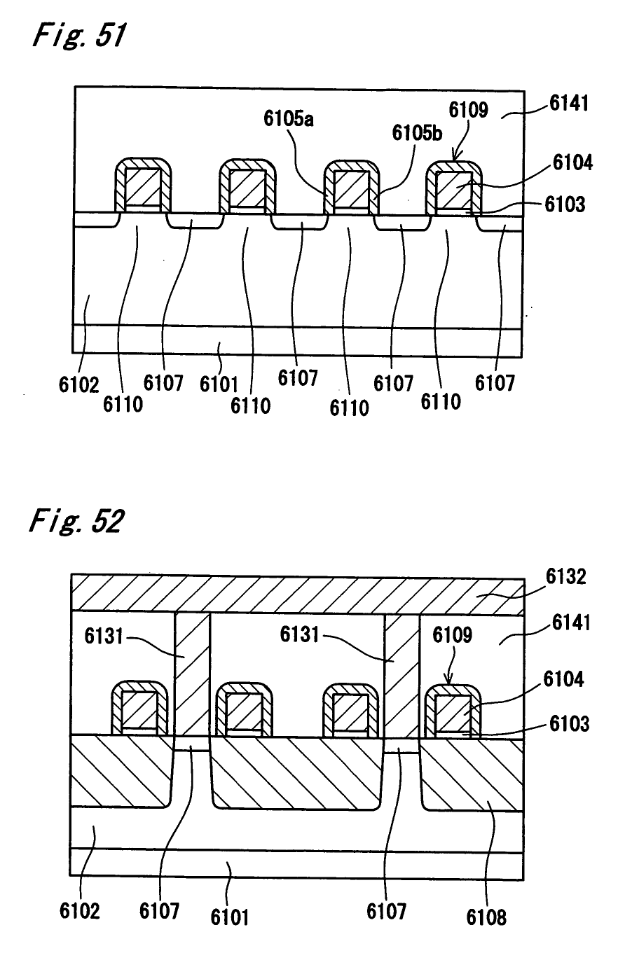

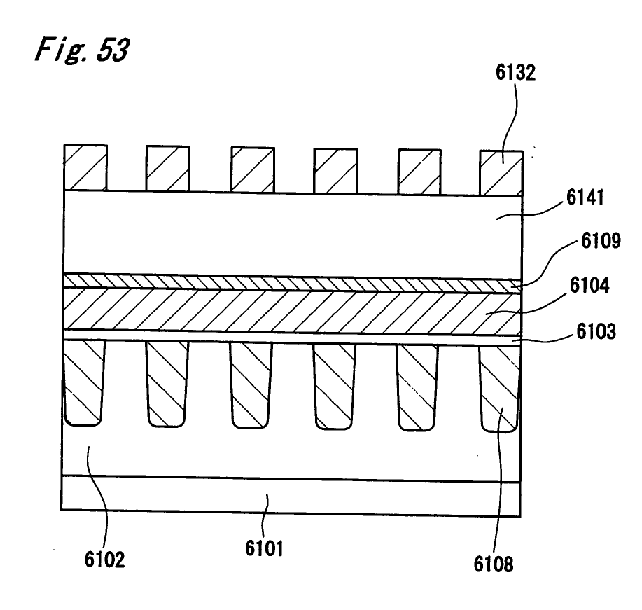

FIG. 50 is a schematic plan view of the semiconductor storage device of the twenty-first embodiment of the present invention. FIG. 51 is a schematic sectional view taken along the line 51-51 of FIG. 50. FIG. 52 is a schematic sectional view taken along the line 52-52 of FIG. 50. FIG. 53 is a schematic sectional view taken along the line 53-53 of FIG. 50. It is to be noted that an upper portion interconnection structure (bit lines and contacts) is expressed by wires and dots for the sake of simplicity in FIG. 50. Although a memory cell array of four rows by five columns are shown in FIGS. 50 through 52, the number of rows and the number of columns are arbitrary.

As shown in FIGS. 52 and 53, a p-type well region 6102 is formed on a semiconductor substrate 6101. An element isolation region 6108 is formed on the surface of the p-type well region 6102. The region in which the element isolation region 6108 is not formed on the surface of the semiconductor substrate serves as an active region. Word lines WL1, WL2, WL3 and WL4 (6104) are extended sidewise in the sheet plane of FIG. 50 and arranged side by side longitudinally in the sheet plane of FIG. 50.

As shown in FIG. 51, the word lines 6104 (WL1, WL2, WL3, WL4) extend over active regions via a gate insulator 6103. That is, the gate insulator 6103 is formed between the word line 6104 and each active region. Then, a diffusion region 6107 is formed as one example of the source/drain diffusion regions on opposite sides of the word lines 6104 (WL1, WL2, WL3, WL4) (regions that are active regions being not covered with the word lines 6104). A region located between these diffusion regions 6107 serves as a channel region 6110 of the memory element.

As described above, a memory element, which is one field-effect transistor, includes the word line 6104 (gate electrode) and the diffusion regions 6107 (source region or drain region) formed on opposite sides of the word line 6104.

In this case, adjoining three word lines 6104 (e.g., WL1, WL2, WL3) are selected in FIG. 50, and it is assumed that the lines are the first word line (WL1), the second word line (WL2) and the third word line (WL3) in the order of arrangement. In this case, first diffusion regions (indicated by D1 in FIG. 50), which serve as one of the source/drain regions enclosed by the first and second word lines and the element isolation region 6108 (T1), are arranged in the direction in which the first and second word lines are extended between the first word line and the second word line. Likewise, second diffusion regions (indicated by D2 in FIG. 50), which serve as the other of the source/drain regions enclosed by these second and third word lines and the element isolation region 6108 (T2), are arranged in the direction in which the second and third word lines are extended between the second word line (WL2) and the third word line (WL3). The first diffusion region (D1) and the two second diffusion regions (D2) share one channel region and each of the regions constitute one field-effect transistor. Likewise, the second diffusion region (D2) and the two first diffusion regions (D1) share one channel region and each of the regions constitute one field-effect transistor. Therefore, one diffusion region is shared by four field-effect transistors.

That is, a plurality of memory elements as the memory cells of the memory cell array are arranged in a matrix form. Among the plurality of memory elements, two memory elements adjoining in an identical row share the diffusion region arranged below the region located between the gate electrodes of these two memory elements. Moreover, two memory elements adjoining in an identical column also share the diffusion region arranged below the region located between the gate electrodes of these two memory elements.

The aforementioned description concerning the arrangement of the element isolation regions 6108 and the diffusion regions 6107 can be paraphrased as follows. In FIG. 50, a first element isolation region (T1) that are arranged extended over the first word line (WL1) and the second word line (WL2) and a second element isolation region (T2) that are arranged extended over the second word line (WL2) and the third word line (WL3) are alternately arranged in the direction in which the word lines are extended. A first diffusion region (D1), which serves as one of the source/drain. regions enclosed by the two first element isolation regions (T1) and the first and second word lines, is defined. Likewise, a second diffusion region (D2), which serves as the other of the source/drain regions enclosed by the two second element isolation regions (T2) and the second and third word lines, is defined. The arrangement of the element isolation region and the diffusion region can be paraphrased as above.

As shown in FIG. 51, a silicon nitride 6109 is formed on the sidewalls and the upper surfaces of the word lines 6104 (WL1, WL2, WL3, WL4). That is, the side surfaces and the upper surfaces of the word lines 6104 are covered with the silicon nitride 6109. The portions, which exist on opposite sidewalls of the word lines 6104, of the silicon nitride 6109 serve as memory function bodies 6105a and 6105b. It is to be noted that an interlayer insulator 6141 is laminated on the silicon nitride 6109.

The one (D1) of the source/drain regions is connected to bit lines 6132 (BL2, BL4, BL6) constructed of first layer metal. interconnections, and the other (D2) of the source/drain regions is connected to bit lines 6132 (BL1, BL3, BL5) adjacent to the bit lines 6132. The bit lines are extended in a direction perpendicular to the direction in which the word lines are extended. In the present embodiment, the bit lines 6132 are each connected to the diffusion regions 6107 via a contact 6131 (indicated by CH in FIG. 50) constructed of a conductive material.

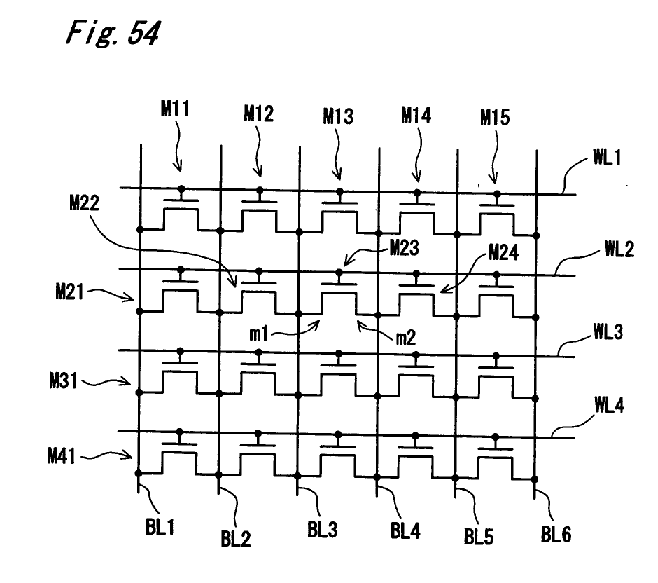

FIG. 54 shows the circuit diagram of the memory cell array. For the sake of simplicity, the memory elements are each indicated by a symbol that represents an ordinary field-effect transistor. In the memory cell Mij (i=1, 2, 3, 4, j=1, 2, 3, 4, 5), the gate electrode is connected to a word line WLi (i=1, 2, 3, 4), one of the diffusion regions is connected to a bit line BLj (j=1, 2, 3, 4, 5), and the other of the diffusion regions is connected to a bit line BLj+1 (j=2, 3, 4, 5). Moreover, each of the memory cell Mij includes two memory function bodies m1 and m2 (6105a, 6105b).

A method for operating the memory cell array will be described next.

Reference is first made to a read method. In this case, it is assumed that the storage information of the memory function body (m1) located on the bit line BL3 side of the memory cell M23 is subjected to read. First of all, the bit line BL3 and the bit line BL4 are precharged with logic level L and logic level H, respectively. Further, it is preferable that the bit line BL2 that adjoins the bit line BL3 on the left-hand side in the figure (on the side opposite from the bit line BL4) is precharged with logic level L, and the bit line BL5 that adjoins the bit line BL4 on the right-hand side in the figure (on the side opposite from the bit line BL3) is precharged with logic level H. After the precharge is completed, the word line WL2 is made to have logic level H. At the moment when the word line WL2 comes to have logic level H, the memory cells M22 and M23 are turned on. At this time, a high voltage (logic level H−logic level L) is applied across the source and the drain of the memory cell M23 and a current flows. The amount of the current changes depending on the state of the memory function body m1. Therefore, by detecting the amount of the current flowing through the bit line BL3 or BL4 or monitoring the voltage change of the bit line BL3 or BL4, the state of the memory function body m1 can be known.

If the bit line BL2 is not precharged with logic level L during the aforementioned operation, then the memory cell M22 is disadvantageously turned on to flow a current from the bit line BL2 to the bit line BL3 at the moment when the word line WL2 comes to have logic level H. Such a current obstructs the detection of the current that flows in the selected memory cell M23. Therefore, the bit line BL2 should preferably be precharged with the same logic level L as that of the bit line BL3. Likewise, the bit line BL5 should preferably be precharged with the same logic level H as that of the bit line BL4.

When the storage information of the memory function body (m2) located on the bit line BL4 side of the memory cell M23 is retrieved, the bit lines BL2 and BL3 are precharged with logic level H, and the bit lines BL4 and BL5 are precharged with logic level L. It is proper to make the word line WL2 have logic level H after the precharge is completed.

Table 3 shows a concrete example of voltages during the operations of write, read and erase in the memory cell array of the present embodiment. There are Lbw, Hbw, Lww and Hww, which represent the low-level potential of the bit lines, the high-level potential of the bit lines, the low-level potential of the word lines and the high-level potential of the word lines, respectively, during write. There are Lbr, Hbr, Lwr and Hwr, which represent the low-level potential of the bit lines, the high-level potential of the bit lines, the low-level potential of the word lines and the high-level potential of the word lines, respectively, during read. There are Lbe1, Lbe2, Hbe, Lwe and Hwe, which represent the low-level potential 1 of the bit lines, the low-level potential 2 of the bit lines, the high-level potential of the bit lines, the low-level potential of the word lines and the high-level potential of the word lines, respectively, during erase. Concrete voltages are exemplified in the parentheses.

The erase method shown in the following Table 3 is provided by the aforementioned second erase method. Therefore, a voltage Lbe2 (+0.8 V in Table 3) is applied to the p-type well region during erase. When the memory function body m1 of the memory cell M23 is subjected to erase, electrons injected by the forward voltage applied across the p-type well region and the bit line BL4 become a trigger to execute the erase. Moreover, the voltage Lbe2 is applied to the bit line BL2, and this is to prevent the memory cell M21 from being erroneously erased.

TABLE 3

| Operation | BL1 | BL2 | BL3 | BL4 | WL1 | WL2 | WL3 |
|---|---|---|---|---|---|---|---|
| Write (m1) | Hbw | Hbw | Lbw | Lbw | Lww | Hww | Lww |
| | (+5 V) or Open | (+5 V) | (0 V) | (0 V) or Open | (0 V) | (+5 V) | (0 V) |
| Write (m2) | Lbw | Lbw | Hbw | Hbw | Lww | Hww | Lww |
| | (0 V) or Open | (0 V) | (+5 V) | (+5 V)or Open | (0 V) | (+5 V) | (0 V) |
| Read (m1) | Lbr | Lbr | Hbr | Hbr | Lwr | Hwr | Lwr |
| | (0 V) | (0 V) | (+2 V) | (+2 V) | (0 V) | (+2 V) | (0 V) |
| Read (m2) | Hbr | Hbr | Lbr | Lbr | Lwr | Hwr | Lwr |
| | (+2 V) | (+2 V) | (0 V) | (0 V) | (0 V) | (+2 V) | (0 V) |
| Erase (m1) | Lbe2 | Hbe | Lbe1 | Lbe1 | Lwe | LWe | Hwe |
| | (+0.8 V) | (+5 V) | (0 V) | (0 V) | (0 V) | (−4 V) | (0 V) |
| | | | | or Open | | | |
| Erase (m2) | Lbe1 | Lbe1 | Hbe | Lbe2 | Lwe | LWe | Hwe |
| | (0 V) or Open | (0 V) | (+4 V) | (+0.8 V) | (0 V) | (−4 V) | (0 V) |

As is apparent from Table 3, the memory cell array of the present embodiment permits random access (read and rewrite operations every one bit). Therefore, the access efficiency can be increased in comparison with the device that must be subjected to batch erase. Moreover, there is an effect that the control circuit becomes simple since the sequence of temporary storage of the memory state, batch erase and write is also unnecessary. When the aforementioned first erase method is used, it is proper to make Lbe2 equal (0 V) to Lbe1 in Table 3 and to make Hbe have an appropriate voltage value (e.g., +6 V). In this case, at least two bits are subjected to erase in a batch.

According to the aforementioned read operation, when it is tried to continuously read 2-bit storage of a certain memory cell (e.g., when the memory function bodies m1 and m2 of the memory cell M23 are continuously read), it is required to invert all the voltages of the neighborhood bit lines (all the voltages of the bit lines BL2 through BL5 are inverted in the above example), and this therefore leads to low efficiency. Therefore, it is preferable to avoid the state of continuous alternate read by devising the address decoder circuit or the like and taking the measures of separating the addresses of the right and left memory function bodies or similar measures.

As is apparent from the above description, the memory cell array of the present embodiment is constituted by arranging the aforementioned memory elements. As described above, with. regard to the memory elements, one element can store two bits, allowing scaling down to be facilitated. Therefore, it also becomes easy to achieve the areal shrinkage (or densification) of the memory cell array of the present embodiment constituted by arranging the aforementioned memory elements, and the manufacturing cost is reduced.

Moreover, in the memory cell array of the present embodiment, one diffusion region is shared by four memory elements (field-effect transistors). Therefore, the number of bit lines is reduced, and the number of contact holes, which connect the bit lines to the diffusion regions is also reduced. Therefore, the margins of the bit lines and the contact holes are small, and therefore, it becomes possible to further shrink (or densify) the memory cell array and to reduce the manufacturing cost.

Moreover, as described above, the process for forming the memory elements has a great resemblance to the ordinary CMOS (Complementary Metal-Oxide Semiconductor) process and is able to be manufactured much easier than the nonvolatile memory such as a conventional EEPROM that has a floating gate. Therefore, the memory cell array of the present invention can easily be manufactured and easily consolidated with a logic circuit.

As described in connection with the second embodiment, in the memory element employed in the present embodiment, the regions (silicon nitrides 242) that retain electric charge in the memory function bodies 261 and 262 should preferably overlap with the diffusion regions 212 and 213, respectively. If such the memory element is employed in the semiconductor storage device of the present embodiment, the read speed of the semiconductor storage device can be made sufficiently high.

Moreover, as described in connection with the second embodiment, in the memory element employed in the present embodiment, the memory function bodies should preferably include the charge retention film arranged roughly parallel to the surface of the gate insulator. If such the memory element is employed in the semiconductor storage device of the present embodiment, variations in the memory effect of the memory elements can be reduced, and therefore, variations in the read current of the semiconductor storage device can be restrained. Furthermore, the characteristic change of the memory element during storage retention can be reduced, and therefore, the storage retention characteristic of the semiconductor storage device is improved.

Moreover, as described in connection with the third embodiment, in the memory element employed in the present embodiment, it is preferable that the memory function bodies include the charge retention film arranged roughly parallel to the surface of the gate insulator and the portion extended roughly parallel to the side surfaces of the gate electrode. If such the memory element is employed in the semiconductor storage device of the present embodiment, the rewrite speed of the memory element is increased, and therefore, the rewrite operation of the semiconductor storage device can be executed at high speed.

Moreover, it is preferable to employ the memory element of the seventh embodiment for the memory element employed in the present embodiment. That is, the thickness (T1) of the insulation film that separates the charge retention film (silicon nitride 242) from the channel region or the well region should preferably be smaller than the thickness (T2) of the gate insulator and not smaller than 0.8 nm. If such the memory element is employed in the semiconductor storage device of the present embodiment, it becomes possible to lower the voltage of the write operation and the erase operation or to increase the speed of the write operation and the erase operation. Furthermore, the memory effect of the memory element is increased, and therefore, the read speed of the semiconductor storage device can be increased.

Moreover, it is preferable to employ the memory element of the eighth embodiment for the memory element employed in the present embodiment. That is, the thickness (T1) of the insulation film that separates the charge retention film (silicon nitride 242) from the channel region or the well region should preferably be greater than the thickness (T2) of the gate insulator and not greater than 20 nm. If such the memory element is employed in the semiconductor storage device of the present embodiment, the retention characteristic can be improved without degrading the short-channel effect of the memory element, and therefore, a sufficient storage retention performance can be obtained even if the semiconductor storage device is densely integrated.

Moreover, the memory element employed in the present embodiment should preferably be provided with the memory function bodies that have the structure in which the silicon nitride is placed between the silicon oxides as in, for example, the first embodiment (FIG. 7). If such the memory element is employed in the semiconductor storage device of the present embodiment, it becomes possible to improve the operating speed of the semiconductor storage device and improve reliability.

Moreover, it is preferable to employ the memory element of the best mode that has already been described for the memory element employed in the present embodiment. With the arrangement, the performance of the semiconductor storage device can be optimized.

(The Twenty-Second Embodiment)

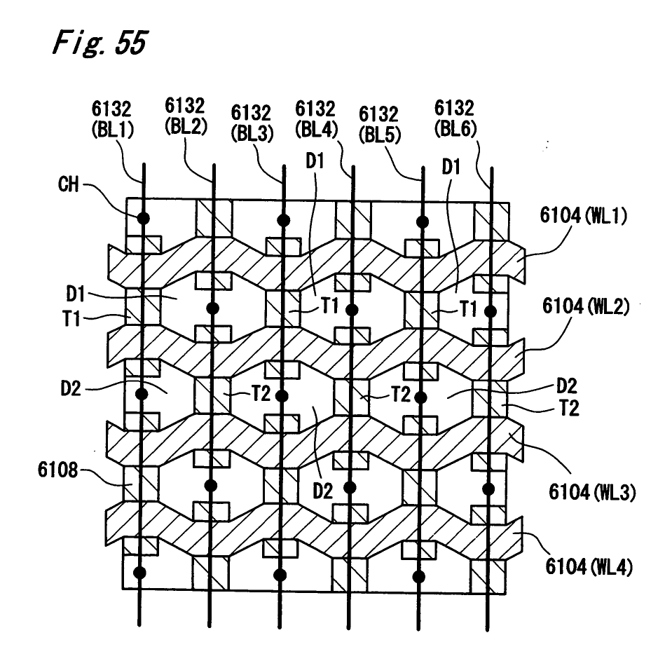

The twenty-second embodiment of the present invention will be described with reference to FIG. 55. In the semiconductor storage device of the present embodiment, the memory cell area is shrunk by meandering the word lines 6104 (WL1, WL2, WL3, WL4) in the semiconductor storage device of the twenty-first embodiment. Moreover, in FIG. 55, the same components as the components shown in FIG. 50 are denoted by the same reference numerals as those of the components in FIG. 50, and no description is provided for them.

The word lines 6104 (WL1, WL2, WL3, WL4) meander in synchronization with the cycle of the arrangement of the element isolation regions 6108. The meander of mutually adjacent word lines 6104 have opposite phases (shifted by 180 degrees). Therefore, a distance in the direction perpendicular to the direction in which the word lines 6104 are extended (longitudinal direction in the sheet plane of FIG. 55) between the mutually adjacent two word lines 6104 is changed in synchronization with the cycle of the arrangement of the element isolation regions 6108. In concrete, between the mutually adjacent two word lines 6104, the distance in the direction parallel to the direction in which the bit lines 6132 are extended is shorter above the element isolation region 6108 then above the active region. In concrete, the above-mentioned distance is long in the portion where the first or second diffusion region D1 or D2 is placed between mutually adjacent two word lines 6104, and the above-mentioned distance is short in the portion where mutually adjacent word lines extend over one element isolation region 6108.

By meandering the word lines 6104 (WL1, WL2, WL3, WL4) as described above, the length of the element isolation region 6108 can be shortened with the margin between the word line 6104 and the contact CH maintained. As is clarified by comparing FIG. 50 with FIG. 55, the size of the memory cell of the semiconductor storage device of the present embodiment is shrunk in the length in the longitudinal direction in the sheet plane of FIG. 54. Therefore, it becomes possible to further shrink (or densify) the memory cell array and to reduce the manufacturing cost.

(The Twenty-Third Embodiment)

The semiconductor storage device of the fourteenth, twenty-first and twenty-second embodiments can be employed in battery-driven portable electronic equipment or in particular, portable information terminal. As the portable electronic equipment, there can be enumerated a portable information terminal, a portable telephone, a game machine and so on.

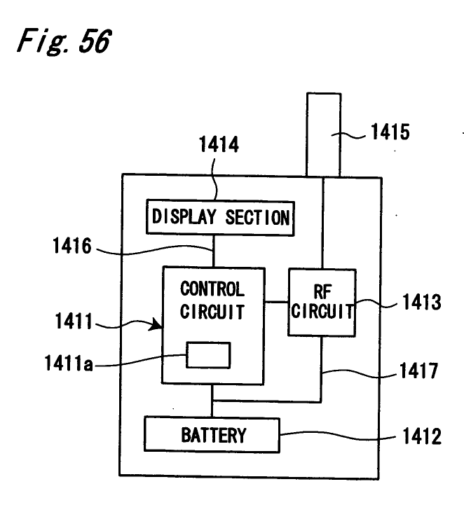

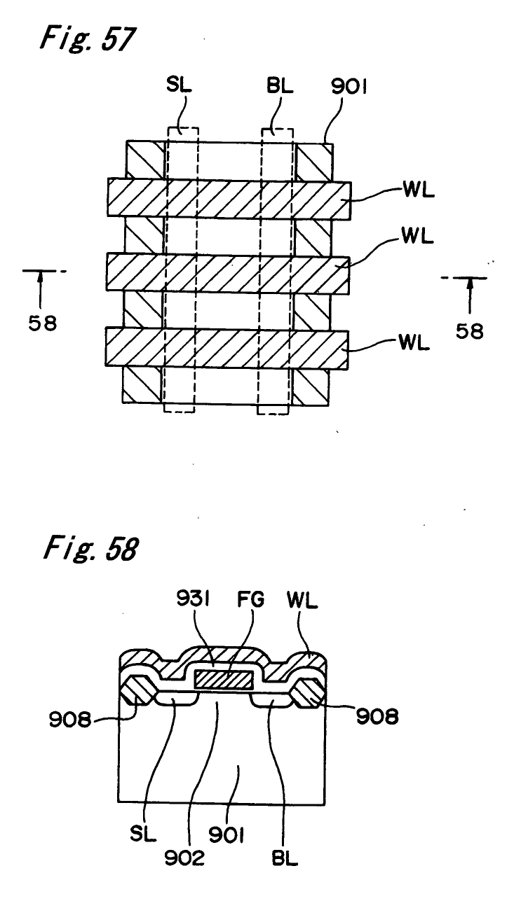

FIG. 56 shows an example of the portable telephone. A semiconductor storage device 1411a of the present invention is built in a control circuit 1411 of this portable telephone. Moreover, with regard to the reference numerals of FIG. 56, there are shown a battery 1412, an RF (Radio Frequency) circuit section 1413, a display section 1414, an antenna section 1415, a signal line 1416 and a power line 1417.

By employing the semiconductor storage device 1411a of the present invention in the portable electronic equipment, the manufacturing cost of the control circuit 1411 is reduced, and therefore, the cost of the portable electronic equipment itself can be reduced. Moreover, the function of the portable electronic equipment can be improved by increasing the capacity of the nonvolatile memory included in the control circuit 1411.

It is to be noted that the semiconductor device of the present invention may be built in the control circuit 1411. With the semiconductor device of the present invention built in the control circuit 1411, the parts count of the portable electronic equipment can be further reduced, and the manufacturing cost can be further reduced.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor storage device comprising:
element isolation regions formed at a surface of a semiconductor substrate;
active regions other than the element isolation regions formed at the surface of the semiconductor substrate, wherein the active regions are arranged in a matrix form defined by a first direction and a second direction intersecting with the first direction;
two source/drain diffusion regions which operate as a source or a drain and are formed in each of the active regions;
a channel region defined between the two source/drain diffusion regions;
a plurality of word lines extending in the second direction provided on the semiconductor substrate, each of the word lines being located on the channel regions of the active regions arranged in the second direction, with an insulator disposed between each of the word lines and the semiconductor substrate; and
a plurality of first bit lines extending in the first direction and a plurality of second bit lines extending in the first direction provided on the semiconductor substrate, wherein
each of the first bit lines is connected to one of the source/drain diffusion regions formed in the active regions arranged in the first direction,
each of the second bit lines is connected to the other of the source/drain diffusion regions formed in the active regions arranged in the first direction,
each of the word lines functions as a gate electrode on the channel region,
the insulator functions as a gate insulator on the channel region,
memory function bodies having a function to maintain electric charge or polarization are formed in sidewalls located on one side and the other side of the source/drain diffusion regions with regard to the gate electrode, and
a quantity of electric charge flowing in the channel region specified by selecting the prescribed word line, first bit line and second bit line changes according to an amount of the electric charge or polarization retained in one of the memory function bodies specified by selecting the prescribed word line, first bit line and second bit line.

2. A semiconductor storage device comprising:
element isolation regions formed at a surface of a semiconductor substrate;
active regions other than the element isolation regions formed at the surface of the semiconductor substrate, wherein the active regions extend in a first direction and are arranged in a second direction intersecting with the first direction;
a plurality of source/drain diffusion regions which operate as a source or a drain and are formed in each of the active regions;
channel regions defined between the source/drain diffusion regions that adjoin in an identical active region;
a plurality of word lines extending in the second direction provided on the semiconductor substrate, each of the word lines being located on the channel regions of the active regions, with an insulator disposed between each of the word lines and the semiconductor substrate; and
a plurality of first bit lines extending in the first direction and a plurality of second bit lines extending in the first direction provided on the semiconductor substrate, wherein
each of the first bit lines is connected to one of the source/drain diffusion regions formed on an identical active region,
each of the second bit lines is connected to the other of the source/drain diffusion regions formed on the identical active region,
each of the word lines functions as a gate electrode on the channel region,
the insulator functions as a gate insulator on the channel region,
memory function bodies having a function to maintain electric charge or polarization are formed in sidewalls located on one side and the other side of the source/drain diffusion regions with regard to the gate electrode, and
a quantity of electric charge flowing in one of the channel regions specified by selecting the prescribed word line, first bit line and second bit line changes according to an amount of the electric charge or polarization retained in one of the memory function bodies specified by selecting the prescribed word line, first bit line and second bit line.

3. A semiconductor storage device comprising:
element isolation regions formed at a surface of a semiconductor substrate;
active regions other than the element isolation regions formed at the surface of the semiconductor substrate, wherein the active regions extend in a first direction and are arranged in a second direction intersecting with the first direction;
a plurality of source/drain diffusion regions which operate as a source or a drain and are formed in each of the active regions;
channel regions defined between the source/drain diffusion regions that adjoin in an identical active region;
a plurality of word lines extending in the second direction provided on the semiconductor substrate, each of the word lines being located on the channel regions of the active regions, with an insulator disposed between each of the word lines and the semiconductor substrate; and
a plurality of bit lines extending in the first direction provided on the semiconductor substrate, wherein
regarding one of the active regions connected to the adjoining two bit lines, one of the two bit lines is connected to one of the source/drain diffusion regions formed on the active region, and the other of the two bit lines is connected to the other one of the source/drain diffusion regions formed on the active region,
each of the word lines functions as a gate electrode on the channel region,
the insulator functions as a gate insulator on the channel region,
memory function bodies having a function to maintain electric charge or polarization are formed in sidewalls located on one side and the other side of the source/drain diffusion regions with regard to the gate electrode,
a memory element is defined by the gate electrode, the memory function bodies formed in the sidewalls located on opposite sides of this gate electrode and the source/drain diffusion regions adjoining regarding this gate electrode, and
a quantity of electric charge flowing in one of the channel regions specified by selecting the prescribed word line and mutually adjoining two bit lines changes according to an amount of the electric charge or polarization retained in one of the memory function bodies specified by selecting the prescribed word line and the mutually adjoining two bit lines.

4. A semiconductor storage device comprising:
element isolation regions formed at a surface of a semiconductor substrate;
active regions other than the element isolation regions formed at the surface of the semiconductor substrate, wherein the active regions extend in a first direction and are arranged in a second direction intersecting with the first direction;
a plurality of source/drain diffusion regions which operate as a source or a drain and are formed in each of the active regions;
channel regions defined between the source/drain diffusion regions that adjoin in an identical active region;
a plurality of word lines extending in the second direction provided on the semiconductor substrate, each of the word lines being located on the channel regions of the active regions, with an insulator disposed between each of the word lines and the semiconductor substrate; and
a plurality of bit lines extending in the first direction provided on the semiconductor substrate, wherein
concerning successively adjoining first bit line, second bit line and third bit line, a first active region is connected to the first bit line and the second bit line, and a second active region is connected to the second bit line and the third bit line,
the second bit line is connected to one of the source/drain diffusion regions formed in the first active region and connected to one of the source/drain diffusion regions formed in the second active region,
the first bit line is connected to the other of the source/drain diffusion regions formed in the first active region,
the third bit line is connected to the other of the source/drain diffusion regions formed in the second active region,
each of the word lines functions as a gate electrode on the channel region,
the insulator functions as a gate insulator on the channel region,
a memory function bodies having a function to maintain electric charge or polarization are formed in sidewalls located on one side and the other side of the source/drain diffusion regions with regard to the gate electrode,
a memory element is defined by the gate electrode, the memory function bodies formed in the sidewalls located on opposite sides of this gate electrode and the source/drain diffusion regions adjoining regarding this gate electrode, and
a quantity of electric charge flowing in one of the channel regions specified by selecting the prescribed word line and mutually adjoining two bit lines changes according to an amount of the electric charge or polarization retained in one of the memory function bodies specified by selecting the prescribed word line and the mutually adjoining two bit lines.

5. A semiconductor storage device comprising:
a semiconductor substrate having an element isolation region and an active region at its surface;
a plurality of memory elements that are a plurality of field-effect transistors formed in the active region and arranged in a matrix form;
a plurality of word lines each connected to gate electrodes of the memory elements of an identical row; and
a plurality of bit lines each connected in common to source/drain diffusion regions of the memory elements of an identical column via contacts, wherein
concerning adjoining two bit lines; one of the bit lines is electrically connected to one of the source/drain diffusion regions of an identical column, and the other one of the bit lines is electrically connected to the other of the source/drain diffusion regions of the identical column,
the memory element comprises:
the gate electrode formed on the semiconductor substrate, with a gate insulator disposed therebetween;
two memory function bodies that are formed on opposite sides of the gate electrode and have a function to retain electric charge or polarization;
a channel region arranged below the gate insulator; and
the source/drain diffusion regions arranged on opposite sides of the channel region, and wherein
a quantity of a current, which flows from one of the source/drain diffusion regions to the other of the source/drain diffusion regions when a voltage is applied to the gate electrode changes according to an amount of electric charge or polarization retained in the memory function body.

6. A semiconductor storage device comprising:
a semiconductor substrate having an element isolation region and an active region at its surface;
a plurality of memory elements that are a plurality of field-effect transistors formed in the active region and arranged in a matrix form;
a plurality of word lines connected to gate electrodes of the memory elements; and
a plurality of bit lines connected to source/drain diffusion regions of the memory elements, wherein
concerning adjoining two bit lines, one of the bit lines is electrically connected to one of the source/drain diffusion regions of an identical column, and the other one of the bit lines is electrically connected to the other of the source/drain diffusion regions of the identical column,
the memory elements adjoining in an identical row share one of the source/drain diffusion regions,
the memory elements adjoining in an identical column share one of the source/drain diffusion regions, and
the memory element comprises:
the gate electrode formed on the semiconductor substrate, with a gate insulator disposed therebetween;
two memory function bodies that are formed on opposite sides of the gate electrode and have a function to retain electric charge or polarization;
a channel region arranged below the gate insulator; and
the source/drain diffusion regions arranged on opposite sides of the channel region, and wherein
a quantity of a current, which flows from one of the source/drain diffusion regions to the other of the source/drain diffusion regions when a voltage is applied to the gate electrode changes according to an amount of electric charge or polarization retained in the memory function body.

7. The semiconductor storage device as claimed in claim 5, wherein
the contact is connected in common to the source/drain diffusion regions adjoining in an identical row.

8. The semiconductor storage device as claimed in claim 5, wherein
the contact has an elliptic cylindrical configuration.

9. The semiconductor wstorage device as claimed in claim 5, wherein
the contact is electrically connected to the source/drain diffusion regions via a conductor having an elliptical plate configuration.

10. The semiconductor storage device as claimed in claim 5, wherein
the memory function body includes an insulation film and a plurality of dot-shaped metal bodies formed in the insulation film, and
the metal bodies have diameters within a range of 0.1 nm to 20 nm.

11. The semiconductor storage device as claimed in claim 5, comprising:
a liquid crystal display driver.

12. The semiconductor storage device as claimed in claim 6, wherein
the word lines are each extended meandering, and
a distance in a direction parallel to the direction in which the bit lines extend between the adjoining two word lines is shorter on the element isolation region than on the active region.

13. The semiconductor storage device as claimed in claim 1, wherein
the memory function bodies are handled as independent storage units to be subjected to rewrite operation and read operation.

14. The semiconductor storage device as claimed in claim 2, wherein
the memory function bodies are handled as independent storage units to be subjected to rewrite operation and read operation.

15. The semiconductor storage device as claimed in claim 3, wherein
the memory function bodies are handled as independent storage units to be subjected to rewrite operation and read operation.

16. The semiconductor storage device as claimed in claim 4, wherein
the memory function bodies are handled as independent storage units to be subjected to rewrite operation and read operation.

17. The semiconductor storage device as claimed in claim 5, wherein
the memory function bodies are handled as independent storage units to be subjected to rewrite operation and read operation.

18. The semiconductor storage device as claimed in claim 6, wherein
the memory function bodies are handled as independent storage units to be subjected to rewrite operation and read operation.

19. The semiconductor storage device as claimed in claim 1, wherein
at least part of the memory function body is formed so as to overlap with part of the source/drain diffusion region.

20. The semiconductor storage device as claimed in claim 2, wherein
at least part of the memory function body is formed so as to overlap with part of the source/drain diffusion region.

21. The semiconductor storage device as claimed in claim 3, wherein
at least part of the memory function body is formed so as to overlap with part of the source/drain diffusion region.

22. The semiconductor storage device as claimed in claim 4, wherein
at least part of the memory function body is formed so as to overlap with part of the source/drain diffusion region.

23. The semiconductor storage device as claimed in claim 6, wherein
at least part of the memory function body is formed so as to overlap with part of the source/drain diffusion region.

24. The semiconductor storage device as claimed in claim 1, wherein
the memory function body comprises a charge retention film that has a function to retain electric charge, and
the charge retention film has a portion roughly parallel to a surface of the gate insulator.

25. The semiconductor storage device as claimed in claim 2, wherein
the memory function body comprises a charge retention film that has a function to retain electric charge, and
the charge retention film has a portion roughly parallel to a surface of the gate insulator.

26. The semiconductor storage device as claimed in claim 3, wherein
the memory function body comprises a charge retention film that has a function to retain electric charge, and
the charge retention film has a portion roughly parallel to a surface of the gate insulator.

27. The semiconductor storage device as claimed in claim 4, wherein
the memory function body comprises a charge retention film that has a function to retain electric charge, and
the charge retention film has a portion roughly parallel to a surface of the gate insulator.

28. The semiconductor storage device as claimed in claim 6, wherein
the memory function body comprises a charge retention film that has a function to retain electric charge, and
the charge retention film has a portion roughly parallel to a surface of the gate insulator.

29. The semiconductor storage device as claimed in claim 1, wherein
the memory function body comprises a charge retention film that has a function to retain electric charge, and
the charge retention film has a portion roughly parallel to the surface of the gate insulator and a portion roughly parallel to a side surface of the gate electrode.

30. The semiconductor storage device as claimed in claim 2, wherein
the memory function body comprises a charge retention film that has a function to retain electric charge, and
the charge retention film has a portion roughly parallel to the surface of the gate insulator and a portion roughly parallel to a side surface of the gate electrode.

31. The semiconductor storage device as claimed in claim 3, wherein
the memory function body comprises a charge retention film that has a function to retain electric charge, and
the charge retention film has a portion roughly parallel to the surface of the gate insulator and a portion roughly parallel to a side surface of the gate electrode.

32. The semiconductor storage device as claimed in claim 4, wherein
the memory function body comprises a charge retention film that has a function to retain electric charge, and
the charge retention film has a portion roughly parallel to the surface of the gate insulator and a portion roughly parallel to a side surface of the gate electrode.

33. The semiconductor storage device as claimed in claim 6, wherein
the memory function body comprises a charge retention film that has a function to retain electric charge, and
the charge retention film has a portion roughly parallel to the surface of the gate insulator and a portion roughly parallel to a side surface of the gate electrode.

34. The semiconductor storage device as claimed in claim 1 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a thickness of the gate insulator and not smaller than 0.8 nm.

35. The semiconductor storage device as claimed in claim 2 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a film thickness of the gate insulator and not smaller than 0.8 nm.

36. The semiconductor storage device as claimed in claim 3 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a film thickness of the gate insulator and not smaller than 0.8 nm.

37. The semiconductor storage device as claimed in claim 4 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a film thickness of the gate insulator and not smaller than 0.8 nm.

38. The semiconductor storage device as claimed in claim 5 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a film thickness of the gate insulator and not smaller than 0.8 nm.

39. The semiconductor storage device as claimed in claim 6 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is smaller than a film thickness of the gate insulator and not smaller than 0.8 nm.

40. The semiconductor storage device as claimed in claim 1 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

41. The semiconductor storage device as claimed in claim 2 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

42. The semiconductor storage device as claimed in claim 3 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

43. The semiconductor storage device as claimed in claim 4 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

44. The semiconductor storage device as claimed in claim 5 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

45. The semiconductor storage device as claimed in claim 6 further comprises an insulation film, wherein
the memory function body comprises a charge retention film that has a function to retain electric charge,
the charge retention film has a portion roughly parallel to the surface of the gate insulator,
the insulation film is disposed between the portion of the charge retention film and the semiconductor substrate, and
a thickness of the insulation film is greater than the film thickness of the gate insulator and not greater than 20 nm.

46. The semiconductor storage device as claimed in claim 1, wherein
the memory function body comprises:
a silicon nitride film, and
two silicon oxide films, and wherein
the silicon nitride film is disposed between the two silicon oxide films.

47. The semiconductor storage device as claimed in claim 2, wherein
the memory function body comprises:
a silicon nitride film, and
two silicon oxide films, and wherein
the silicon nitride film is disposed between the two silicon oxide films.

48. The semiconductor storage device as claimed in claim 3, wherein
the memory function body comprises:
a silicon nitride film, and
two silicon oxide films, and wherein
the silicon nitride film is disposed between the two silicon oxide films.

49. The semiconductor storage device as claimed in claim 4, wherein
the memory function body comprises:
a silicon nitride film, and
two silicon oxide films, and wherein
the silicon nitride film is disposed between the two silicon oxide films.

50. The semiconductor storage device as claimed in claim 5, wherein
the memory function body comprises:
a silicon nitride film, and
two silicon oxide films, and wherein
the silicon nitride film is disposed between the two silicon oxide films.

51. The semiconductor storage device as claimed in claim 6, wherein
the memory function body comprises:
a silicon nitride film, and
two silicon oxide films, and wherein
the silicon nitride film is disposed between the two silicon oxide films.

52. A method for operating the semiconductor storage device claimed in claim 3, wherein,
regarding a selecting memory element that is the memory element to which the memory function body to be operated belongs,
before a potential for executing operation is applied to the word line connected to the selecting memory element,
one of two bit lines connected to the selecting memory element is precharged with a first potential and the other is precharged with a second potential,
a bit line located adjacently on a side opposite from the other bit line concerning the one bit line is precharged with the first potential, and
a bit line located adjacently on a side opposite from the one bit line concerning the other bit line is precharged with the second potential.

53. A method for operating the semiconductor storage device claimed in claim 4, wherein,
regarding a selecting memory element that is the memory element to which the memory function body to be operated belongs,
before a potential for executing operation is applied to the word line connected to the selecting memory element,
one of two bit lines connected to the selecting memory element is precharged with a first potential and the other is precharged with a second potential,
a bit line located adjacently on a side opposite from the other bit line concerning the one bit line is precharged with the first potential, and
a bit line located adjacently on a side opposite from the one bit line concerning the other bit line is precharged with the second potential.

54. A method for operating the semiconductor storage device claimed in claim 5, wherein,
regarding a selecting memory element that is the memory element to which the memory function body to be operated belongs,
before a potential for executing operation is applied to the word line connected to the selecting memory element,
one of two bit lines connected to the selecting memory element is precharged with a first potential and the other is precharged with a second potential,
a bit line located adjacently on a side opposite from the other bit line concerning the one bit line is precharged with the first potential, and
a bit line located adjacently on a side opposite from the one bit line concerning the other bit line is precharged with the second potential.

55. A method for operating the semiconductor storage device claimed in claim 6, wherein,
regarding a selecting memory element that is the memory element to which the memory function body to be operated belongs,
before a potential for executing operation is applied to the word line connected to the selecting memory element,
one of two bit lines connected to the selecting memory element is precharged with a first potential and the other is precharged with a second potential,
a bit line located adjacently on a side opposite from the other bit line concerning the one bit line is precharged with the first potential, and
a bit line located adjacently on a side opposite from the one bit line concerning the other bit line is precharged with the second potential.

56. A semiconductor device comprising the semiconductor storage device claimed in claim 1, a column decoder, a sense amplifier and a row decoder, wherein
at least one of the column decoder, the sense amplifier and the row decoder and the semiconductor storage device are formed on an identical semiconductor substrate.

57. A semiconductor device comprising the semiconductor storage device claimed in claim 2, a column decoder, a sense amplifier and a row decoder, wherein
at least one of the column decoder, the sense amplifier and the row decoder and the semiconductor storage device are formed on an identical semiconductor substrate.

58. A semiconductor device comprising the semiconductor storage device claimed in claim 3, a column decoder, a sense amplifier and a row decoder, wherein
at least one of the column decoder, the sense amplifier and the row decoder and the semiconductor storage device are formed on an identical semiconductor substrate.

59. A semiconductor device comprising the semiconductor storage device claimed in claim 4, a column decoder, a sense amplifier and a row decoder, wherein
at least one of the column decoder, the sense amplifier and the row decoder and the semiconductor storage device are formed on an identical semiconductor substrate.

60. A semiconductor device comprising the semiconductor storage device claimed in claim 5, a column decoder, a sense amplifier and a row decoder, wherein
at least one of the column decoder, the sense amplifier and the row decoder and the semiconductor storage device are formed on an identical semiconductor substrate.

61. A semiconductor device comprising the semiconductor storage device claimed in claim 6, a column decoder, a sense amplifier and a row decoder, wherein
at least one of the column decoder, the sense amplifier and the row decoder and the semiconductor storage device are formed on an identical semiconductor substrate.

62. Portable electronic equipment comprising the semiconductor storage device claimed in claim 1.

63. Portable electronic equipment comprising the semiconductor storage device claimed in claim 2.

64. Portable electronic equipment comprising the semiconductor storage device claimed in claim 3.

65. Portable electronic equipment comprising the semiconductor storage device claimed in claim 4.

66. Portable electronic equipment comprising the semiconductor storage device claimed in claim 5.

67. Portable electronic equipment comprising the semiconductor storage device claimed in claim 6.

68. Portable electronic equipment comprising a semiconductor device, wherein
the semiconductor device comprises:
the semiconductor storage device claimed in claim 1,
a column decoder,
a sense amplifier, and
a row decoder, and wherein
at least one of the column decoder, the sense amplifier and the row decoder and the semiconductor storage device are formed on an identical semiconductor substrate.

69. Portable electronic equipment comprising a semiconductor device, wherein
the semiconductor device comprises:
the semiconductor storage device claimed in claim 2,
a column decoder,
a sense amplifier, and
a row decoder, and wherein
at least one of the column decoder, the sense amplifier and the row decoder and the semiconductor storage device are formed on an identical semiconductor substrate.

70. Portable electronic equipment comprising a semiconductor device, wherein
the semiconductor device comprises:
the semiconductor storage device claimed in claim 3,
a column decoder,
a sense amplifier, and
a row decoder, and wherein
at least one of the column decoder, the sense amplifier and the row decoder and the semiconductor storage device are formed on an identical semiconductor substrate.

71. Portable electronic equipment comprising a semiconductor device, wherein
the semiconductor device comprises:
the semiconductor storage device claimed in claim 4,
a column decoder,
a sense amplifier, and
a row decoder, and wherein
at least one of the column decoder, the sense amplifier and the row decoder and the semiconductor storage device are formed on an identical semiconductor substrate.
